(19) United States
(12) Patent Application Publication
(10) Pub. No.: US 2010/0078309 A1
(43) Pub. Date: Apr. 1, 2010

(54) SPUTTERING METHOD AND SPUTTERING APPARATUS

(75) Inventors: Yoshihiko Ueda, Osaka (JP); Kazuki Moyama, Amagasaki (JP); Koji Fukumori, Amagasaki (JP)

Correspondence Address: PEARNE & GORDON LLP, 1801 EAST 9TH STREET, SUITE 1200, CLEVELAND, OH, 44114-3108, US

(73) Assignees: OSAKA VACUUM, LTD., Osaka-shi, Osaka (JP); TOKYO ELECTRON LIMITED, Tokyo (JP)

(21) Appl. No.: 12/524,390

(22) PCT Filed: Jan. 25, 2008
(86) PCT No.: PCT/JP2008/051094

§ 371 Date: Aug. 12, 2009

(30) Foreign Application Priority Data
Jan. 26, 2007 (JP) 2007-016723
Jan. 26, 2007 (JP) 2007-016724

(51) Int. Cl. C23C 14/34; C23C 14/35; C23C 14/50

(52) U.S. Cl. 204/192.1; 204/298.18; 204/298.15

(57) ABSTRACT

A sputtering method is for forming, in a vacuum chamber, an initial layer on a film formation target object and then further forming a second layer on the initial layer therein, and the method includes: in the vacuum chamber, arranging surfaces of a pair of targets to face each other while distanced apart from each other at a preset distance and to be inclined toward the film formation target object placed at a lateral position between the targets, and then sputtering the targets by generating a magnetic field space on the facing surfaces of the pair of targets, and thus forming the initial layer on the film formation target object by using particles sputtered by the sputtering; and further forming the second layer on the film formation target object at a higher film forming rate than a film forming rate of the initial layer.

### TECHNICAL FIELD

The present invention relates to a sputtering method and a sputtering apparatus for use in forming a thin film on a substrate; and, more particularly, to a sputtering method and a sputtering apparatus for forming a multi-function thin film of a metal, an alloy or a compound on a film of a substrate made of polymer or resin substrate, or on an organic EL device·organic thin film (organic semiconductor or the like), which requires a low-temperature·low-damage film formation. The present invention is applicable to forming a transparent conductive film, an electrode film, and a protective film·sealing film (gas barrier film) on an organic EL (Electro Luminescence) device and forming an electrode film and a protective film on an organic thin-film semiconductor. Further, the present invention is also applicable to a sputtering method and a sputtering apparatus for forming a thin film on a polymer film or resin substrate and also has a wide application in the field of a general-purpose thin film fabrication.

### BACKGROUND ART

When forming a metal film to be used as an electrode, a transparent conductive thin film, a protective film·sealing film or the like on a substrate (film formation target object) which is readily damaged in the process of forming an organic EL device or an organic thin film (organic semiconductor or the like), in order to prevent decrease of a product lifetime or deterioration of the substrate characteristics caused by damage during the film formation process, a low-temperature·low-damage film formation, which accompanies low damage at a film interface between a substrate such as an organic thin film and a thin film formed on the substrate, needs to be performed.

In this regard, as a film forming apparatus capable of performing a low-temperature·low-damage film formation, there has been utilized a facing target type sputtering apparatus in which a pair of targets are disposed in parallel to each other, and an inter-target magnetic field space having magnetic force lines oriented from one target to the other target is generated between the pair of targets, and a substrate is placed at a lateral position of the pair of targets, and then the sputtering is performed.

In the facing target type sputtering apparatus, the low-temperature·low-damage film formation can be implemented because the apparatus has a high effect of confining plasma and charged particles such as secondary electrons between the targets. Since, however, a sputtering surface of each target faces toward a direction perpendicular to a film formation target surface of the substrate, the amount of sputtered particles reaching the substrate is small and a film forming rate is low. Accordingly, it has been difficult to obtain a sufficient production rate (film forming rate) to meet recent demands for the improvement of productivity.

Therefore, it can be considered to carry out a film formation at a high film forming rate by using a parallel plate type magnetron sputtering apparatus in which a target is disposed such that its sputtering surface is parallel to the film formation target surface of the substrate, and sputtering is performed by generating, on the sputtering surface of the target, a curved magnetic field space having magnetic force lines connecting a peripheral portion with a central portion of the target in an arc shape. In the parallel plate type magnetron sputtering apparatus, however, since the sputtering surface is positioned to face the substrate, though a film forming rate may be increased because the amount of the sputtered particles reaching the substrate increases, the influence of the plasma upon the substrate or the amount of the charged particles such as secondary electrons flying thereto may also be increased. Accordingly, the low-temperature·low-damage film formation cannot be carried out.

As stated above, in the film formation by sputtering, it has been very difficult to achieve improvement of productivity and a low-temperature·low-damage film formation at the same time.

For this reason, there has been developed a V-shaped facing target type sputtering apparatus having a configuration in which facing surfaces of a pair of targets in the above-described facing target type sputtering apparatus are respectively inclined with respect to a substrate (see, for example, Patent Document 1). Since the sputtering apparatus is a facing target type sputtering apparatus, it exhibits a high effect of confining plasma and charged particles such as secondary electrons between the targets. Further, since angles between the sputtering surfaces of the targets and a film formation target surface of the substrate become smaller than a right angle, i.e., since the sputtering surfaces are further oriented toward the substrate, the amount of the sputtered particles reaching (flying to) the substrate can be increased, resulting in an increase of a film forming rate.

Since, however, the sputtering surfaces are further oriented toward the substrate, the influence of the plasma upon the substrate and the amount of the charged particles such as secondary electrons flying thereto may be also increased as compared to the facing target type sputtering apparatus in which the pair of targets are parallel. Thus, when a film formation is performed on a substrate such as an organic EL device or an organic thin film (organic semiconductor or the like) on which a considerably low level of low-temperature·low-damage film formation needs to be performed, problems such as decrease of a product lifetime or deterioration of substrate characteristics, which are caused by damage during the film forming process, cannot be solved sufficiently.

Meanwhile, in the sputtering using a magnetron type cathode, when a film formation is performed on a film formation target object by the sputtering using a sputtering apparatus having a RF coil for supplementing negative ions or charged particles such as secondary electrons on a front surface of the target, the pressure within a vacuum chamber where the sputtering is conducted is set to be low (equal to or less than 1.33×10⁻² Pa) and a plasma density on a target surface is set to be low. By setting up the sputtering condition in such a way, the amount of the negative ions or the charged particles such as secondary electrons incident upon the substrate can be reduced when a film interface between a film formation target surface of the substrate and a thin film formed thereon are being formed, so that the low-temperature·low-damage film formation is accomplished. By using this, an initial layer (first layer) is formed on the film formation target surface of the substrate on which the low-temperature·low-damage film formation needs to be performed at an initial stage of the film formation. Since, however, a film forming rate is slow and productivity is very low under the mentioned sputtering condition, there has been proposed a method of forming a second layer. In this method, the pressure within the vacuum chamber is increased (to 6.65×10⁻¹ Pa or greater) by raising a flow rate of a sputtering gas introduced into the vacuum chamber after the formation of the initial layer, and a sputtering amount is increased by raising a plasma density on the target surface, and the film forming rate is increased (see, for example, Patent Document 2). Further, the initial layer (first layer) and the second layer are only distinguished for the purpose of explanation by an imaginary surface where a film forming rate of a thin film is changed in a film thickness direction, and they are not actually divided as separate layers in the film thickness direction, but they are continuous. Further, the film interface is a boundary surface where the film formation target surface and the thin film are in contact with each other.

According to such a sputtering method, on the film formation target surface of the substrate such as the organic EL device or the like which requires the low-temperature·low-damage film formation, the initial layer is formed in a sufficient thickness by the low-temperature·low-damage film formation under the above-mentioned low pressure condition. Due to the presence of the initial layer, it is possible to prevent an adverse influence upon the substrate due to the increase of the plasma density or the increase of the amount of the charged particles such as secondary electrons released from the targets, which are generated when the second layer is formed at a high film forming rate and are increased with the rise of the sputtering amount.

Therefore, the low-temperature·low-damage film can be formed on the substrate which requires the low-temperature·low-damage film formation. Further, as compared to a case of carrying out the film formation to the last by the low-temperature·low-damage film formation, the film forming rate of the entire film forming process (formation of the first and second layers) can be increased (i.e., time for the film formation can be reduced) by increasing the film forming rate for the second layer formation, so that improvement of the productivity can be accomplished.

Patent Document 1: Japanese Patent Laid-open Publication No. 2004-285445

Patent Document 2: Japanese Patent Laid-open Publication No. 2005-340225

### DISCLOSURE OF THE INVENTION

### Problems to Be Solved by the Invention

According to the above-described sputtering method, however, since the pressure levels in the vacuum chamber are different when the first layer and the second layer are formed, the pressure within the vacuum chamber needs to be changed (increased) before starting the second layer formation and after completion of the first layer formation.

Though the change of the pressure within the vacuum chamber may be implemented by varying the flow rate of the sputtering gas (e.g., an argon gas) introduced into the vacuum chamber, it takes a certain period of time before the pressure within the vacuum chamber reaches a preset level and is stabilized enough to perform the sputtering.

Thus, according to the above-stated sputtering method, the increase rate of the film forming rate is low despite of the pressure change when the second layer is formed and a certain period of time is required to change the pressure within the vacuum chamber. Therefore, the entire film formation processing time for obtaining a required film thickness is hardly shortened as compared to a case of performing the entire film forming process by the low-temperature·low-damage film formation at a low film forming rate. To elaborate, the improvement of the film forming rate in the entire film forming process, which can be achieved by increasing the flow rate of the sputtering gas introduced into the vacuum chamber while the power (input power) inputted to the cathode for the sputtering is maintained the same, only ranges from several % to about 10%. Moreover, it has been recently required to obtain a higher level of productivity by reducing the processing time of the entire film forming process.

Moreover, according to the above-stated sputtering method, the RF coil needs to be provided in front of the target to supplement the charged particles such as the secondary electrons or the negative ions incident upon the substrate, and an RF power supply for driving the RF coil or a controlling unit for controlling the RF coil and the RF power supply needs to be additionally provided. As a result, the structure of the sputtering apparatus for performing the above-stated sputtering method becomes complicated.

Therefore, in view of the foregoing, an object of the present invention is to provide a sputtering method and a sputtering apparatus, which have a simple structure and capable of carrying out a low-temperature·low-damage film formation and have a high productivity.

### Means for Solving the Problems

In accordance with the present invention, there is provided a sputtering method for forming, in a vacuum chamber, an initial layer on a film formation target object and then further forming a second layer on the initial layer therein, the method including: in the vacuum chamber, arranging surfaces of a pair of targets to face each other while distanced apart from each other at a preset distance and to be inclined toward the film formation target object placed at a lateral position between the targets, and then sputtering the targets by generating a magnetic field space on the facing surfaces of the pair of targets, and thus forming the initial layer on the film formation target object by using particles sputtered by the sputtering; and further forming the second layer on the film formation target object at a higher film forming rate than a film forming rate of the initial layer. Further, in accordance with the present invention, there is provided a sputtering apparatus for forming, in a vacuum chamber, an initial layer on a film formation target object and then further forming a second layer on the initial layer therein, the apparatus including: in the vacuum chamber, a pair of targets for forming the initial layer, arranged to face each other while distanced apart at a preset distance and having surfaces inclined toward the film formation target object placed at a lateral position between the targets; a magnetic field generating unit for generating a magnetic field space on the facing surfaces of the pair of targets; and a holder for holding the film formation target object, wherein the second layer is formed on the film formation target object at a film forming rate higher than that of the initial layer.

Further, to be more specific, in the sputtering method in accordance with the present invention, in the vacuum chamber whose inner space is divided into a first film formation region having a first film forming unit for forming the initial layer and a second film formation region having a second film forming unit for forming the second layer, the first film forming unit and the second film forming unit are arranged in juxtaposition, the initial layer is formed on the film formation target object in the first film forming unit, then, the film formation target object is transferred from a first film formation position where the film formation is performed on the film formation target object in the first film forming unit to a second film formation position where the film formation is performed on the film formation target object in the second film forming unit, the second layer is further formed on the film formation target object in the second film forming unit, and the method includes: disposing the pair of targets in the first film forming unit as first targets; generating, on a surface side of one of the first targets, an arc-shaped inwardly curved magnetic field space having magnetic force lines oriented from an outer peripheral portion toward a central portion of the one first target and generating, on a surface side of the other first target, an arc-shaped outwardly curved magnetic field space having magnetic force lines oriented from a central portion toward an outer periphery of the other first target; performing sputtering by generating a cylindrical auxiliary magnetic field space, which has magnetic force lines oriented from a vicinity of the one first target toward a vicinity of the other first target while surrounding a first inter-target space formed between the first targets and has a magnetic field strength greater than that of the curved magnetic field space, and thus forming the initial layer on the film formation target object by using first particles sputtered by the sputtering; and performing sputtering by generating an inwardly curved magnetic field space or an outwardly curved magnetic field space on surface sides of second targets in the second film forming unit, and forming the second layer on the film formation target object by second particles sputtered by the sputtering. Furthermore, in the sputtering apparatus in accordance with the present invention, in the vacuum chamber whose inner space is divided into a first film formation region having a first film forming unit for forming the initial layer and a second film formation region having a second film forming unit for forming the second layer, the first film forming unit and the second film forming unit are arranged in juxtaposition, the holder is configured to be movable, while holding the film formation target object in the vacuum chamber, from a first film formation position where the film formation is performed on the film formation target object in the first film forming unit to a second film formation position where the film formation is performed on the film formation target object in the second film forming unit, the first film forming unit includes a pair of first complex type cathodes each having a first target of the pair of targets; a curved magnetic field generating unit for generating a curved magnetic field space having arc-shaped magnetic force lines on the facing surface of the first target; and a cylindrical auxiliary magnetic field generating unit installed to surround the first target, the pair of first complex type cathodes are installed such that surfaces of the first targets face each other while distanced apart from each other at a preset distance and the surfaces are inclined toward the first film formation position located at a lateral position between the first targets, the curved magnetic field generating unit of one of the pair of first cathodes generates an inwardly curved magnetic field whose polarity is set such that magnetic force lines are oriented from an outer peripheral portion of one of the first targets toward a central portion thereof while the curved magnetic field generating unit of the other first cathode generates an outwardly curved magnetic field whose polarity is set such that magnetic force lines are oriented from a central portion of the other first target to an outer peripheral portion thereof, the cylindrical auxiliary magnetic field generating unit generates a cylindrical auxiliary magnetic field space having magnetic force lines oriented from a vicinity of the one first target toward a vicinity of the other first target so as to surround a first inter-target space formed between the first targets and having a magnetic field strength greater than that of the curved magnetic field space, and the second film forming unit includes a sputtering cathode having a second target and an inwardly or outwardly curved magnetic field generating unit for generating an inwardly or outwardly curved magnetic field space on a surface of the second target, and being capable of emitting sputtered particles toward the second film formation position, and having a film forming rate higher than that of the first film forming unit.

According to this configuration, in the first film forming unit of the first film formation region, the cylindrical auxiliary magnetic field space having a magnetic field strength greater than that of the curved magnetic field space is formed (generated) to surround the first inter-target space between the first targets such that magnetic force lines are oriented from the vicinity of one first target to the vicinity of the other first target by the cylindrical auxiliary magnetic field generating unit installed in the vicinity of each of the first targets.

Since the cylindrical auxiliary magnetic field generating unit is separately provided in the vicinity of the curved magnetic field generating unit (first target) and the cylindrical auxiliary magnetic field is formed to surround the first inter-target space, a space having a high magnetic field strength can be formed between the first inter-target space and the substrate, which is the film formation target object, without having to shorten (reduce) the distance between the centers of the pair of first targets. Accordingly, in the first film forming unit, effect of confining plasma and charged particles such as secondary electrons between the first targets (first complex type cathodes) can be improved without accompanying a reduction of a film forming rate.

That is, the curved magnetic field space formed on the surface of the first target is surrounded (enclosed) by the cylindrical auxiliary magnetic field space, so that plasma escaped from the curved magnetic field space may be trapped in the cylindrical auxiliary magnetic field space (the escape toward the substrate is suppressed), and an influence of plasma upon the substrate can be suppressed.

Furthermore, in the first film forming unit, since the curved magnetic field space is surrounded by the cylindrical auxiliary magnetic field space, the effect of confining charged particles such as secondary electrons, which are released toward (flying to) the substrate from the curved magnetic field space, in the first inter-target space can also be improved. That is, the release of the charged particles toward the substrate is decreased.

Moreover, since the first complex cathode is a magnetron type cathode (magnetron cathode) having the cylindrical auxiliary magnetic field generating unit, an unstable electric discharge due to high plasma concentration at a central portion, which may occur in case of using facing target type cathodes, does not occur even when a current inputted to the first cathodes is increased. Therefore, plasma generated in the vicinities of the target surfaces can be electrically discharged stably for a long period of time.

Thus, in the first film forming unit, since it is stable for a long period of time without having to shorten the distance between the centers of the pair of the first targets, the influence of the plasma upon the substrate and the influence of (damage by) the charged particles such as secondary electrons flying from the sputtering surfaces can be minimized. As a result, a low-temperature·low-damage film formation can be performed on the substrate to form an initial layer.

Accordingly, by performing the sputtering in the first film forming unit as described above, a low-temperature·low-damage film formation can be carried out on the substrate up to a preset thickness, whereby the initial layer (first layer) is formed. Thereafter, the substrate is transferred from the first film formation position of the first film forming unit to the second film formation position of the second film forming unit without changing a sputtering condition such as the pressure within the vacuum chamber. Then, sputtering having a higher film forming rate than that in the first film forming unit is started in the second film forming unit. At this time, as a result of performing the sputtering with a higher film forming rate in the second film forming unit, the amount of the charged particles such as secondary electrons reaching the substrate or the influence of the plasma upon the substrate may be increased though the second layer can be formed in a shorter period of time.

However, since the initial layer formed by the low-temperature·low-damage film formation in the first film forming unit serves as a protective layer, the second layer can be formed at a higher film forming rate while suppressing the damage caused by the charged particles such as secondary electrons or the influence of the plasma upon the substrate. That is, by covering the substrate with the initial layer, the substrate can be protected from the damage due to the charged particles flying thereto or a temperature rise due to the influence of the plasma.

In addition, when the second layer is formed after forming the initial layer, only the substrate position needs to be changed and a change of the sputtering condition such as the pressure within the vacuum chamber, which would take a long time, is not required. Thus, a desired film thickness can be obtained in a shorter period of time. This effect is especially advantageous when a thin film formation is performed on a plurality of substrates.

Conventionally, a film formation of a plurality of substrates has been consecutively performed by repeating the processes of forming a first layer on a substrate; forming a second layer after changing (increasing) the pressure within the vacuum chamber; forming a first layer on a next substrate after returning the pressure within the vacuum chamber to a pressure level for forming the first layer; and forming a second layer after changing (increasing) the pressure within the vacuum chamber to a pressure level for forming the second layer.

According to the conventional sputtering method stated above, the pressure within the vacuum chamber needs to be changed repetitively to carry out the film formation of the plurality of substrates consecutively. Thus, it has taken a lot of time for carrying out the pressure changes, and the entire film formation time has been very long in consideration of productivity.

In the present invention, however, since the substrate only needs to be transferred by the holder to the first film forming unit and to the second film forming unit in sequence without having to change the sputtering condition such as the pressure within the vacuum chamber, the film formation time for the plurality of substrates can be reduced greatly.

From the foregoing, a film formation of a substrate which requires a low-temperature·low-damage film formation can be successfully carried out, and reduction of the entire film formation time for processing the plurality of substrates consecutively can also be achieved.

Furthermore, since the first complex type cathode is a magnetron cathode having the cylindrical auxiliary magnetic field generating unit, it can perform film formation on an elongated substrate. That is, if the aspect ratio of a facing surface of a target in a facing target type cathode is greater than about 3:1, an inter-target electric discharge may become unstable, thereby making it difficult to form a high-quality thin film. Furthermore, it may be considered to use a facing target type cathode having a big-size target with an aspect ratio of about 3:1 to form a thin film on an elongated substrate. In such case, however, economical efficiency may be greatly deteriorated. In contrast, the aspect ratio of the facing surface of the target can be increased to about 5:1 or greater in the magnetron cathode. Thus, it is possible to form a thin film on an elongated substrate corresponding to such a target. Therefore, a thin film formation can be carried out on an elongated substrate with the first complex type cathode without deteriorating economical efficiency. In addition, since the first complex type cathode additionally includes the cylindrical auxiliary magnetic field generating unit as compared to a conventional magnetron cathode, a higher level of low-temperature·low-damage film formation is accomplished.

Further, in the present invention, it is not necessary to additionally install RF coils on the facing surfaces of the pair of first targets in the first film forming unit or install a RF power supply for driving the RF coils or a controller for controlling the RF coils and the RF power supply so as to perform the low-temperature·low-damage film formation. Thus, the structure of the apparatus can be simplified.

Further, in the sputtering method in accordance with the present invention, a plurality of first film forming units may be arranged in juxtaposition in the first film formation region, and film formation may be carried out on the film formation target object by the plurality of first film forming units in sequence or at the same time. In the sputtering apparatus in accordance with the present invention, a plurality of first film forming units may be arranged in juxtaposition in the first film formation region.

In this configuration, since the plurality of first film forming units are juxtaposed in the first film formation region and film formation target objects are processed by the plurality of first film forming units in sequence or simultaneously, a film forming rate can be increased and improvement of productivity can be achieved due to a reduction of film formation time in the first film formation region.

Further, in the sputtering method in accordance with the present invention, a multiple number of second film forming units may be arranged in juxtaposition in the second film formation region, and film formation may be carried out on the film formation target object by the multiple number of second film forming units in sequence or at the same time. In the sputtering apparatus in accordance with the present invention, a multiple number of second film forming units may be arranged in juxtaposition in the second film formation region.

In this configuration, since a multiple number of second film forming units are juxtaposed in the second film formation region and the film formation target objects are processed by the multiple number of second film forming units in sequence or simultaneously, a film forming rate can be increased and the productivity can be further improved due to a reduction of film formation time in the second film formation region.

Further, as another specific invention, in the sputtering method in accordance with the present invention, the initial layer is formed on the film formation target object in a preset thickness by performing the sputtering after an angle between the facing surfaces of the pair of targets is set to a preset angle, and then, the second layer is formed by performing the sputtering after the angle between the facing surfaces is set to be larger than the preset angle by way of changing the directions of the facing surfaces toward the film formation target object. Furthermore, in the sputtering apparatus in accordance with the present invention, the pair of targets is disposed such that their directions can be changed toward the holder so as to increase an angle formed between their facing surfaces.

In general, as the angle formed between the facing surfaces of the pair of targets decreases (as the facing surfaces are arranged more parallel to each other), the amount of charged particles such as secondary electrons reaching (flying to) the substrate serving as the film formation target object may be decreased and the effect of confining plasma between the targets may be improved. However, the amount of sputtered particles reaching the substrate would be also reduced. Thus, though a low-temperature·low-damage film formation is accomplished, a film forming rate of a thin film formed on the substrate may be decreased.

Meanwhile, as the angle between the facing surfaces of the pair of targets increases (i.e., as the facing surfaces is further oriented toward the substrate), the amount of sputtered particles reaching the substrate may be increased. However, the amount of charged particles such as secondary electrons reaching the substrate is increased and the effect of confining the plasma in the inter-target space is deteriorated. Thus, though the temperature rise of the substrate and the damage on the substrate caused by the charged particles may be also increased, the film forming rate may be increased.

According to the above-described configuration, by performing the sputtering while the angle between the facing surfaces is set small, the low-temperature·low-damage film formation can be performed on the substrate to the preset thickness though the film forming rate is small. As a result, the initial layer (first layer) is formed by the low-temperature·low-damage film formation. Thereafter, the sputtering is performed after increasing the angle by changing the directions of the facing surfaces to be oriented toward the substrate without changing the sputtering condition such as the pressure within the vacuum chamber. Accordingly, the second layer can be formed at a higher film forming rate though the amount of the charged particles such as secondary electrons reaching the substrate or the influence of the plasma upon the substrate may be increased.

That is, the initial layer having a sufficient thickness is formed on the substrate by the low-temperature·low-damage film formation. Thereafter, by forming the second layer after changing the direction of the facing surfaces of each target toward the substrate (holder), an increase of film forming rate much greater than that obtainable by a pressure change within the vacuum chamber can be attained because the facing surfaces (sputtering surfaces) of each target is more oriented toward the substrate. At that time, the influence of the plasma or the increased amount of charged particles such as secondary electrons reaching the substrate can be suppressed because the initial layer serves as the protective layer. Furthermore, it is not necessary to change the sputtering condition such as the pressure within the chamber, which would take a long time if changed. Accordingly, the processing time of the entire film formation process can be shortened (i.e., the film forming rate can be improved) while the low-temperature·low-damage film formation is carried out. Specifically, the improvement of the film forming rate, which can be achieved by performing the sputtering after changing the angle between the facing surfaces of the pair of targets while an input power is maintained the same, becomes about 10% or greater.

Furthermore, in the present invention, since it is not necessary to additionally install RF coils on the facing surfaces of the pair of targets or to install a RF power supply for driving the RF coils or a controller for controlling the RF coils and the RF power supply so as to perform the low-temperature·low-damage film formation. Thus, the structure of the apparatus can be simplified.

Further, if the angle between the facing surfaces is 0°, it means that the facing surfaces are parallel to each other; if the angle increases, it means that the directions of the facing surfaces of the pair of targets are changed so that they are more oriented toward the substrate; and if the angle decreases, it means that the facing surfaces become more parallel to each other.

Further, in the sputtering method in accordance with the present invention, a magnetic field space generated on the facing surfaces of the pair of targets may be an inter-target magnetic field space having magnetic force lines oriented from one of the targets toward the other. In the sputtering apparatus in accordance with the present invention, the magnetic field generating unit may be an inter-target magnetic field generating unit for generating an inter-target magnetic field space having magnetic force lines oriented from one of the targets toward the other.

In such configuration, after the angle between the targets is set small, the initial layer is formed on the substrate by the sputtering using the facing target type sputtering cathodes in which the inter-target magnetic field space having magnetic force lines oriented from one target to the other target is formed between the pair of targets and plasma is formed (trapped) in the inter-target magnetic field space. Then, after the angle is increased, the second layer is formed on the substrate, so that the desired thin film is obtained.

By performing the film formation in such a way, the initial layer is formed by the low-temperature·low-damage film formation as described above. Further, the first layer serves as the protective layer when the second layer is formed, so that the film formation can be carried out while the influence of plasma or charged particles such as secondary electrons upon the substrate is suppressed. Thus, the film formation on the substrate (film formation target object), which requires the low-temperature·low-damage film formation, is accomplished.

Moreover, after the initial layer is formed by the low-temperature·low-damage film formation, the second layer is formed by changing the directions of the facing surfaces of the pair of targets toward the substrate, so that the film forming rate can be increased higher than that in case of changing the pressure within the vacuum chamber. In addition, only the angle between the pair of targets needs to be changed after the first layer is formed and before the start of the second layer formation, and the change of the sputtering condition such as the pressure within the vacuum chamber, which would take a long time, is not necessary. Accordingly, the film formation time can be greatly reduced, and the productivity of the thin film formation can be improved.

Further, in the sputtering method in accordance with the present invention, a cylindrical auxiliary magnetic field space having a magnetic field strength greater than that of the inter-target magnetic filed space may be further formed to surround the outside of the inter-target magnetic field space such that magnetic force lines of the cylindrical auxiliary magnetic field space are oriented in the same direction as that of magnetic force lines of the inter-target magnetic field space. In the sputtering apparatus in accordance with the present invention, a cylindrical auxiliary magnetic filed generating unit may be further disposed to surround each of the pair of targets so as to generate a cylindrical auxiliary magnetic field space having a magnetic field strength greater than that of the inter-target magnetic field space and surrounding the outside of the inter-target magnetic field space such that magnetic force lines of the cylindrical auxiliary magnetic field space are oriented in the same direction as that of magnetic force lines of the inter-target magnetic field space.

In this configuration, since the cylindrical auxiliary magnetic field space is formed (generated) so as to surround the inter-target magnetic field space, a magnetic field strength at a central portion of the inter-target magnetic field space can be increased without having to shorten (reduce) the distance between the centers of the pair of targets. Accordingly, it is possible to improve the effect of confining plasma and charged particles such as secondary electrons between the targets without accompanying a reduction of the film forming rate.

That is, since the cylindrical auxiliary magnetic field space is additionally formed to surround the outside of the inter-target magnetic field space, a distance (a width of a trapping magnetic field space) from a central line formed in the inter-target magnetic field space to an end of a space (a trapping magnetic field space to be described later) is increased, wherein the central line connects the center of one target to the center of the other target, and the space is formed outward and has a high magnetic flux density. Thus, plasma is not escaped from a magnetic field space (hereinafter, simply referred to as a “trapping magnetic field space”) including the inter-target magnetic field space and the cylindrical auxiliary magnetic field space formed at the outer side thereof, and the plasma is trapped in the trapping magnetic field space. In such a way, since the plasma is trapped within the trapping magnetic field space, the influence of the plasma upon the substrate can be reduced. Furthermore, the trapping magnetic field space is a combination of the inter-target magnetic field space and the cylindrical auxiliary magnetic field space. A space having a low magnetic flux density may be intervened between the inter-target magnetic field space and the cylindrical auxiliary magnetic field space, or the inter-target magnetic field space and the cylindrical auxiliary magnetic field space may be integrated (may be formed such that their magnetic flux densities are the same or vary continuously).

Further, the width of the trapping magnetic field space is increased by as much as the width of the cylindrical auxiliary magnetic field space as compared to the inter-target magnetic field space. Accordingly, a travelling distance of charged particles such as secondary electrons released from the inter-target magnetic field space toward the outside is increased within the trapping magnetic field space. Therefore, the effect of confining the charged particles in the trapping magnetic field space is increased. That is, the release of the charged particles from the inside of the trapping magnetic field space toward the substrate may be reduced.

In addition, since the magnetic field strength of the cylindrical auxiliary magnetic field space is greater than that of the inter-target magnetic field space, there can be obtained a magnetic field distribution in which the magnetic field strength increases as a distance from the central line in the trapping magnetic field space (inter-target magnetic field space) increases.

That is, in a conventional facing target type sputtering cathode in which the magnetic field generating unit is disposed only at a rear surface side (opposite to a facing surface) of each target, if an input power supplied to the cathode is increased, plasma between the targets may be concentrated at a central portion and the erosion of the target may also be increased at the central portion. This phenomenon becomes more conspicuous when the target is a magnetic material as compared to a case where the target is a non-magnetic material, because the target becomes a yoke. With the above-described configuration, however, since the trapping magnetic field space has the magnetic field distribution in which the magnetic field strength increases toward the periphery thereof, the concentration of the plasma in the central portion of the trapping magnetic field space (inter-target magnetic field space) caused by the increase of the input power to the cathode can be reduced even in case that the target is the magnetic material, and the degree of erosion does not increase greater at the central portion. Thus, even in case that the target is made of the magnetic material, deterioration of utilization efficiency of the target can be reduced, and a film thickness distribution of the thin film formed on the substrate can be uniform.

Accordingly, a film formation having a lower temperature and a lower damage can be accomplished, and a film quality can be improved. Further, if a required film quality is approximately the same as the film quality of a thin film formed by the sputtering which does not generate the cylindrical auxiliary magnetic field space, the angle formed between the facing surfaces of the pair of targets may be increased. Therefore, the film forming rate can be increased, and productivity can be improved.

Further, in the sputtering method in accordance with the present invention, a magnetic field space generated on the facing surface of the pair of targets may be a curved magnetic field space having magnetic force lines connecting an outer peripheral portion of the facing surface of the target with a central portion thereof in an arc shape. In the sputtering apparatus in accordance with the present invention, the magnetic field generating unit may be a curved magnetic field generating unit for generating a magnetic field space having magnetic force lines connecting an outer peripheral portion of the facing surface of the target with a central portion thereof in an arc shape.

In such configuration, the initial layer is formed on the substrate while the angle formed between the targets is set small by the sputtering which is performed by disposing a pair of so-called facing target type sputtering cathodes to face each other. In the facing target type sputtering cathodes, the curved magnetic field space connecting the outer peripheral portion of the facing surface with the central portion thereof in an arc shape is formed on the facing surface, and plasma is generated (trapped) in the curved magnetic field space, and the sputtering is performed. Then, after the angle is increased, the second layer is formed on the substrate, so that the desired thin film is obtained.

By performing the film formation in such a way, the initial layer is formed by the low-temperature·low-damage film formation as described above. Since the first layer serves as the protective layer, the film formation can be carried out while the influence of plasma or charged particles such as secondary electrons upon the substrate is suppressed when the second layer is formed. Therefore, the film formation on the substrate (film formation target object), which requires the low-temperature·low-damage film formation, is accomplished.

Moreover, after the initial layer is formed by the low-temperature·low-damage film formation, the second layer is formed by changing the directions of the facing surfaces of the pair of targets toward the substrate, so that the film forming rate can be increased higher than that in case of changing the pressure within the vacuum chamber. In addition, only the angle between the pair of targets needs to be changed after the first layer is formed and before the start of the second layer formation, and the change of the sputtering condition such as the pressure within the vacuum chamber, which would take a long time, is not necessary. Accordingly, the film formation time can be greatly reduced, and productivity of the thin film formation can be improved.

Further, in the sputtering method in accordance with the present invention, the curved magnetic field space has magnetic force lines oriented from a peripheral portion toward a central portion on the facing surface of one of the pair of targets and magnetic force lines oriented from a central portion toward a peripheral portion on the facing surface of the other target, and there is further generated a cylindrical auxiliary magnetic field space having magnetic force lines oriented from a vicinity of one of the targets toward a vicinity of the other target to surround the outside of an inter-target space formed between the pair of targets and having a magnetic field strength greater than that of the curved magnetic field space. In the sputtering apparatus in accordance with the present invention, the curved magnetic field generating unit may generate a curved magnetic field in which magnetic force lines on the facing surface of one of the targets is oriented from a peripheral portion toward a central portion, while magnetic force lines on the facing surface of the other target is oriented from a central portion toward a peripheral portion, and may be disposed to surround the each of the pair of targets is a cylindrical auxiliary magnetic field generating unit for generating a cylindrical auxiliary magnetic field space having magnetic force lines oriented from a vicinity of one of the targets toward a vicinity of the other target to surround the outside of an inter-target space formed between the pair of targets and having a magnetic field strength greater than that of the curved magnetic field space.

In such configuration, formed (generated) is the cylindrical auxiliary magnetic field space connecting the vicinity of one target with the vicinity of the other target in a cylinder shape and having magnetic force lines oriented from the vicinity of the one target toward the vicinity of the other. Thus, plasma escaped from or charged particles such as secondary electrons released from the inside of the curved magnetic field space on the facing surfaces of the targets during the sputtering can be trapped within the cylindrical auxiliary magnetic field space.

That is, since both ends of the cylindrical auxiliary magnetic field space are enclosed by the facing surfaces of the targets, the plasma escaped from the curved magnetic field space formed on the surface (facing surface) of the target is trapped within the cylindrical auxiliary magnetic field space (i.e., the escape toward the substrate is suppressed), so that the influence of the plasma upon the substrate can be reduced.

Furthermore, since both ends of the cylindrical auxiliary magnetic field space are enclosed by the facing surfaces of the targets, charged particles such as secondary electrons released from the curved magnetic field space may be trapped within the cylindrical auxiliary magnetic field space, so that the amount of the charged particles reaching the substrate may be reduced.

Furthermore, in the above-stated configuration, the magnetron type sputtering cathodes are used. Thus, unlike the case of using the facing target type sputtering cathodes, an unstable electric discharge due to a high plasma concentration at the central portion does not occur even when an input current to the cathodes is increased during the sputtering. Accordingly, the plasma generated in the vicinities of the surfaces of the targets can be electrically discharged stably for a longer period of time.

In addition, since the magnetic field strength of the cylindrical auxiliary magnetic field space is greater than that of the curved magnetic field space, there can be obtained a magnetic field strength distribution in which the magnetic field strength in the vicinity of the facing surfaces is the weakest at the center sides of the targets and the strongest at the peripheral portions thereof. Accordingly, the effect of confining the plasma escaped from the curved magnetic field space and the effect of confining the charged particles such as secondary electrons released therefrom within the cylindrical auxiliary magnetic field space can be further improved.

Therefore, the influence of the plasma upon the substrate serving as the film formation target object and the influence of the charged particles such as secondary electrons flying from the sputtering surfaces (facing surfaces) can be minimized without having to shorten the distance between the centers of the pair of targets. As a result, a film formation having a lower temperature and a lower damage can be accomplished and a film quality can be improved. Furthermore, when a required film quality is approximately the same as that of a thin film formed by the sputtering which does not generate the cylindrical auxiliary magnetic field space, the angle between the facing surfaces of the pair of targets can be further increased.

Further, in the sputtering apparatus in accordance with the present invention, the second film forming unit may include a parallel plate type magnetron cathode made up of the sputtering cathode in which a surface of the second target is oriented toward the second film formation position.

In this configuration, the second film forming unit has a so-called parallel plate type magnetron cathode (planar magnetron cathode) in which the sputtering cathode (magnetron cathode), which has the curved magnetic field space formed on its surface when the substrate is placed at the second film formation position, is disposed such that the second target of the sputtering cathode faces the substrate and the surface (sputtering surface) of the second target is parallel to the film formation target surface of the substrate. Thus, as compared to the configuration in which the surface of the second target is inclined with respect to the film formation target surface of the substrate at a certain angle, the amount of the sputtered particles reaching the substrate can be increased for the same input power, so that a film forming rate in the second film forming unit can be increased.

As a result, the time required for the formation of the second layer in the second film forming unit can be shortened, and the entire film formation processing time for forming the thin film of the desired film thickness can be reduced. Thus, productivity of the thin film can be improved.

Further, in the sputtering apparatus in accordance with the present invention, the second film forming unit may include dual magnetron cathodes in which a pair of the sputtering cathodes are arranged in juxtaposition and surfaces of second targets are oriented toward the second film formation position, and the dual magnetron cathodes are connected with an AC power supply capable of applying AC electric fields having a phase difference of about 180° to the pair of sputtering cathodes respectively.

With this configuration, when the substrate is positioned at the second film formation position, the second film forming unit includes so-called dual magnetron cathodes in which the pair (two in one set) of sputtering cathodes (magnetron cathodes) forming curved magnetic field spaces on their surfaces are arranged in juxtaposition so that the surface (sputtering surface) of each second target of the sputtering cathodes and the film formation target surface of the substrate are arranged in parallel or substantially parallel to each other, and each of the pair of sputtering cathodes is connected with an AC power supply capable of applying AC electric fields having a phase difference of about 180°.

In the dual magnetron cathodes, if a negative potential is applied to one of the magnetron cathodes, a positive potential or an earth potential may be applied to the other magnetron cathode. Therefore, the other magnetron cathode serves as an anode, and the second target included in the one magnetron cathode to which the negative potential is applied becomes sputtered. Further, if the negative potential is applied to the other magnetron cathode, the positive potential or the earth potential is applied to the one magnetron cathode. Therefore, the one magnetron cathode is made to serve as an anode, and the second target included in the other magnetron cathode is sputtered.

In this way, by alternately switching the potentials to be applied to the pair of magnetron cathodes, a charge-up of an oxide and a nitride does not occur on the surface of the second target, and a stable electric discharge can be carried out for a long period of time. For this reason, it is possible to perform a film formation of an insulating thin film such as SiOx for a long period of time.

Further, as stated above, since it is possible to increase the input power to the magnetron cathodes, a high-speed sputtering can be carried out and a higher film forming rate can be achieved in the second film forming unit by increasing the input power applied to the cathodes.

As a result, the second layer having a high quality can be formed and a time required for forming the second layer can be reduced, so that it is possible to improve the quality of the thin film as well as productivity thereof.

Further, the second film forming unit may include a pair of second complex type cathodes each having a second target; a curved magnetic field generating unit for generating a curved magnetic field space having arc-shaped magnetic force lines on the surface of the second target; and a cylindrical auxiliary magnetic field generating unit installed to surround the second target, the pair of second complex type cathodes are installed such that surfaces of the second targets face each other while distanced apart from each other at a preset distance and the surfaces are inclined toward the second film formation position located at a lateral position between the second targets, the curved magnetic field generating unit of one of the pair of second cathodes generates an inwardly curved magnetic field whose polarity is set such that magnetic force lines are oriented from an outer peripheral portion of one of the second targets toward a central portion thereof while the curved magnetic field generating unit of the other second cathode generates an outwardly curved magnetic field whose polarity is set such that magnetic force lines are oriented from a central portion of the other second target to an outer peripheral portion thereof, the cylindrical auxiliary magnetic field generating unit generates a cylindrical auxiliary magnetic field space having magnetic force lines oriented from a vicinity of the one second target toward a vicinity of the other second target so as to surround a second inter-target space formed between the second targets and having a magnetic field strength greater than that of the curved magnetic field space, and an angle formed between facing surfaces of the second targets in the pair of second complex type cathodes is larger than an angle formed between the facing surfaces of the first targets in the pair of first complex type cathodes of the first film forming unit.

In this configuration, the angle formed between the surfaces of the first targets of the pair of first complex cathodes in the first film forming unit is smaller (i.e., the surfaces are more parallel to each other) than the angle formed between the surfaces of the second targets of the pair of the second complex cathodes in the second film forming unit. For this reason, in the first film forming unit, the effect of confining the plasma and the charged particles such as second electrons generated by the sputtering between the targets can be improved as compared to the second film forming unit. Therefore, the amount of the charged particles flying to the substrate and the influence of the plasma upon the substrate may be reduced, so that it is possible to perform a low-temperature·low-damage film formation on the substrate.

Meanwhile, the angle formed between the surfaces of the second targets of the pair of second complex cathodes in the second film forming unit is larger (i.e., the surfaces of the targets are further oriented toward the substrate) than the angle formed between the surfaces of the first targets of the pair of the first complex cathodes in the first film forming unit. For this reason, in the second film forming unit, the effect of confining the plasma and the charged particles such as second electrons generated by the sputtering between the targets may be reduced as compared to the first film forming unit. Therefore, the amount of the charged particles flying to the substrate and the influence of the plasma upon the substrate may be increased, so that a temperature rise of the substrate caused by the plasma and damage on the substrate caused by the charged particles are more likely to occur. However, since the amount of the second sputtered particles flying to the substrate is increased, the film forming rate becomes much higher than the film forming rate in the first film forming unit.

Accordingly, by performing the sputtering in the first film forming unit as stated above, the low-temperature·low-damage film formation can be performed on the substrate up to a predetermined thickness, so that the initial layer (first layer) is formed. Thereafter, without changing sputtering condition such as a pressure within the vacuum chamber, the substrate is moved by the substrate holder from the first film formation position in the first film forming unit to the second film formation position in the second film forming unit, and then the sputtering is performed in the second film forming unit at a higher film forming rate than that of the first film forming unit. In this way, by performing the sputtering at a higher film forming rate than the first film forming unit, the second layer can be formed in a shorter period of time though the influence of the plasma or the charged particles such as the secondary electrons flying to the substrate may be increased.

In view of the foregoing, the initial layer is formed on the substrate by the low-temperature·low-damage film formation in the first film forming unit and the initial layer serves as the protective layer. Thus, it is possible to perform the film formation (thin film formation) at a high filming rate while suppressing (preventing) damage due to the charged particles such as the secondary electrons flying to the substrate or the influence of the plasma upon the substrate during the second layer formation in the second film forming unit. Moreover, after forming the initial layer, the second layer may be formed by changing only the position of the substrate and the change of the sputtering condition such as the pressure within the vacuum chamber is not required. Therefore, the required film thickness can be formed in a short period of time. Especially, in case of consecutively forming thin films on plural sheets of substrates, it is not necessary to change the sputtering condition such as the pressure within the vacuum chamber but the substrates only need to be transferred into the first and second film forming units in sequence by the holder in the same manner as stated above. Therefore, the time for performing the film formation on the plural substrates can be greatly reduced.

As a result, it is possible to perform the film formation on the substrate which requires the low-temperature·low-damage film formation and reduce the film formation time when the film formation processes on the plural sheets of substrates are consecutively performed. That is, since the entire film formation processing time can be reduced, the productivity of the thin film formation can be improved. Therefore, it is possible to perform the film formation on the substrate which requires the low-temperature·low-damage film formation and the productivity can be improved by reducing the film formation processing time.

Further, the pair of first complex type cathodes may be connected with an AC power supply capable of applying AC electric fields having a phase difference of about 180° to the pair of first combination cathodes respectively.

With this configuration, since the pair of first complex cathodes are magnetron-type cathodes (magnetron cathodes) each including the cylindrical auxiliary magnetic field generating unit, if a negative potential is applied to one magnetron cathode, a positive potential or an earth potential is applied to the other magnetron cathode. Accordingly, the other magnetron cathode serves as an anode, and the first target of the one magnetron cathode to which the negative potential is applied is sputtered. Further, if the negative potential is applied to the other magnetron cathode, the positive potential or the earth potential is applied to the one magnetron cathode. Accordingly, the one magnetron cathode serves as an anode, and the first target of the other magnetron cathode is sputtered.

In this way, by alternately switching the potentials to be applied to the pair of the magnetron cathodes, low-temperature·low-damage film formation, a charge-up of an oxide and a nitride generated does not occur on the surface of the second target and a stable electric discharge can be carried out for a long period of time. For this reason, it is possible to perform a film formation of an insulating thin film such as SiOx for a long period of time.

As a result, it is possible to form the initial layer (first layer) having a high-quality, and thus the high-quality thin film can be obtained.

Further, in the sputtering apparatus in accordance with the present invention, the pair of targets are disposed such that their directions can be changed so as to increase or decrease the angle formed between their facing surfaces, and the apparatus may further include: a detection unit for detecting at least one of a film thickness and a temperature at a vicinity of the film formation target object held by the holder, the detection unit being provided at a position facing a flow path of sputtered particles flying toward the film formation target object from each of the pair of targets; and a controller for controlling a change of direction of each target based on a detection value obtained by the detection unit.

With this configuration, the detection unit for detecting the film thickness is provided at a vicinity of the film formation target object (hereinafter, referred to as “substrate”) and at a position facing a flow path of the sputtered particles, a film thickness of a thin film formed on a film formation target surface of the substrate can be detected. In this way, since the film thickness is detected while the film formation is being performed, the value (detection value) of a film thickness variation per unit time (film forming rate) can also be detected.

Besides, the control unit compares the detection value detected by the detection unit with a first film formation condition of the initial layer (a film forming rate at which an interface of the substrate requiring the low-temperature·low-damage film formation is not damaged and a film thickness with which the initial layer is capable of serving as the protective film), and if it is determined that the detection value is different from the first film formation condition of the initial layer, each target is changed in direction (in angle), so that the angle formed between the facing surfaces of the pair of targets satisfies the first film formation condition of the initial layer. Then, if it is determined that the initial layer formation is completed, each target is changed in direction (in posture) again so as to satisfy a first film formation condition of the second layer.

As a result, the initial layer can be formed according to the first film formation condition of the initial layer, and the film formation can be performed on the substrate requiring the low-temperature·low-damage film formation in the shortest film formation time without causing damage or without forming the initial layer thicker than necessary.

Furthermore, since the detection unit for detecting the temperature is provided in the vicinity of the substrate and at the position facing the flow path of the sputtered particles, the temperature of the film formation target surface of the substrate can be detected. In this way, by detecting the temperature of the film formation target surface while performing the film formation, the value (detection value) of a variation in the temperature per unit time (increase in the temperature) can be detected.

Moreover, the control unit compares the detection value detected by the detection unit with a second film formation condition of the initial layer (a temperature at which the interface of the substrate in need of the low-temperature·low-damage film formation is not damaged and an increase in the temperature during the film formation time), and if it is determined that the detection value is different from the second film formation condition of the initial layer, each target is changed in direction (in angle) so that the angle formed between the facing surfaces of the pair of the targets satisfies the second film formation condition of the initial layer. Then, if it is determined that the initial layer formation is completed, each target is changed in direction (in posture) so as to satisfy a second film formation condition of the second layer.

As a result, the initial layer can be formed according to the second film formation condition of the initial layer and the film formation can be performed on the substrate in need of the low-temperature·low-damage film formation in the shortest film formation time without causing damage or without forming the initial layer thicker than necessary.

Furthermore, since the detection unit for detecting the film thickness and the temperature is provided in the vicinity of the substrate and at the position facing the flow path of the sputtered particles, the thickness of the thin film formed on the film formation target surface of the substrate and the temperature of the film formation target surface of the substrate can be detected. In this way, by detecting the film thickness and the temperature of the film formation target surface while performing the film formation, the value of the variation in the film thickness per unit time and the value (detection value) of the variation in the temperature per unit time (increase in the temperature) can be detected.

Furthermore, the control unit compares the detection value of the film thickness variation and the detection value of the temperature variation detected by the detection unit with the first film formation condition and with the second film formation condition of the initial layer, respectively. If it is determined that at least one of the detection value of the film thickness variation and the detection value of the temperature variation is different from the first film formation condition or the second film formation condition of the initial layer, each target is changed in direction (in angle) so that the angle formed between the facing surfaces of the pair of the targets satisfies at least one of the first and second film formation conditions for the initial layer. Then, if it is determined that the initial layer formation is completed, each target is changed in direction in posture so as to satisfy the first and second film formation conditions of the second layer.

As a result, since the initial layer can be formed according to the first and second film formation conditions of the initial layer, the film formation can be more efficiently performed on the substrate in need of the low-temperature·low-damage film formation in the shortest film formation time without causing damage or without forming the initial layer thicker than necessary, as compared to the case where either one of the film thickness and the temperature can be detected.

### Effect of the Invention

In accordance with the present invention, there is provided a sputtering method and a sputtering apparatus having a simple structure and capable of performing a low-temperature·low-damage film formation and exhibiting high productivity even when film formations are performed consecutively on a plurality of substrates.

### BRIEF DESCRIPTION OF THE DRAWINGS

FIG. 1 is a schematic configuration view of a sputtering apparatus in accordance with a first embodiment;

FIG. 2A is a transversal cross sectional view of a curved magnetic field generating unit of the sputtering apparatus in accordance with the first embodiment, in which the curved magnetic field generating unit is coupled to a target via a backing plate; FIG. 2B is a front view thereof; and FIG. 2C is a cross sectional view thereof taken along line A-A;

FIG. 3A is a front view of an auxiliary magnetic field generating unit of the sputtering apparatus in accordance with the first embodiment; FIG. 3B is a cross sectional view thereof taken along line A-A; FIG. 3C is a cross sectional view thereof taken along line B-B; and FIG. 3D is a partially enlarged cross sectional view of an installation state thereof;

FIG. 4 is a schematic configuration view of a sputtering apparatus in accordance with a second embodiment;

FIG. 5 is a schematic configuration view of a sputtering apparatus in accordance with a third embodiment;

FIG. 6 is a schematic configuration view of a sputtering apparatus in which a plurality of first film forming units and a multiple number of second film forming units in accordance with the first embodiment are arranged in juxtaposition in a first film formation region and a second film formation region, respectively;

FIG. 7 is a schematic configuration view of a sputtering apparatus in which a plurality of second film forming units in accordance with the second embodiment is arranged in juxtaposition in a second film formation region;

FIG. 8 is a schematic configuration view of a sputtering apparatus in which a plurality of second film forming units in accordance with the third embodiment is arranged in juxtaposition in a second film formation region;

FIG. 9 is a schematic configuration view of a sputtering apparatus in which a plurality of second film forming units in accordance with the second embodiment is arranged in juxtaposition in a second film formation region and an elongated substrate is held on a substrate holder such that its lengthwise direction coincides with the arrangement direction of the second film forming units;

FIG. 10 is a schematic configuration view of a sputtering apparatus connected to an AC power supply capable of applying AC electric fields having a phase difference of about 180° to a pair of cathodes in a first film forming unit in the second embodiment;

FIG. 11A is a schematic configuration view of a sputtering apparatus in which a film formation target surface of a substrate is moved along a line T-T, and FIG. 11B is a schematic configuration view of a sputtering apparatus in which a film formation target surface is moved along a revolution orbit;

FIG. 12 is a schematic configuration view of a sputtering apparatus in accordance with a fourth embodiment, showing a state where an angle formed between facing surfaces of targets is small;

FIG. 13 is a schematic configuration view of the sputtering apparatus in accordance with the fourth embodiment, showing a state where an angle formed between facing surfaces of targets is large;

FIG. 14A is a transversal cross sectional view of a curved magnetic field generating unit of the sputtering apparatus in accordance with the fourth embodiment, in which the curved magnetic field generating unit is coupled to a target via a backing plate; FIG. 14B is a front view thereof; and FIG. 14C is a cross sectional view thereof taken along line A-A;

FIG. 15A is a front view of an auxiliary magnetic field generating unit of the sputtering apparatus in accordance with the fourth embodiment; FIG. 15B is a cross sectional view thereof taken along line A-A; FIG. 15C is a cross sectional view thereof taken along line B-B; and FIG. 15D is a partially enlarged cross sectional view of an installation state thereof;

FIG. 16A is a front view of a target holder rotation unit of the sputtering apparatus in accordance with the fourth embodiment, and FIG. 16B is a schematic plane view showing a moving direction thereof;

FIG. 17A is a schematic configuration view of target holder rotation units in accordance with another embodiment having two cylinders, and FIG. 17B is a schematic configuration view thereof having one cylinder;

FIG. 18A is a schematic configuration view of a sputtering apparatus including magnetron cathodes having no cylindrical auxiliary magnetic field generating unit in accordance with another embodiment; FIG. 18B is a schematic configuration view of a sputtering apparatus including facing target type cathodes in accordance with another embodiment; and FIG. 18C is a schematic configuration view of a sputtering apparatus including facing target type cathodes having a cylindrical auxiliary magnetic field generating unit in accordance with another embodiment;

FIG. 19 is a schematic configuration view of a sputtering apparatus using an AC power supply in accordance with another embodiment;

FIG. 20 is a schematic plane view showing a target moving direction in accordance with another embodiment;

FIG. 21A is a schematic configuration view of a sputtering apparatus in accordance with another embodiment in which a film formation target surface is moved along a line A-A line, and FIG. 21B is a schematic configuration view of the sputtering apparatus in accordance with another embodiment in which the film formation target surface is moved along a revolution orbit; and

FIG. 22 is a schematic configuration view of a sputtering apparatus including a detection unit in accordance with another embodiment.

### EXPLANATION OF CODES

1, 1′, 1″: Sputtering apparatus

2: Vacuum chamber

3: Substrate holder

4a, 4′a, 4b, 4′b, 4″b: Sputtering power supply

5: Evacuation unit

6: Sputtering gas supply unit

6′, 6″: Nonreactive gas introduction pipe

7: Reactive gas supply unit

7′, 7″: Reactive gas introduction pipe

8, 8′: Communication passage

9, 9′: other processing chambers (or load lock chambers)

10a, 10b, 110a, 110b, 110′, 110″a, 110″b: Target

10a′, 10b′, 110a′, 110b′, 110′a′, 110″a′, 110″b′: Sputtering surface (facing surface, surface)

11a, 11b, 111a, 111b, 111′, 111″a, 111″b: Cathode (target holder)

12a, 12b, 112a, 112b, 112′, 112″a, 112″b: Backing plate

20a, 20b, 120a, 120b, 120′, 120″a, 120″b: Curved magnetic field generating unit

21a, 21b, 121a, 121b, 121′, 121″a, 121″b: Frame-shaped magnet (permanent magnet)

22a, 22b, 122a, 122b, 122′, 122″a, 122″b: Central magnet (permanent magnet)

23a, 23b, 123a, 123b, 123′, 123″a, 123″b: Yoke

30a, 30b, 130a, 130b: Cylindrical auxiliary magnetic field generating unit (permanent magnet)

201: Sputtering apparatus

202: Vacuum chamber

203: Sputtering power supply unit

204: Substrate holder

205: Evacuation unit

206: Gas supply unit

206′: Nonreactive gas introduction pipe

207: Communication passage

208: Load lock chambers (other processing chambers)

209: Target holder rotation unit

210a, 210b: Target

210a′, 210b′: Sputtering surface (facing surface, surface)

211a, 211b: Target holder

212a, 212b: Backing plate

215: Control unit

216: Detection unit controller

217: Target holder rotation unit controller

220a, 220b: Curved magnetic field generating unit

220′a, 220′b: Inter-target magnetic field generating unit

221a, 221b: Frame-shaped magnet (permanent magnet)

222a, 222b: Central magnet (permanent magnet)

223a, 223b: Yoke

230a, 230b: Cylindrical auxiliary magnetic field generating unit (permanent magnet)

250: Control unit (controller)

B: Substrate

B′: Film formation target surface

D: Detection unit (detecting sensor)

d, d1, d2: Distance between target centers

F1: First film formation region

F2: Second film formation region

K, K1, K2: Inter-target space (space)

M, M′: Rotation shaft of the target holder rotated by the target holder rotation unit

L1: First film formation position

L2, L′2, L″2: Second film formation position

P1: First film forming unit

P2, P′2, P″2: Second film forming unit

Q: Reactive gas introduction pipe

R: Inter-target magnetic field space

S: Inner space

Ta, Tb, T1a, T1b, T2a, T2b, T′2, T″2a, T″2b: Target center

t, t1, t2: Cylindrical auxiliary magnetic field space

W, W1, W1′, W2, W2′, W′2, W″2, W″2′: Curved magnetic field space

### BEST MODE FOR CARRYING OUT THE INVENTION

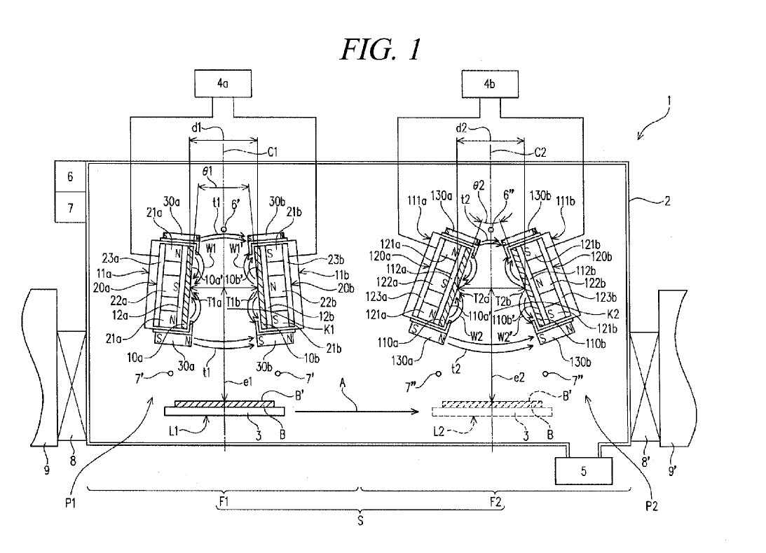

Hereinafter, a first embodiment of the present invention will be described with reference to FIGS. 1 to 3.

As depicted in FIG. 1, a sputtering apparatus 1 includes a vacuum chamber 2 having an inner space S; a first film forming unit P1 and a second film forming unit P2 for forming a film on a film formation target surface B′ of a substrate B which is a target object on which a film is to be formed; and a holder (hereinafter, referred to as a substrate holder) 3 capable of moving inside the vacuum chamber 2 at least from a first film formation position L1, where a film formation is performed on the substrate B in the first film forming unit P1, to a second film formation position L2, where a film formation is performed on the substrate B in the second film forming unit P2 (moving in an arrow A direction), while holding the substrate B thereon.

Further, the sputtering apparatus 1 includes a first sputtering power supply 4a for supplying a sputtering power to the first film forming unit P1; a second sputtering power supply 4b for supplying a sputtering power to the second film forming unit P2; an evacuation unit 5 for evacuating the inside (inner space S) of the vacuum chamber 2; and a sputtering gas supply unit 6 for supplying a sputtering gas into the vacuum chamber 2. Further, the vacuum chamber 2 may be provided with a reactive gas supply unit 7 for supplying a reactive gas to the vicinity of the substrate B.

The vacuum chamber 2 is connected to other processing chambers or load lock chambers 9 and 9′ via communication passages (substrate transfer line valves) 8 and 8′ provided at the vacuum chamber 2′s both ends on the side of the substrate holder 3 (lower end side of the drawing).

The inner space S of the vacuum chamber 2 includes a first film formation region F1 in which the first film forming unit P1 is installed and a second film formation region F2 in which the second film forming unit P2 is installed, wherein the first film forming unit P1 and the second film forming unit P2 are arranged in juxtaposition.

The first film forming unit P1 includes a pair of first cathodes (first target holders) 11a and 11b having first targets 10a and 10b at their front ends, respectively. This pair of first cathodes 11a and 11b are arranged such that surfaces 10a′ and 10b′ of the first targets 10a and 10b face each other while spaced apart from each other at a certain distance.

The first cathode 11a (11b) includes the first target 10a (10b) fixed to a front end portion thereof via a backing plate 12a (12b); a first curved magnetic field generating unit 20a (20b) installed at a rear surface (a surface opposite to a surface where the first target 10a (10b) is fixed) of the backing plate 12a (12b), for generating a magnetic field space curved in an arc shape on the side of the first target surface (facing surface) 10a′ (10b′); and a first cylindrical auxiliary magnetic field generating unit 30a (30b) fitted onto a front end portion of one first cathode 11a (11b), for generating a cylindrical magnetic field space between one first cathode 11a (11b) and the vicinity of the other first cathode 11b (11a).

To elaborate, the two facing surfaces 10a′ and 10b′ of the first targets 10a and 10b are arranged such that they are inclined toward the direction of the lateral position of the pair of first targets 10a and 10b and the first film formation position L1 where a film formation is performed on the substrate B in the first film forming unit P1 as will be described later. Here, an angle θ1 between the two facing surfaces 10a′ and 10b′, to be specific, an angle θ1 between two surfaces extended from the two facing surfaces 10a′ and 10b′ is set to be in a range of about 0° to 60°. This angle θ1 is set to be small such that charged particles such as secondary electrons or plasma generated during the sputtering may not damage the film formation target surface B′ of the substrate B beyond a tolerance limit. In the present embodiment, the angle θ1 is set to be in a range of about 0° to 45° , and desirably, in a range of about 5° to 20°.

Further, in the first embodiment and other embodiments to be described later, a cathode which generates curved magnetic field spaces on a facing surface of a target may be referred to as a “magnetron cathode”; a cathode including the magnetron cathode and the cylindrical auxiliary magnetic field generating unit may be referred to as a “complex type cathode”; and a pair of cathodes having the arrangement such that the two facing surfaces of the targets disposed in the complex type cathodes form a substantially V-shape may be referred to as “complex V-type cathodes”.

In the present embodiment, each of the first targets 10a and 10b is made of ITO (Indium Tin Oxide). Each of the first targets 10a and 10b is formed of a rectangular plate-shaped member having a size of about 125 mm (width)×300 mm (length)×5 mm (thickness). The first targets 10a and 10b are disposed to face each other in the first film forming unit P1 (the first film formation region F1) inside the vacuum chamber 2, and the facing surfaces (surfaces to be sputtered) 10a′ and 10b′ are spaced apart from each other at a predetermined distance d1 (here, the distance d1 between centers T1a and T1b of the facing surfaces 10a′ and 10b′ is set to be about 160 mm).

The first curved magnetic field generating unit 20a (20b) generates (forms) the magnetic field spaces having arc-shaped magnetic force lines (curved magnetic field spaces W1 and W1′: see arrows W1 and W1′ of FIG. 1) in the vicinity of the facing surface 10a′ (10b′) of the first target 10a (10b). In the present embodiment, they are made of permanent magnets.

The first curved magnetic field generating unit (permanent magnet) 20a (20b) is made of a ferromagnetic substance such as a ferrite-based or neodymium-based (e.g., neodymium, iron or boron) magnet or a samarium·cobalt-based magnet. In the present embodiment, they are made of ferrite-based magnets.

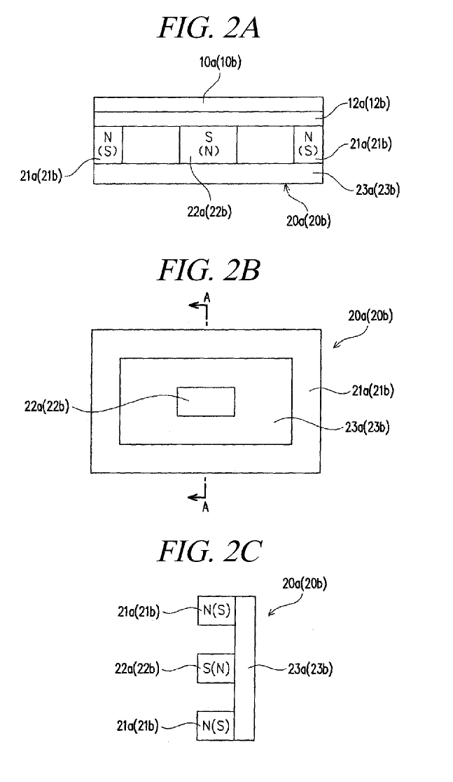

As illustrated in FIGS. 2A to 2C, the first curved magnetic field generating unit 20a (20b) has a configuration in which a frame-shaped magnet 21a (21b) and a central magnet 22a (22b) having a magnetic pole opposite to that of the frame-shaped magnet 21a (21b) is disposed at a yoke 23a (23b). To be more specific, the first curved magnetic field generating unit 20a (20b) is configured such that the framed-shaped magnet 21a (21b) and the central magnet 22a (22b) are fixed to the yoke 23a (23b). The framed-shaped magnet 21a (21b) has a rectangular frame shape when viewed from the front. The central magnet 22a (22b) has a rectangular shape when viewed from the front and are located at the center of an opening of the frame-shaped magnet 21a (21b). The yoke 23a (23b) has the same outer circumference shape as the frame-shaped magnet 21a (21b) and has a plate shape of a certain thickness when viewed from the front (see FIG. 2B and FIG. 2C).

One first curved magnetic field generating unit 20a is disposed on a rear surface of the backing plate 12a such that the frame-shaped magnet 21a has a N (S) pole at lateral end portions of the backing plate 12a (i.e., at lateral end portions of the yoke 23a) while the central magnet 22a has a S (N) pole. The other first curved magnetic field generating unit 20b is disposed on a rear surface of the backing plate 12b such that the frame-shaped magnet 21b has a S (N) pole at lateral end portions of the backing plate 12b (i.e., at lateral end portions of the yoke 23b) while the central magnet 22b has a N (S) pole. In such a configuration, formed at one first target 10a is the inwardly curved magnetic field space W1 having magnetic force lines oriented from an outer peripheral portion of the first target surface (facing surface) 10a′ toward a central portion thereof in an arc shape, whereas formed at the other first target 10b is the outwardly curved magnetic field space W2 having magnetic force lines oriented from a central portion of the first target surface (facing surface) 10b′ to an outer peripheral portion thereof in an arc shape. Further, the inwardly curved magnetic field space W1 and the outwardly curved magnetic field space W2 together may be simply referred to as a “curved magnetic field space W.”

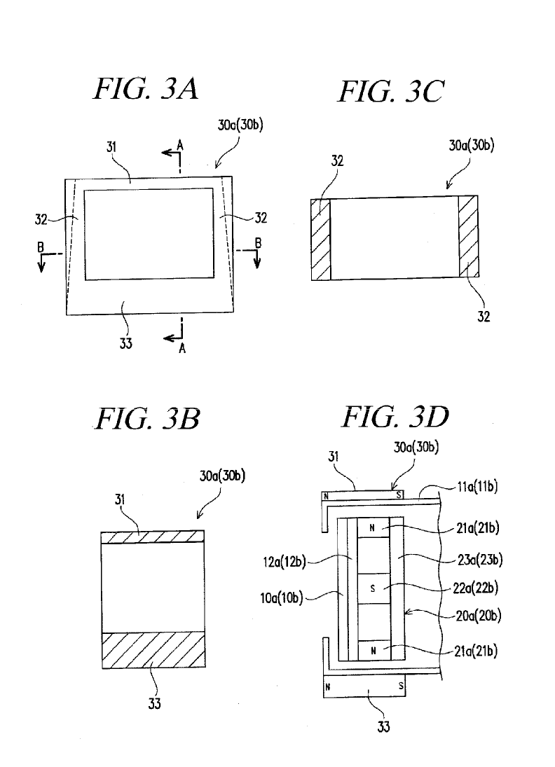

Like the first curved magnetic field generating units 20a and 20b, each of the first cylindrical auxiliary magnetic field generating unit 30a and 30b is made of a permanent magnet and formed in a square (rectangular) tube shape conforming to (capable of being fitted onto) the outer periphery of the front end portion of the first cathode (target holder) 11a (11b), as depicted in FIGS. 3A to 3D. In the present embodiment, each of the first cylindrical auxiliary magnetic field generating units 30a and 30b is made of a neodymium-based magnet such as neodymium, iron or boron magnet and formed in a rectangular frame shape when viewed from the front and formed in a square (rectangular) tube shape having a peripheral wall whose forward-backward directional thickness is uniform (see FIG. 3B and FIG. 3C). The peripheral wall forming the first cylindrical auxiliary magnetic field generating unit 30a (30b) is configured such that the thickness thereof is the thinnest at a ceiling wall 31; thicker at sidewalls 32; and the thickest at a bottom wall 33 which is positioned on the side of the substrate B when fitted onto the first cathode 11a (11b), as will be described later. Further, in the present embodiment, though the first cylindrical auxiliary magnetic field generating unit 30a (30b) is formed in a square (rectangular) tube shape, it may be formed in a cylindrical shape or the like, as long as it may be configured to surround the first targets 10a and 10b.

The thickness of the peripheral wall is set such that the strength of magnetic field at midway points between the corresponding front ends of the pair of first cylindrical auxiliary magnetic field generating units 30a and 30b is constant. Accordingly, a difference in the thickness varies depending on the angle θ1 formed between the two facing surfaces 10a′ and 10b′. Therefore, when the angle θ1 increases, the thickness of the sidewalls 32 may gradually increase from the ceiling wall 31 toward the bottom wall 33 (see dashed lines in FIG. 3A).

The first cylindrical auxiliary magnetic field generating unit 30a (30b) is fitted onto the outer periphery of the front end of the first cathode 11a (11b) such that the polarity of the front end thereof is the same as that of the frame-shaped magnet 21a (21b) of the first curved magnetic field generating unit 20a (20b) (see FIG. 3D). With this arrangement, formed is a cylindrical auxiliary magnetic field space t1 which surrounds a space (inter-target space) K1 formed between the first targets 10a and 10b and has magnetic force lines oriented from one first target 10a toward the other first target 10b (see an arrow t1 of FIG. 1).

The second film forming unit P2 includes a pair of second cathodes (second target holders) 111a and 111b having second targets 110a and 110b at their front ends, respectively. This pair of second cathodes 111a and 111b are arranged such that surfaces 110a′ and 110b′ of the second targets 110a and 110b face each other while spaced apart from each other at a certain distance.

Like the first cathode 11a (11b) of the first film forming unit P1, the second cathode (second target holder) 111a (111b) includes the second target 110a (110b) fixed to a front end portion thereof via a backing plate 112a (112b); a second curved magnetic field generating unit 120a (120b) installed at a rear surface of the backing plate 112a (112b), for generating a magnetic field space curved in an arc shape at the second target surface (facing surface) 110a′ (110b′); and second cylindrical auxiliary magnetic field generating units 130a (130b) fitted onto front end portion of one second cathode 111a (111b), for generating a cylindrical magnetic field space between one second cathode 111a (111b) and the vicinity of the other second cathode 111b (111a).

To elaborate, the two facing surfaces 110a′ and 110b′ of the second targets 110a and 110b are arranged such that they are located laterally between the pair of second targets 110a and 110b and inclined toward the second film formation position L2 where a film formation is performed on the substrate B in the second film forming unit P2 as will be described later. Here, an angle θ2 between the two facing surfaces 110a′ and 110b′ is set to be in a range of about 45° to 180° and to be larger than the angle θ1 formed between the two facing surfaces 10a′ and 10b′ of the first targets 10a and 10b (that is, θ1<θ2). Though, with such an angle θ2, though the influence of plasma on the substrate B and the amount of charged particles such as secondary electrons flying to the substrate B increase during the sputtering in comparison to the angle θ1, a film forming rate increases in comparison to the angle θ1. More desirably, the angle θ2 is set to be in a range of about 60° to 120° (when θ1 ranges from about 5° to 20° and θ1<θ2). In the present embodiment, the angle θ2 is about 45° (when θ1 is about 20°.

In the present embodiment, each of the pair of second targets 110a and 110b is made of ITO (Indium Tin Oxide), like the pair of first targets 10a and 10b in the first film forming unit P1. Like the first targets 10a and 10b, each of the second targets 110a and 110b is formed of a rectangular plate-shaped member having a size of about 125 mm (width)×300 mm (length)×5 mm (thickness). The second targets 110a and 110b are disposed to face each other in the second film forming unit P2 (the second film formation region F2) inside the vacuum chamber 2, and the facing surfaces (sputtered surfaces) 110a′ and 110b′ are spaced apart from each other at a predetermined distance d2 (here, the distance d2 between centers T2a and T2b of the facing surfaces 110a′ and 110b′ is set to be about 160 mm (=d1)). Further, in the present embodiment, though the first targets 10a and 10b and the second targets 110a and 110b are configured to have the same shape, it is not limited thereto and they may have different sizes or shapes. Furthermore, in the present embodiment, though the first and second targets 10a, 10b and 110a, 110b are disposed in the first and second film formation regions F1 and F2 by the first and second cathodes 11a, 11b and 111a, 111b, respectively, such that d1=d2, they may be disposed such that d1 and d2 may be different.

The second curved magnetic field generating unit 120a (120b) generates (forms) a magnetic field space having arc-shaped magnetic force lines (curved magnetic field spaces W2 and W2′: see arrows W2 and W2′ of FIG. 1) in the vicinities of the facing surfaces 110a′ and 110b′ of the second targets 110a and 110b. In the present embodiment, they are made of permanent magnets.

Like the first curved magnetic field generating unit 20a (20b), the second curved magnetic field generating unit (permanent magnet) 120a (120b) is made of a ferromagnetic substance such as a ferrite-based or neodymium-based magnet or a samarium·cobalt-based magnet. In the present embodiment, they are made of ferrite-based magnets.

The second curved magnetic field generating unit 120a (120b) has the same configuration as the first curved magnetic field generating unit 20a (20b), i.e., has a configuration in which a frame-shaped magnet 121a (121b) and a central magnet 122a (122b) having a magnetic pole opposite to that of the frame-shaped magnet 121a (121b) are positioned on a yoke 123a (123b). To be more specific, the second curved magnetic field generating unit 120a (120b) is configured such that the framed-shaped magnet 121a (121b) and the central magnet 122a (122b) are fixed to the yoke 123a (123b). The framed-shaped magnet 121a (121b) has a rectangular frame shape when viewed from the front, and the central magnet 122a (122b) has a rectangular shape when viewed from the front and is located at the center of an opening of the frame-shaped magnet 121a (121b). The yoke 123a (123b) has the same outer circumference shape as the frame-shaped magnet 121a (121b) and has a plate shape of a certain thickness when viewed from the front.

One second curved magnetic field generating unit 120a is disposed on a rear surface of the backing plate 112a such that the frame-shaped magnet 121a has a N (S) pole at lateral end portions of the backing plate 112a (i.e., at lateral end portions of the yoke 123a) while the central magnet 122a has a S (N) pole. The other second curved magnetic field generating unit 120b is disposed on a rear surface of the backing plate 112b such that the frame-shaped magnet 121b has a S (N) pole at lateral end portions of the backing plate 112b (i.e., at the lateral end portions of the yoke 123b) while the central magnet 122b has a N (S) pole. In such a configuration, formed at one second target 110a is an inwardly curved magnetic field space W2 having magnetic force lines oriented from an outer peripheral portion of the second target surface (facing surface) 110a′ toward a central portion thereof in an arc shape, whereas formed at the other second target 110b is an outwardly curved magnetic field space W2′ having magnetic force lines oriented from a central portion of the second target surface (facing surface) 110b′ toward an outer peripheral portion thereof in an arc shape.

Like the first curved magnetic field generating units 20a and 20b in the first film forming unit P1, each of the second cylindrical auxiliary magnetic field generating units 130a and 130b is made of a permanent magnet and has the same configuration as the first cylindrical auxiliary magnetic field generating units 30a and 30b, i.e., formed in a square (rectangular) tube shape conforming to (capable of being fitted onto) the outer periphery of the front end portions of the second cathode (target holder) 111a (111b). In the present embodiment, each of the second cylindrical auxiliary magnetic field generating units 130a and 130b is made of a neodymium-based magnet such as neodymium, iron or boron magnet and formed in a rectangular frame shape when viewed from the front and formed in a square (rectangular) tube shape having a peripheral wall whose forward-backward directional thickness is uniform. The peripheral wall forming the second cylindrical auxiliary magnetic field generating unit 130a (130b) is configured such that the thickness thereof is the thinnest at a ceiling wall; thicker at sidewalls; and the thickest at a bottom wall. Further, like the first cylindrical auxiliary magnetic field generating unit 30a (30b), the second cylindrical auxiliary magnetic field generating unit 130a (130b) may be formed in a different shape other than the square column shape if it is disposed to surround the second targets 110a and 110b.

The thickness of the peripheral wall is set such that the strength of magnetic field at midway points between the corresponding front ends of the pair of second cylindrical auxiliary magnetic field generating units 130a and 130b is uniform, like the pair of first cylindrical auxiliary magnetic field generating units 30a and 30b in the first film forming unit P1.

The second cylindrical auxiliary magnetic field generating unit 130a (130b) is fitted onto the outer periphery of the front end of the second cathode 111a (111b) such that the polarity of the front end thereof is the same as that of the frame-shaped magnet 121a (121b) of the second curved magnetic field generating unit 120a (120b). With this arrangement, formed is a cylindrical auxiliary magnetic field space t2 which surrounds a space (inter-target space) K2 formed between the second targets 110a and 110b and has magnetic force lines oriented from one second target 110a toward the other second target 110b (see an arrow t2 of FIG. 1).

As described above, the first film forming unit P1 and the second film forming unit P2 have the same configuration except for the angle θ1 (θ2) formed between the two facing surfaces 10a′ and 10b′ (110a′ and 110b′) of the pair of targets 10a and 10b (111a and 111b). The first film forming unit P1 and the second film forming unit P2 having the above-described configuration are arranged in juxtaposition inside the vacuum chamber 2. To elaborate, the first cathodes 11a and 11b of the first film forming unit P1 and the second cathodes 111a and 111b of the second film forming unit P2 are juxtaposed in a row within the vacuum chamber 2. To be more specific, the centers T1a, T1b and T2a, T2b of the first and second targets 10a, 10b and 110a, 110b lie on the same line, respectively, and a first central surface C1 of the pair of inclined facing targets 10a and 10b and a second central surface C2 of the pair of inclined facing targets 111a and 111b are parallel or substantially parallel to each other, as will be described later.

The first sputtering power supply 4a is capable of applying a DC constant power or constant current, and it supplies a sputtering power while the vacuum chamber 2 at a ground potential (earth potential) serves as an anode and the first targets 10a and 10b serve as cathodes. Further, the second sputtering power supply 4b is capable of applying a DC constant power or constant current, and it supplies a sputtering power while the vacuum chamber 2 at a ground potential (earth potential) serves as an anode and the second targets 110a and 110b serve as cathodes.

Further, in the present embodiment, though the first and second sputtering power supplies 4a and 4b are capable of supplying a DC constant power, it is not limited thereto. That is, the sputtering power supplies 4a and 4b can be appropriately modified depending on the material of the targets and the kind of a thin film to be formed (e.g., a metal film, an alloy film, a compound film, or the like). They may be a RF power supply, a MF power supply, or the like, and it may be also possible to use a DC power supply and a RF power supply in combination. Further, it may be also possible to connect one DC power supply or one RF power supply to each cathode. Moreover, the first and second sputtering power supplies 4a and 4b need not be of the same type, but they may be of different types.

The substrate holder 3 includes a moving mechanism (not shown) capable of holding the substrate B thereon and capable of moving, while holding the substrate B thereon, at least from the first film forming unit P1 to the second film forming unit P2, more particularly, from the first film formation position L1 where a film formation is performed on the substrate B in the first film forming unit P1 to the second film formation position L2 where a film formation is performed on the substrate B in the second film forming unit P2. Further, when the substrate holder 3 is moved by the moving mechanism, the substrate holder 3 is moved such that the film formation target surface B′ of the substrate B held thereon faces the direction of the first cathodes 11a and 11b of the first film forming unit P1 at the first film formation position L1 and the direction of the second cathodes 111a and 111b of the second film forming unit P2 at the second film formation position L2.

In the present embodiment, the substrate holder 3 serves to load the substrate B into the vacuum chamber 2 from one processing chamber (load lock chamber) 9 at one side of the vacuum chamber 2 and unload the substrate B to another processing chamber (load lock chamber) 9′ at the other side thereof after performing the film formation on the film formation target surface B′ in the first and second film forming units P1 and P2. Therefore, the substrate holder 3 moves along a line connecting one processing chamber 9 at one side and another processing chamber 9′ at the other side so as to cross the inner space S of the vacuum chamber 2 in a direction from the first film formation region F1 to the second film formation region F2.

The first film formation position L1 and the second film formation position L2 are positioned (exist) on the line connecting the other processing chambers 9 and 9′ connected to both lateral sides of the vacuum chamber 2. To elaborate, when the substrate holder 3 holding the substrate B thereon is located at the first film formation position L1, the film formation target surface B′ of the substrate B faces the center between the first targets 10a and 10b and becomes perpendicular to the surface (first central surface) C1 which bisects the angle θ1 formed between the facing surfaces 10a′ and 10b′, and the shortest distance e1 between a straight line (T1-T1 line) connecting the centers T1a and T1b of the two facing surfaces 10a′ and 10b′ of the first targets 10a and 10b and the center of the film formation target surface B′ becomes equal to about 175 mm (e1=175 mm).

Further, when the substrate holder 3 holding the substrate B thereon is located, the second film formation position L2 is positioned such that the film formation target surface B′ of the substrate B faces the center between the first targets 110a and 110b and becomes perpendicular to the surface (second central surface) C2 which bisects the angle θ2 between the facing surfaces 110a′ and 110b′, and the shortest distance e2 between a straight line (T2-T2 line) connecting the centers T2a and T2b of the two facing surfaces 110a′ and 110b′ of the second targets 110a and 110b becomes equal to about 175 mm (e2=175 mm (=e1)).

The evacuation unit 5 is connected to the vacuum chamber 2 so as to evacuate the vacuum chamber 2 and is used to lower the pressure in the inner space S by evacuating the vacuum chamber 2.

The sputtering gas supply unit 6 is connected to the vacuum chamber 2 so as to supply an electric discharge gas (sputtering gas) between the targets. The sputtering gas supply unit 6 includes a first nonreactive gas introduction pipe 6′ disposed in the vicinity of the first targets 10a and 10b, for supplying a nonreactive gas (in the present embodiment, an argon (Ar) gas) and a second nonreactive gas introduction pipe 6″ disposed in the vicinity of the second targets 110a and 110b. Further, the sputtering gas supply unit 6 may supply the nonreactive gas to both the first nonreactive gas introduction pipe 6′ and the second nonreactive gas introduction pipe 6″ or may be switched to supply the nonreactive gas to only one of them.

Further, it may be also possible to install, in the vicinity of the first and second film formation positions L1 and L2, the reactive gas supply unit 7 together with first reactive gas introduction pipes 7′ and 7′ and second reactive gas introduction pipes 7″ and 7″ for introducing reactive gases such as O₂ and N₂ toward the first film formation position L1 and the second film formation position L2 from the reactive gas supply unit 7, respectively, in order to manufacture a thin film of dielectric such as oxide or nitride. Moreover, the reactive gas supply unit 7 may supply the reactive gas to both of the first reactive gas introduction pipes 7′ and 7′ and the second reactive gas introduction pipes 7″ and 7″ or may be switched to supply the reactive gas to either of them.

The substrate B is a film formation target object having the film formation target surface B′ on which a thin film is to be formed. In the present embodiment, a relationship between the size of the substrate B and the size of targets 10a and 10b for use in the sputtering is generally related with the required degree of film thickness distribution uniformity within the substrate surface (film formation target surface) B′. When the film thickness distribution uniformity is within about ±10%, a relationship between a substrate width S_{W} (mm) of the substrate B, which corresponds to a length of the targets 10a and 10b in a lengthwise direction thereof, and a lengthwise size T_{L} (mm) of the targets 10a and 10b, which corresponds to a length of the substrate B in a widthwise direction thereof, is represented as S_{W}≦T_{L}×0.6˜0.7. Accordingly, in the sputtering apparatus 1 in accordance with the present embodiment, since the rectangular targets each having a size of 125 mm (width)×300 mm (length)×5 mm (thickness) are used, the film formation can be carried out on the substrate B having a substrate width S_{W} of about 200 mm derived from the above-mentioned relationship. In addition, the sputtering apparatus 1 has a configuration in which the film formation is carried out while the substrate is transferred within the apparatus (i.e., the sputtering is performed while the substrate B is transferred in left-right direction of FIG. 1), so that the apparatus can perform the film formation on a substrate having a length equal to or larger than the width thereof even though the length of the substrate B is limited by the size of the apparatus. For example, in the present embodiment, it is be possible to perform the film formation on the substrate B having a size of about 200 mm (width)×200 mm (length), 200 mm (width)×250 mm (length) or 200 mm (width)×300 mm (length) within the range of film thickness distribution of about ±10%. At this time, the substrate B such as an organic EL device or an organic thin film semiconductor, which requires a low-temperature·low-damage film formation, may be used as the substrate B having the film formation target surface B′ on which the thin film is to be formed by the sputtering.

In addition, in the present embodiment, the width of the substrate B corresponds to a length along the lengthwise direction of the targets 10a and 10b, while the length of the substrate B corresponds to a length along a direction perpendicular to the lengthwise direction of the targets 10a and 10b (left-right direction of FIG. 1).

Furthermore, in the present embodiment, a substrate such as an organic EL device or an organic semiconductor, which requires a low-temperature·low-damage film formation, may be used as the substrate B having the film formation target surface B′ on which the thin film is to be formed by the sputtering.

The sputtering apparatus 1 in accordance with the first embodiment is configured as described above, and an operation of a thin film formation in the sputtering apparatus 1 will be described hereinafter.

When carrying out a thin film formation on the film formation target surface B′ of the substrate B in the present embodiment, a second layer is formed by the sputtering enabling a high film forming rate after forming an initial layer (first layer) by the sputtering capable of enabling a low-temperature·low-damage film formation (i.e., a low film forming rate), so that a thin film having a necessary film thickness is formed on the film formation target surface B′. This process will be explained in detail hereinafter. Here, it should be noted that the initial layer (first layer) and the second layer are only distinguished for the purpose of explanation by an imaginary surface where the film forming rate is changed in a film thickness direction of a thin film, and the thin film is not actually divided as separate layers in the film thickness direction, but formed as a continuous single thin film.

First, when forming the initial layer, the substrate B is held on the substrate holder 3, and the substrate holder 3 is placed at the first film formation position L1 (the position of the substrate B and the substrate holder 3 shown by a solid line of FIG. 1).

Then, the vacuum chamber 2 is evacuated by the evacuation unit 5. Thereafter, an argon gas (Ar) is introduced from the first and second nonreactive gas introduction pipes 6′ and 6″ by the sputtering gas supply unit 6, and a preset sputtering operation pressure (here, about 0.4 Pa) is set.

Afterward, a sputtering power is supplied to the first targets 10a and 10b by the first sputtering power supply 4a. At this time, since the first curved magnetic field generating units 20a and 20b and the first cylindrical auxiliary magnetic field generating units 30a and 30b are made of permanent magnets, the first curved magnetic field spaces (first inwardly and outwardly curved magnetic field spaces) W1 and W1′ are formed on the facing surfaces 10a′ and 10b′ of the first targets 10a and 10b, respectively, by the first curved magnetic field generating units 20a and 20b. Further, the cylindrical auxiliary magnetic field space t1 is formed to surround the column-shaped space K1 formed between the facing surfaces 10a′ and 10b′ of the first targets 10a and 10b by the first cylindrical auxiliary magnetic field generating units 30a and 30b.

Then, plasma is generated within the first curved magnetic field spaces W1 and W1′, and the facing surfaces 10a′ and 10b′ of the first targets 10a and 10b are sputtered, and (first) sputtered particles are emitted. Plasma escaped from the first curved magnetic field spaces W1 and W1′ or charged particles such as secondary electrons released therefrom are trapped, by the first cylindrical auxiliary magnetic field space t1, in the space (first inter-target space) K1 surrounded by the first cylindrical auxiliary magnetic field space t1.

Accordingly, the sputtered particles (first sputtered particles) emitted (ejected due to collisions) from the sputtering surfaces (facing surfaces) 10a′ and 10b′ of the first targets 10a and 10b are adhered to the substrate B held by the substrate holder 3 such that the film formation target surface B′ faces the first inter-target space K1, so that a thin film (initial layer of the thin film) is formed at a lateral position of the first inter-target space K1 (i.e., at the first film formation position L1).

Generally, in the sputtering performed by disposing the pair of targets to face each other, if the distance between the centers of the targets is the same, the strength of the magnetic field in the inter-target space increases as the angle θ between the facing surfaces of the pair of targets decreases (i.e., as the facing surfaces become more parallel to each other). Thus, the amount of the charged particles such as secondary electrons flying to the substrate decreases and the effect of confining the plasma in the inter-target space improves. However, since the two facing surfaces become more parallel to each other, the amount of the sputtered particles flying to the substrate decreases. Thus, though a low-temperature·low-damage film formation is accomplished, a film forming rate of the thin film formed on the substrate decreases.

Meanwhile, as the angle θ between the facing surfaces of the pair of targets increases (i.e., as the facing surfaces is further oriented toward the substrate), the distance between end portions of the facing surfaces at the side of the substrate increases, and the strength of the magnetic field in the inter-target space at that region decreases. Thus, the plasma or the charged particles such as secondary electrons are likely to be released from that region where the strength of the magnetic field is decreased, and the amount of the charged particles such as secondary electrons flying to the substrate increases, and the effect of confining the plasma in the inter-target space is deteriorated. However, since the facing surfaces are further oriented toward the substrate, the amount of the sputtered particles reaching the substrate increases, so that a film forming rate increases though a temperature rise of the substrate B and a damage on the substrate caused by the charged particles increase as compared to the case where the angle θ is set smaller.

In this regard, the angle θ1 between the facing surfaces 10a′ and 10b′ of the first targets 10a and 10b is set to be almost parallel to each other (i.e., small) such that the plasma and the charged particles such as secondary electrons may not damage the substrate B during the sputtering beyond a tolerance limit. In this manner, the effect of confining the plasma and the charged particles such as secondary electrons in the first inter-target space K1 may be ameliorated.

Furthermore, since the first cylindrical auxiliary magnetic field generating units 30a and 30b are disposed at the first cathodes 11a and 11b, respectively, the first cylindrical auxiliary magnetic field space t1 is formed outside the first inter-target space K1. Thus, the first cylindrical auxiliary magnetic field space t1 is formed between the substrate B and the first curved magnetic field spaces W1 and W1′ formed on the first target surfaces (facing surfaces) 10a′ and 10b′, respectively, and the plasma escaped from the first curved magnetic field spaces W1 and W1′ is trapped by the first cylindrical auxiliary magnetic field space t1 (i.e., its escape toward the substrate B is suppressed), so that the influence of the plasma upon the substrate B can be more reduced.

Moreover, as for the charged particles such as secondary electrons released from the first curved magnetic field spaces W1 and W1′ toward the substrate B, since the first cylindrical auxiliary magnetic field space t1 surrounds the first inter-target space K1 and is formed between the first curved magnetic field spaces W1 and W1′ and the substrate B, the effect of confining the charged particles in the inter-target space K1 is enhanced. That is, the release of the charged particles from the first inter-target space K1 toward the substrate B may be further reduced.

Further, since the first cylindrical auxiliary magnetic field generating units 30a and 30b are arranged such that their thick bottom walls 33 are placed on the side (substrate B side) where the distance between the facing surfaces of the pair of first targets 10a and 10b increases, the strength of the magnetic field in the vicinities of the first cylindrical auxiliary magnetic field generating units 30a and 30b is enhanced as the distance between the facing surfaces of the first targets 10a and 10b increases.

If the strengths of the magnetic field were set to be the same in the vicinities of the respective first cylindrical auxiliary magnetic field generating units 30a and 30 which are arranged along the peripheries of the first targets 10a and 10b, the strength of the magnetic field at a midway point between one first target 10a and the other first target 10b would be weakened as the distance between the facing surfaces is increased when the facing surfaces (sputtering surfaces) 10a′ and 10b′ of the first targets 10a and 10b are inclined so as to face toward the film formation surface B′ of the substrate B (when the angle θ>0°. As a result, the plasma would escape from that region (substrate B side) where the strength of the magnetic field is reduced and the charged particles such as the secondary electrons would be released therefrom, so that the substrate B may be damaged.

However, if the first cylindrical auxiliary magnetic field generating units 30a and 30b have the above-described configuration, the strength of the magnetic field at the midway point can be constant because the strength of the magnetic field in the vicinities of the first cylindrical auxiliary magnetic field generating units 30a and 30b is set to increase as the distance between the facing surfaces increases.

Accordingly, even in the arrangement (so-called V-shaped facing target arrangement) where the first targets 10a and 10b are inclined toward the substrate B (toward the first film formation position L1), it is possible to effectively suppress the escape of the plasma or the release of the charged particles such as the secondary electrons from where the distance between the facing surfaces 10a′ and 10b′ is increased, so that the effect of confining the plasma and the charged particles such as the secondary electrons can be improved.

Moreover, the first cylindrical auxiliary magnetic field generating units 30a and 30b may be set as one of an earth potential, a minus potential, a plus potential or a floating (electrically insulated state), or may be set such that the earth potential and the minus potential or the earth potential and the plus potential are alternately switched in time. By setting the potential of the first cylindrical auxiliary magnetic field generating units 30a and 30b to be one of the above-mentioned potentials, an electric discharge voltage can be reduced as compared to a magnetron sputtering apparatus of V-shaped facing target arrangement (a conventional magnetron sputtering apparatus), which does not have the first cylindrical auxiliary magnetic field generating units 30a and 30b and has a pair of magnetron cathodes including facing surfaces of targets inclined toward the substrate.

As stated above, in the first film forming unit P1, the sputtering can be carried out while having a good effect of confining the charged particles such as the secondary electrons and the plasma generated by the sputtering in the inter-target space K1. Thus, the influence of the plasma and the charged particles such as the secondary electrons flown from the sputtering surfaces 10a′ and 10b′ upon the film formation target surface B′ of the substrate B can be reduced greatly, so that the initial layer of the thin film can be formed by a low-temperature·low-damage film formation. In the present embodiment, the initial layer is formed in a film thickness of about 10 to 20 nm.

Subsequently, after the sputtering in the first film forming unit P1 is stopped, a formation of the second layer is carried out. After the sputtering is stopped, the substrate holder 3 is moved from the first film formation position L1 to the second film formation position L2 by the moving mechanism while holding thereon the substrate B having the initial layer formed on its film formation target surface B′. After the substrate holder 3 is moved to the second film formation position L2, the sputtering for forming the second layer begins in the second film forming unit P2. At this time, since a sputtering condition such as a pressure within the vacuum chamber 2 requires no change, the sputtering at the second film formation position L2 can be started immediately after the substrate holder 3 is moved to the second film formation position L2 from the first film formation position L1.

In the second film forming unit P2, a sputtering power is supplied from the second sputtering power supply 4b to the second targets 110a and 110b, as in the first film forming unit P1. At this time, since the second curved magnetic field generating units 120a and 120b and the second cylindrical auxiliary magnetic field generating units 130a and 130b are made of permanent magnets, the second curved magnetic field spaces (second inwardly and outwardly curved magnetic field spaces) W2 and W2′ are formed on the facing surfaces 110a′ and 110b′ of the second targets 110a and 110b, respectively, by the second curved magnetic field generating units 120a and 120b. Further, the cylindrical auxiliary magnetic field space t2 is formed to surround the column-shaped space K2 formed between the facing surfaces 110a′ and 110b′ of the second targets 110a and 110b by the second cylindrical auxiliary magnetic field generating units 130a and 130b.

Then, plasma is generated within the second curved magnetic field spaces W2 and W2′, and the facing surfaces 110a′ and 110b′ of the second targets 110a and 110b are sputtered, and (second) sputtered particles are emitted. Plasma escaped from the second curved magnetic field spaces W2 and W2′ or charged particles such as secondary electrons released therefrom are trapped, by the second cylindrical auxiliary magnetic field space t2, in the space (second inter-target space) K2 surrounded by the second auxiliary magnetic field space t2.

Accordingly, the sputtered particles (second sputtered particles) emitted (ejected due to collisions) from the sputtering surfaces (facing surfaces) 110a′ and 110b′ of the second targets 110a and 110b are adhered to the substrate B held by the substrate holder 3 such that the film formation target surface B′ faces the second inter-target space K2, so that a thin film (second layer of the thin film) is formed at a lateral position of the second inter-target space K2 (i.e., at the second film formation position L2).

At this time, since the angle θ2 between the two facing surfaces 110a′ and 110b′ of the pair of second targets 110a and 110b in the second film forming unit P2 is larger than the angle θ1 in the first film forming unit F1, i.e., since the facing surfaces 110a′ and 110b′ are further oriented toward the substrate B, the influence of the plasma upon the substrate B and the amount of charged particles flying thereto may be increased.

However, since the facing surfaces 110a′ and 110b′ are further oriented toward the substrate B, the amount of the emitted (second) sputtered particles, which are generated by sputtering the sputtering surfaces (facing surfaces) 110a′ and 110b′ and then reach the substrate B (the film formation target surface B′), may be increased. Therefore, a film forming rate would be increased.

Accordingly, in the second film forming unit P2, the second layer is formed on the initial layer at a film forming rate greater than that in case of the initial layer formation. In the present embodiment, the second layer is formed in a film thickness of about 100 to 150 nm.

As stated above, when the initial layer (first layer) and the second layer are formed on the film formation target surface B′ in sequence in the first film forming unit P1 (with the angle θ1 between the facing surfaces 10a′ and 10b′) and the second film forming unit P2 (with the angle θ2 between the facing surfaces 110a′ and 110b′) by changing the film forming rate by varying the angle formed between the facing surfaces of the pair of targets, the angles θ1 and θ2 meet a condition of θ1<θ2. If the input powers to the first targets 10a and 10b and the second targets 110a and 110b are the same, the film forming rate of the second layer formation can be increased to about 20% to 50% of the film formation rate of the first layer formation. In addition, by increasing the input power to the second cathodes 111a and 111b at the angle θ2, a film forming rate can be raised two times or more.

From the above explanation, in the first film forming unit P1 of the first film formation region F1, by providing the first cylindrical auxiliary magnetic field generating units 30a and 30b fitted onto the outer periphery of the front end portions of the first cathodes 11a and 11b, formed is the first cylindrical auxiliary magnetic field space t1 which is extended from the vicinity of one first target 10a to the vicinity of the other first target 10b in a cylinder shape and has magnetic force lines oriented from the vicinity of one first target 10a toward the vicinity of the other first target 10b. Thus, the plasma escaped from within the first curved magnetic field spaces W1 and W1′ on the first target facing surfaces 10a′ and 10b′ and the charged particles released therefrom during the sputtering are trapped in the first cylindrical auxiliary magnetic field space t1.

That is, since both ends of the first cylindrical auxiliary magnetic field space ti are enclosed by the facing surfaces 10a′ and 10b′ of the first targets 10a and 10b, the plasma escaped from the first curved magnetic field spaces W1 and W1′ formed on the first target surfaces (facing surfaces) 10a′ and 10b′ is trapped by the first cylindrical auxiliary magnetic field space t1 (i.e., the plasma ejection toward the substrate is suppressed), so that the influence of the plasma upon the substrate B can be reduced.

Moreover, since the charged particles such as the secondary electrons released from the first curved magnetic field spaces W1 and W1′ toward the substrate B can also be trapped in the first cylindrical auxiliary magnetic field space ti, the amount of the charged particles reaching the substrate B can be reduced.

Further, the first cathodes 11a and 11b are complex type cathodes having the first cylindrical auxiliary magnetic field generating units 30a and 30b at the outer periphery of the front end portions of the magnetron cathodes. Thus, an unstable electric discharge due to high plasma concentration at a central portion, which may occur in case of using the facing target type cathodes, does not occur even when the current inputted to the first cathodes (complex type cathodes) 11a and 11b during the sputtering is increased as in the case of the magnetron cathodes. Therefore, the plasma generated in the vicinities of the target surfaces 10a′ and 10b′ can be electrically discharged stably for a long period time.

In addition, since the magnetic field strength of the first cylindrical auxiliary magnetic field space t1 is greater than the magnetic field strengths of the first curved magnetic field spaces W1 and W1′, there can be obtained a magnetic field distribution in which the magnetic field strength in the vicinities of the facing surfaces 10a′ and 10b′ is the weakest at the center sides of the first targets 10a and 10b and the strongest at the peripheral portions of the first targets 10a and 10b. Further, the effect of confining the plasma escaped from the curved magnetic field spaces W1 and W1′ and the charged particles such as the secondary electrons released therefrom within the first cylindrical auxiliary magnetic field space ti can be further improved.

Therefore, the influence of the plasma and the influence of the charged particles such as the secondary electrons flying from the sputtering surfaces (facing surfaces) 10a′ and 10b′ upon the substrate B used as the film formation target object can be minimized without having to shorten the distance between the centers of the pair of first targets 10a and 10b. Furthermore, if a required film property is approximately the same as that of a thin film formed by the sputtering which does not generate the first cylindrical auxiliary magnetic field space ti, the angle θ formed between the facing surfaces 10a′ and 10b′ of the pair of first targets 10a and 10b can be further increased.

Accordingly, by performing the sputtering using the first cathodes (complex V-type cathodes) 11a and 11b in which the angle θ between the facing surfaces 10a′ and 10b′ of the pair of first targets 10a and 10b in the first film forming unit P1 is set to be small (θ1), the effect of confining the plasma and the charged particles, which are generated by the sputtering, in the first inter-target space K1 can be greatly improved. Thus, the film forming rate is low. However, the low-temperature·low-damage film formation can be performed on the film formation target surface B′ of the substrate B, so that the initial layer (first layer) having a preset thickness can be obtained.

Furthermore, the substrate holder 3 is transferred from the first film formation position L1 of the first film forming unit P1 to the second film formation position L2 of the second film forming unit P2 without changing the sputtering condition such as the pressure within the vacuum chamber 2, which would take time if changed. Then, the sputtering is performed by using the second cathodes 111a and 111b having the angle θ between the facing surfaces 110a′ and 110b′ of the pair of second targets 110a and 110b in the second film forming unit and the angle θ is set as the angle θ2 larger than the angle θ1. Accordingly, the influence of the plasma or the charged particles such as the secondary electrons flying to the substrate B may be increased. However, the film forming rate can be enhanced, so that the second layer can be formed in a shorter period of time.

As mentioned above, the initial layer formed on the substrate B by the low-temperature·low-damage film formation in the first film forming unit P1 serves as a protective layer. Thus, when the film formation in the second film forming unit P2 is performed at a high film forming rate to shorten the entire film formation processing time, even though the influence of the plasma upon the substrate B or the amount of the charged particles such as the secondary electrons flying to the substrate B increases, the film formation can be carried out while the initial layer (protective layer) suppresses the influence of the plasma or the damage on the substrate B by the charged particles such as the secondary electrons. Furthermore, the sputtering condition such as the pressure within the vacuum chamber 2 requires no change after the initial layer formation until the second layer formation, and the substrate holder 3 only needs to be transferred from the first film forming unit P1 to the second film formation position P2, so that the film formation time (entire film formation processing time) can be reduced. Especially, if thin films are formed (i.e., when film formation is performed) on a plurality of substrates B consecutively, the sputtering condition such as the pressure in the vacuum chamber does not need to be changed for every substrate B, but the substrates B only need to be transferred to the first and second film forming units by the substrate holder 3 in sequence while the sputtering condition is maintained the same. Thus, the film formation time for processing the plurality of substrates B can be greatly reduced.

As a result, a film formation can be carried out on the substrate B which requires a low-temperature·low-damage film formation, and the film formation processing time can be reduced even when the plurality of substrates B are consecutively processed.

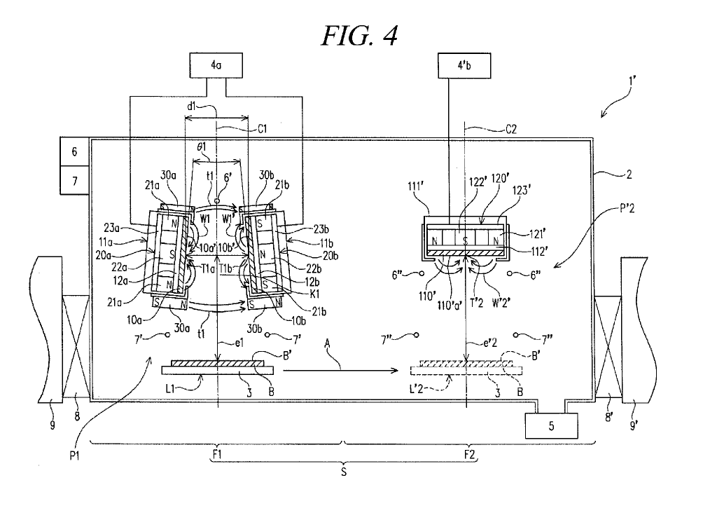

Hereinafter, a second embodiment of the present invention will be explained with reference to FIG. 4. In the second embodiment, the same components as those described in the first embodiment will be illustrated with the same reference numerals in FIG. 4, and explanation thereof will be partially omitted while components different from the first embodiment are described.

A sputtering apparatus 1′ includes a vacuum chamber 2 having an inner space S; a first film forming unit P1 and a second film forming unit P′2 for forming a film on a film formation target surface B′ of a substrate B which is a target object on which a film is to be formed; and a substrate holder 3 capable of moving inside the vacuum chamber 2 at least from a first film formation position L1, where a film formation is performed on the substrate B in the first film forming unit P1, to a second film formation position L′2, where a film formation is performed on the substrate B in the second film forming unit P′2 (moving in an arrow A direction), while holding the substrate B thereon.

Further, the sputtering apparatus 1′ includes a first sputtering power supply 4a for supplying a sputtering power to the first film forming unit P1; a second sputtering power supply 4′b for supplying a sputtering power to the second film forming unit P′2; an evacuation unit 5 for evacuating the inside (inner space S) of the vacuum chamber 2; and a sputtering gas supply unit 6 for supplying a sputtering gas into the vacuum chamber 2. Further, the vacuum chamber 2 may include a reactive gas supply unit 7 for supplying a reactive gas to the vicinity of the substrate B.

The vacuum chamber 2 is connected to other processing chambers or load lock chambers 9 and 9′ via communication passages (substrate transfer line valves) 8 and 8′ provided at the vacuum chamber 2′s both ends on the side of the substrate holder 3 (lower end side of the drawing).

The inner space S of the vacuum chamber 2 includes a first film formation region F1 in which the first film forming unit P1 is installed and a second film formation region F2 in which the second film forming unit P′2 is installed, wherein the first film forming unit P1 and the second film forming unit P′2 are arranged in juxtaposition.

The second film forming unit P′2 includes a second cathode (second target holder) 111′ having a second target 110′ at its front end. The second cathode 111′ is arranged such that a surface 110′a′ of the second target 110′ faces in parallel with the film formation target surface B′ of the substrate B positioned at the second film formation position L′2.

Like the first cathode 11a (11b) in the first film forming unit P1, the second cathode (second target holder) 111′ includes: the second target 110′ fixed to the front end portion of the second cathode 111′ via a backing plate 112′; and a second curved magnetic field generating unit 120′ disposed on the rear surface of the backing plate 112′, for generating a magnetic field space curved in an arc shape on the side of the second target surface 110′a′. The second curved magnetic field generating unit 120′ has the same configuration as that of the second curved magnetic field generating unit 120a in the first embodiment and forms an inwardly curved magnetic field space W′2′ on the side of the second target surface 110′a′.

Moreover, in the second embodiment and other embodiments to be described later, a cathode in which a target surface of the magnetron cathode is arranged in parallel with the film formation target surface B′ of the substrate B may be referred to as “parallel plate type magnetron cathode”.

The second target 110′ in the present embodiment is made of ITO (Indium Tin oxide) in the same manner as in the first embodiment. Further, the second target 110′ is formed of a rectangular plate-shaped member having a size of about 125 mm (width)×300 mm (length)×5 mm (thickness). The second target 110′ is disposed such that it faces in parallel with the film formation target surface B′ of the substrate B when the substrate B is positioned at the second film formation position L′2 of the second film forming unit P′2 within the vacuum chamber 2, and its surface (surface to be sputtered) 110′a′ is spaced away from the film formation target surface B′ at a predetermined distance.

As described above, the second cathode 111′ has the same components as the second cathode 111a of the second film forming unit P2 in the first embodiment except the second cylindrical auxiliary magnetic field generating unit 130a. Further, the first film forming unit P1 and the second film forming unit P′2 are arranged in juxtaposition inside the vacuum chamber 2. To elaborate, the first cathodes 11a and 11b of the first film forming unit P1 and the second cathode 111′ of the second film forming unit P′2 are juxtaposed in a row within the vacuum chamber 2. More particularly, the centers T1a, T1b and T′2 of the first and second targets 10a, 10b and 111′ lie on the same line, respectively, and a first central surface C1 of the pair of inclined facing first targets 10a and 10b and the surface 110′a′ of the second target 110′ are juxtaposed to be perpendicular or substantially perpendicular to each other.

The second film formation position L′2 is positioned on the line connecting the other processing chambers 9 and 9′ connected to both lateral sides of the vacuum chamber 2. To elaborate, when the substrate holder 3 for holding the substrate B is positioned at the second film formation position L′2, the film formation target surface B′ of the substrate B is disposed in front of the second target 110′ and the surface 110′a′ faces parallel to the film formation target surface B′, and a distance e′2 between the center T′2 of the surface 110′a′ of the second target 110′ and the center of the film formation target surface B′ becomes equal to about 175 mm (e1=175 mm). Though the distance e′2 is the same as the distance e1 in the present embodiment, but not limited thereto, the distance e′2 may be set to be different from the distance e1.

Second nonreactive gas introduction pipes 6″ are provided in the vicinity of the substrate B of the second target 110′ and serve to introduce a nonreactive gas to the vicinity of the surface 110′a′ of the second target 110′ from the sputtering gas supply unit 6.

The sputtering apparatus 1′ in accordance with the present embodiment is configured as stated above, and an operation of a thin film formation in the sputtering apparatus 1′ will be explained hereinafter.

First, in the same manner as in the first embodiment, when forming an initial layer, the substrate B is held on the substrate holder 3 and the substrate holder 3 is positioned at the first film formation position L1 (the position of the substrate B and the substrate holder 3 shown by a solid line of FIG. 4), and then the inside of the vacuum chamber 2 is evacuated by the evacuation unit 5. Thereafter, an argon gas (Ar) is introduced into the vacuum chamber 2 from a first nonreactive gas introduction pipe 6′ and the second nonreactive gas introduction pipes 6″ by the sputtering gas supply unit 6, and a preset sputtering operation pressure (about 0.4 Pa in the present embodiment) is set.

Thereafter, in the same manner as in the first embodiment, a thin film is formed on the substrate B in the first film forming unit P1. That is, the initial layer of the thin film is formed on the substrate B by a low-temperature·low-damage film formation. In the present embodiment, the initial layer is formed in a film thickness of about 10 to 20 nm.

Subsequently, after the sputtering in the first film forming unit P1 is stopped, a formation of a second layer is carried out. Then, the substrate holder 3 is moved from the first film formation position L1 to the second film formation position L′2 by a moving mechanism while holding thereon the substrate B having the initial layer formed on its film formation target surface B′. After the substrate holder 3 is moved to the second film formation position L′2, sputtering for forming the second layer begins in the second film forming unit P′2. At this time, since a sputtering condition such as a pressure inside the vacuum chamber 2 need not be changed in the same manner as in the first embodiment, the sputtering can be started immediately after the substrate holder 3 is moved from the first film formation position L1 to the second film formation position L′2.

In the second film forming unit P′2, a sputtering power is supplied from the second sputtering power supply 4′b to the second target 110′. At this time, since the second curved magnetic field generating unit 120′ is made of a permanent magnet, a second curved magnetic field space W′2′ is formed on the surface 110′a′ of the second target 110′ by the second curved magnetic field generating unit 120′.

Then, plasma is generated within the second curved magnetic field space W′2′, whereby the surface 110′a′ of the second target 110′ is sputtered and (second) sputtered particles are emitted.

Accordingly, the sputtered particles (second sputtered particles) emitted (ejected due to collisions) from the sputtering surface (surface) 110′a′ of the second target 110′ are adhered to the substrate B which is disposed to face parallel to the surface 110′a′ of the second target 110′ at the second film formation position L′2, so that a thin film (second layer of the thin film) is formed.

In this case, the second cathode 111′ of the second film forming unit P′2 is a parallel plate type magnetron cathode 111′ in which the surface 110′a′ of the second target 110′ faces parallel to the film formation target surface B′ of the substrate B. In a general magnetron cathode, a strength of the magnetic field decreases at the center portion of the target due to a shape of a magnetic field space (curved magnetic field space) formed at the target surface's side, so that plasma or charged particles such as secondary electrons are likely to be released (escaped) from such a center portion in a perpendicular direction to the target surface. For this reason, at the second film formation position P′2, the influence of the plasma and an amount of the charged particles flying from the parallel plate type magnetron cathode 111′ to the substrate B may be increased.

However, as described above, the parallel plate type magnetron cathode 111′ is disposed so that the surface 110′a′ of the second target 110′ faces parallel to the film formation target surface B′ of the substrate B. For this reason, the amount of the sputtered particles reaching the substrate B (film formation target surface B′) after sputtered and emitted from the sputtering surface (surface) 110′a′ is much greater than that in case of using a target arrangement (so-called “V-type facing-target arrangement”) in which the sputtering surface is inclined toward the substrate B. As a result, a film forming rate is greatly increased.

Accordingly, in the second film forming unit P′2, the second layer is formed on the initial layer at a film forming rate higher than that in case of the initial layer formation. In the present embodiment, the second layer is formed in a film thickness of about 100 to about 150 nm.

In this way, when the initial layer (first layer) and the second layer are formed on the film formation target surface B′ in sequence by using the complex V-type cathodes 11a and 11b and the parallel plate type magnetron cathode 111′, respectively, if the same input power is applied to the first targets 10a and 10b and the second target 110′, the film forming rate of the second layer can be increased to about 80% to 100% of the film forming rate of the first layer. In addition, by increasing the input power to the parallel plate type magnetron cathode 111′, a film forming rate can be raised three times or more.

From the above explanation, by using the complex V-type cathodes 11a and 11b in the first film forming unit P1, it is possible to improve the effect of confining the plasma escaped from first curved magnetic field spaces W1 and W′1 formed on the first target surfaces (facing surfaces) 10a′ and 10b′ and the charged particles released toward the substrate B, as in the first embodiment.

Furthermore, even if a current value to be inputted to the complex V-type cathodes 11a and 11b during the sputtering is increased, an unstable electric discharge due to high plasma concentration in a central portion may not occur. Thus, the plasma generated in the vicinities of the target surfaces 10a′ and 10b′ can be electrically discharged stably for a long time.

Moreover, since the magnetic field strength outside the first curved magnetic field spaces W1 and W1′ (i.e., in the first cylindrical auxiliary magnetic field space t1) is higher than that in the first curved magnetic field spaces W1 and W1′, the plasma and the charged particles such as the secondary electrons can be more effectively trapped within the first cylindrical auxiliary magnetic field space t1.

For this reason, by performing the sputtering using the first cathodes (complex V-type cathodes) 11a and 11b in which an angle θ formed between the facing surfaces 10a′ and 10b′ of the pair of first targets 10a and 10b in the first film forming unit P1 is set to be small (θ1) in the same manner as in the first embodiment, the effect of confining the plasma and the charged particles, which are generated by the sputtering, in a first inter-target space K1 can be greatly improved. Thus, though the film forming rate is low, the low-temperature·low-damage film formation can be performed on the film formation target surface B′ of the substrate B, so that it is possible to form the initial layer (first layer) having a predetermined thickness.

Further, without changing the sputtering condition such as a pressure within the vacuum chamber 2, which takes time, the substrate holder 3 is transferred from the first film formation position L1 of the first film forming unit P1 to the second film formation position L′2 of the second film forming unit P′2. Then, by performing sputtering using the parallel plate type magnetron cathode 111′ in the second film forming unit P′2, though the influence of the plasma or the charged particles such as the secondary electrons flying toward the substrate B may be increased, it is possible to form the second layer in a short period of time by increasing the film forming rate.

In this way, by forming the initial layer on the substrate B by the low-temperature·low-damage film formation in the first film forming unit P1 and using the formed initial layer as a protective layer in the same manner as in the first embodiment, it is possible to form the second layer in the second film forming unit P′2 while suppressing damage on the substrate B due to the charged particles such as the secondary electrons or the influence of the plasma. Moreover, the sputtering condition such as the pressure within the vacuum chamber 2 requires no change after the initial layer formation until the second layer formation in the same manner as in the first embodiment, and the substrate holder 3 only needs to be transferred from the first film forming unit P1 to the second film formation position P′2, so that the film formation time (entire film formation processing time) can be reduced. Especially, if thin films are formed (i.e., when film formation is performed) on a plurality of substrates B consecutively, the sputtering condition such as the pressure in the vacuum chamber does not need to be changed for every substrate B, but the substrates B only need to be transferred to the first and second film forming units by the substrate holder 3 in sequence while the sputtering condition is maintained the same. Thus, the film formation time for processing the plurality of substrates B can be greatly reduced.

As a result, a film formation can be carried out on the substrate B which requires a low-temperature·low-damage film formation, and the film formation processing time can be reduced even when the plurality of substrates B are consecutively processed.

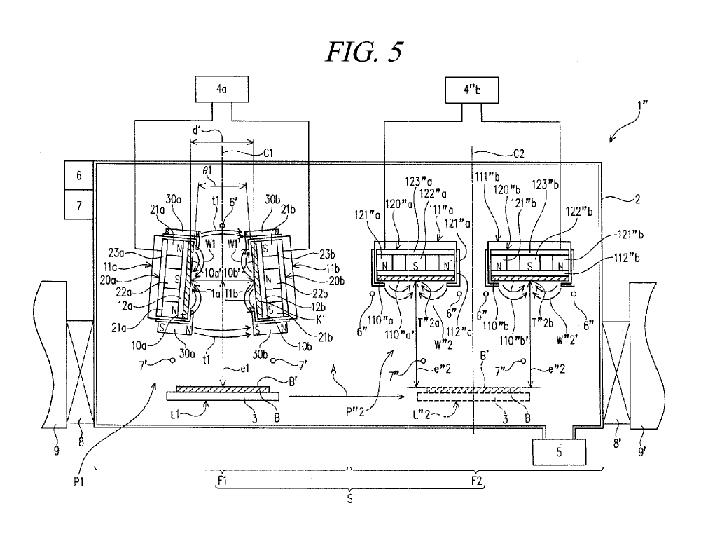

Hereinafter, a third embodiment of the present invention will be explained with reference to FIG. 5. In the third embodiment, the same components as those described in the first and second embodiments will be illustrated with the same reference numerals in FIG. 5 and explanation of some of the same components will be omitted but components different from the first and second embodiments will be described.

A sputtering apparatus 1″ includes a vacuum chamber 2 having an inner space S; a first film forming unit P1 and a second film forming unit P″2 for forming a film on a film formation target surface B′ of a substrate B serving as a film formation target object; and a substrate holder 3 capable of moving inside the vacuum chamber 2 at least from a first film formation position L1, where a film formation is performed on the substrate B in the first film forming unit P1, to a second film formation position L″2, where a film formation is performed on the substrate B in the second film forming unit P″2 (moving in an arrow A direction), while holding the substrate B thereon.

Further, the sputtering apparatus 1″ includes a first sputtering power supply 4a for supplying a sputtering power to the first film forming unit P1; a second sputtering power supply 4″b for supplying a sputtering power to the second film forming unit P″2; an evacuation unit 5 for evacuating the inside (inner space S) of the vacuum chamber 2; and a sputtering gas supply unit 6 for supplying a sputtering gas into the vacuum chamber 2. Furthermore, the vacuum chamber 2 may be provided with a reactive gas supply unit 7 for supplying a reactive gas to the vicinity of the substrate B.

The vacuum chamber 2 are connected to other processing chambers or load lock chambers 9 and 9′ via communication passages (substrate transfer line valves) 8 and 8′ provided at the vacuum chamber 2′s both ends on the side of the substrate holder 3 (lower end side of the drawing).

The inner space S of the vacuum chamber 2 includes a first film formation region F1 in which the first film forming unit P1 is installed and a second film formation region F2 in which the second film forming unit P″2 is installed, wherein the first film forming unit P1 and the second film forming unit P″2 are arranged in juxtaposition.

The second film forming unit P″2 includes a second cathode (second target holder) 111″a (111″b) having second target 110″a (110″b) at each front end. The second cathode 111″a (111″b) is arranged such that a surface 110″a′ (110″b′) of the second target 110″a (110″b) faces parallel or substantially parallel to the film formation target surface B′ of the substrate B positioned at the second film formation position L″2.

Like the first cathode 11a, the second cathode (second target holder) 111″a (111″b) includes: the second target 110″a (110″b) fixed to the front end portion of the second cathode 111″a (111″b) via a backing plate 112″a (112″b); and a second curved magnetic field generating unit 120″a (120″b) disposed on the rear surface of the backing plate 112″a (112″b) and provided at the side of the second target surface 110″a′ (110″b′). Further, the second curved magnetic field generating unit 120″a (120″b) has the same configuration as that of the second curved magnetic field generating unit 120a in the first embodiment and forms an inwardly curved magnetic field space on the side of the second target surface 110″a′ (110″b′).

Moreover, in the third embodiment, a pair of parallel plate type magnetron cathodes may be called “dual magnetron cathode” when they are arranged in juxtaposition such that their target surfaces are on the same plane in the same direction, and parallel plate type magnetron cathodes are connected with an AC power supply having a phase difference of about 180°, which will be described later.

The second target 110″a (110″b) in the present embodiment is made of ITO (Indium Tin Oxide) in the same manner as in the first embodiment. Further, the second target 110″a (110″b) is formed of a rectangular plate-shaped member having a size of about 125 mm (width)×300 mm (length)×5 mm (thickness). In addition, the second target 110″a (110″b) is disposed such that it faces parallel or substantially parallel to the film formation target surface B′ of the substrate B (facing slightly toward the substrate B) when the substrate B is positioned at the second film formation position L″2 of the second film forming unit P″2 within the vacuum chamber 2 and its surface (surface to be sputtered) 110″a′(110″b′) is spaced away from the film formation target surface B′ at a predetermined distance.

As described above, the second cathode 111″a (111″b) has the same configuration as the second cathode 111a (111b) of the second film forming unit P2 in the first embodiment, except a second cylindrical auxiliary magnetic field generating unit 130a (130b) and if the angle θ2 formed between the facing surfaces (surfaces) 110a′ and 110b′ is about 180° (however, each of second curved magnetic field generating units of the second cathodes 111″a and 111″b has the same configuration as that of the second curved magnetic field generating unit 120a of the first embodiment). Further, the first film forming unit P1 and the second film forming unit P″2 are arranged in juxtaposition inside the vacuum chamber 2. To be specific, the first cathode 11a (11b) of the first film forming unit P1 and the second cathode 111″a (111″b) of the second film forming unit P″2 are juxtaposed in a row within the vacuum chamber 2. To be more specific, centers T1a, T1b, T″2a and T″2b of the respective first and second targets 10a and 10b lie on the same line, and a first central surface C1 of a pair of inclined facing first targets 10a and 10b and the surfaces 110″a′ and 110″b′ of the second targets 110″a and 110″b are juxtaposed to be perpendicular or substantially perpendicular to each other.

The second film formation position L″2 is positioned on the line connecting the other processing chambers 9 and 9′ connected to both lateral sides of the vacuum chamber 2. To elaborate, when the substrate holder 3 for holding the substrate B is positioned at the second film formation position L″2, the film formation target surface B′ of the substrate B faces toward a central portion of the second targets 110″a and 110″b; the surfaces 110″a′ and 110″b′ face parallel to the film formation target surface B′; and a shortest distance e“2 between the center T″2a (T″2b) of the surface 110″a′ (110″b′) of the second target 110″a (110″b) and an extended surface of the film formation target surface B′ becomes equal to about 175 mm (e1=175 mm).

The second sputtering power supply 4″b is an AC power supply capable of applying an AC electric field having a phase difference of about 180° to the second cathode 111″a (111″b).

Second nonreactive gas introduction pipes 6″ are provided in the vicinity of the substrates B of the second target 110″a (110″b) and serve to introduce a nonreactive gas to the vicinity of the surface 110″a′ (110″b′) of the second target 110″a (110″b).

The sputtering apparatus 1″ in accordance with the present embodiment is configured as stated above, and there will be explained an operation of a thin film formation in the sputtering apparatus 1″ hereinafter.

First, in the same manner as in the first embodiment, when forming an initial layer, the substrate B is held on the substrate holder 3 and the substrate holder 3 is positioned at the first film formation position L1 (the position of the substrate B and the substrate holder 3 shown by a solid line of FIG. 5). Then, the inside of the vacuum chamber 2 is evacuated by the evacuation unit 5. Thereafter, an argon gas (Ar) is introduced into the vacuum chamber 2 from a first and a second nonreactive gas introduction pipe 6′ and 6″ by the sputtering gas supply unit 6, and a predetermined sputtering operation pressure (0.4 Pa in the present embodiment) is set.

Thereafter, as in the first embodiment, a thin film formation is performed on the substrate B in the first film forming unit P1. That is, the initial layer of the thin film is formed on the substrate B by a low-temperature·low-damage film formation. In the present embodiment, the initial layer is formed in a film thickness of about 10 to 20 nm.

Subsequently, after the sputtering in the first film forming unit P1 is stopped, a formation of a second layer is carried out. Then, the substrate holder 3 is moved from the first film formation position L1 to the second film formation position L″2 by a moving mechanism while holding thereon the substrate B having the initial layer formed on its film formation target surface B′. After the substrate holder 3 is moved to the second film formation position L″2, sputtering for forming the second layer begins in the second film forming unit P″2. At this time, since a sputtering condition such as a pressure inside the vacuum chamber 2 need not be changed in the same manner as in the first embodiment, the sputtering can be started immediately after the substrate holder 3 is moved from the first film formation position L1 to the second film formation position L″2.

In the second film forming unit P″2, the AC electric field having a phase difference of 180° is applied to the second cathodes 111″a (111″b) by the second sputtering power supply 4b. At this time, since the second curved magnetic field generating unit 120″ (120″b) is made of a permanent magnet, a second curved magnetic field space (inwardly curved magnetic field space) W″2′ is formed on the surface 110″a′ (110″b′) of the second target 110″a (110″b) by the second curved magnetic field generating unit 120″ (120″b).

Then, plasma is generated within the second curved magnetic field spaces W″2′, whereby the surfaces 110″a′ and 110″b′ of the second target 110″a and 110″b are sputtered and (second) sputtered particles are emitted.

At this time, the AC electric field having the phase difference of about 180° is applied to the second cathode 111″a (111″b). Thus, if a negative potential is applied to one second target 110″a (second cathode 111″a), a positive potential or an earth potential is applied to the other second target 110″b (second cathode 111″b). Therefore, the other second target 110″b (second cathode 111″b) serves as an anode, so that the one second target 110″a (second cathode 111″a) to which the negative potential is applied is sputtered. Further, if the negative potential is applied to the other second target 110″b, the positive potential or earth potential is applied to the one second target 110″a. Therefore, the one second target 110″a serves as an anode, so that the other second target 110″b is sputtered. In this way, by switching the potentials applied to the targets (cathodes) alternately, charge-up of oxide and nitride does not occur on the target surface and a stable electric discharge can be carried out for a long time.

Accordingly, the sputtered particles (second sputtered particles) emitted (ejected due to collisions) from the sputtering surface (surface) 110″a′ (110″b′) of the second target 110″a (110″b) are adhered to the film formation target surface B′ which is disposed to face parallel or substantially parallel to the surface 110″a′ (110″b′) of the second target 110″a (110″b) at the second film formation position L″2, so that a thin film (second layer of the thin film) is formed.

Here, the surface 110″a′ (110″b′) of the second target 110″a (110″b) in the second film forming unit P″2 faces parallel or substantially parallel to the film formation target surface B′ of the substrate B in the same manner as the second cathode 111′ of the second film forming unit P′2 in the second embodiment. For this reason, though the influence of the plasma and the amount of the charged particles flying toward the substrate B may be increased at the second film formation position P″2, a film forming rate can also be greatly increased because the amount of the sputtered particles reaching the substrate B (film formation target surface B′) after sputtered from the sputtering surface (surface) 110″a′ (110″b′) is much greater than in case of the targets of which the sputtering surfaces are arranged to be inclined with respect to the substrate B.

Accordingly, in the second film forming unit P″2, the second layer is formed on the initial layer at a film forming rate higher than that in case of the initial layer formation. In the present embodiment, the second layer is formed in a film thickness of about 100 nm to about 150 nm.

In this way, when the initial layer (first layer) and the second layer are formed in sequence on the film formation target surface B′ by using the complex V-type cathodes 11a and 11b and the dual magnetron cathodes 111″a and 111″b, respectively, if the same input power is applied to the first targets 10a and 10b and the second targets 110″a and 110″b, the film forming rate of the second layer formation can be increased to about 40% to 50% of the film forming rate of the first layer formation. In addition, by increasing the input power applied to the dual magnetron cathodes 111″a and 111″b, a film forming rate can be raised two times or more.

From the above explanation, by using the complex V-type cathodes 11a and 11b in the first film forming unit P1 in the third embodiment, it is possible to improve the effect of confining the plasma escaped from the first curved magnetic field spaces W1 and W′1 formed on the first target surfaces (facing surfaces) 10a′ and 10b′ and the charged particles released toward the substrate B in the same manner as in the first embodiment.

Furthermore, even if the current value to be inputted to the complex V-type cathodes 11a and 11b during the sputtering is increased, an unstable electric discharge due to high plasma concentration in a central portion may not occur. Thus, the plasma generated in the vicinities of the target surfaces 10a′ and 10b′ can be electrically discharged stably for a long time.

Moreover, since the magnetic field strength outside the first curved magnetic field spaces W1 and W1′ (i.e., in the first cylindrical auxiliary magnetic field space ti) is higher than that in the first curved magnetic field spaces W1 and W1′, the plasma and the charged particles such as the secondary electrons can be more effectively trapped within the first cylindrical auxiliary magnetic field space t1.

For this reason, by performing the sputtering using the first cathodes (complex V-type cathodes) 11a and 11b in which an angle θ formed between the facing surfaces 10a′ and 10b′ of the pair of first targets 10a and 10b in the first film forming unit P1 is set to be small (θ1) in the same manner as in the first and second embodiment, the effect of confining the plasma and the charged particles, which are generated by the sputtering, in a first inter-target space K1 can be greatly improved. Thus, though the film forming rate is decreased, the low-temperature·low-damage film formation can be performed on the film formation target surface B′ of the substrate B, so that it is possible to form the initial layer (first layer) having a predetermined thickness.

Further, without changing the sputtering condition such as a pressure within the vacuum chamber 2, which needs time to be changed, the substrate holder 3 is transferred from the first film formation position L1 of the first film forming unit P1 to the second film formation position L″2 of the second film forming unit P″2. Then, by performing sputtering using the dual magnetron cathodes 111″a and 111″b in the second film forming unit P″2, though the influence of the plasma or the charged particles such as the secondary electrons flying toward the substrate B may be increased, it is possible to form the second layer in a short period of time by increasing the film forming rate.

In this way, by forming the initial layer on the substrate B by the low-temperature·low-damage film formation in the first film forming unit P1 and using the formed initial layer as a protective layer in the same manner as in the first embodiment, it is possible to form the second layer in the second film forming unit P″2 while suppressing damage on the substrate B due to the charged particles such as the secondary electrons or the influence of the plasma. Moreover, the sputtering condition such as the pressure within the vacuum chamber 2 requires no change after the initial layer formation until the second layer formation in the same manner as in the first embodiment, and the substrate holder 3 only needs to be transferred from the first film forming unit P1 to the second film formation position P″2, so that the film formation time (entire film formation processing time) can be reduced. Especially, if thin films are formed (i.e., when film formation is performed) on a plurality of substrates B consecutively, the sputtering condition such as the pressure in the vacuum chamber does not need to be changed for every substrate B, but the substrates B only need to be transferred to the first and second film forming units by the substrate holder 3 in sequence while the sputtering condition is maintained the same. Thus, the film formation time for processing the plurality of substrates B can be greatly reduced.

As a result, a film formation can be carried out on the substrate B which requires a low-temperature·low-damage film formation, and the film formation processing time can be reduced even when the plurality of substrates B are consecutively processed.

Furthermore, the sputtering method and the sputtering apparatus in accordance with the present invention are not limited to the aforementioned first to third embodiments but may be modified in various ways without departing from the scope of the present invention.

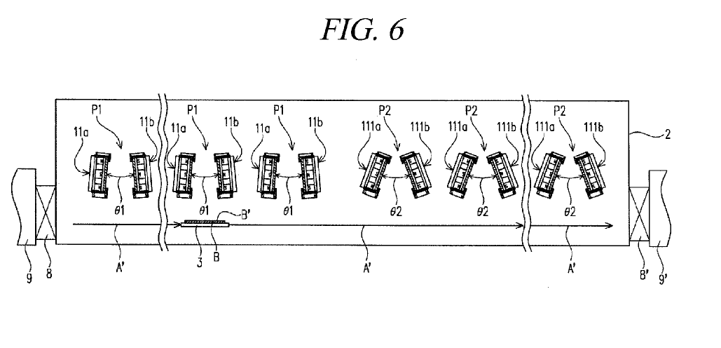

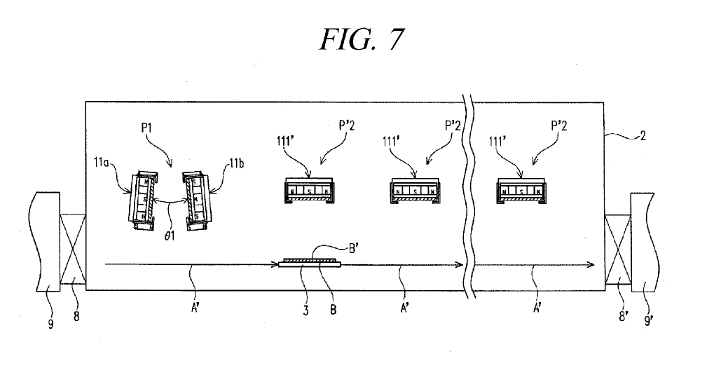

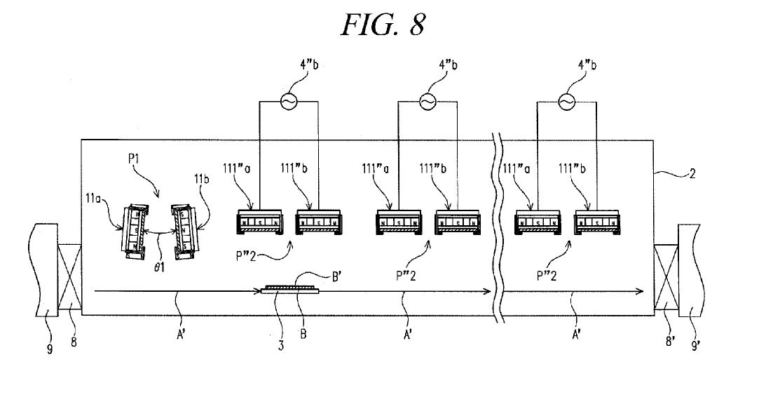

In the aforementioned embodiments, though one first film forming unit P1 and one second film forming unit P2 (P′2, P″2) are installed in the first film formation region F1 and the second film formation region F2, respectively, the present invention is not limited thereto. That is, a number of first film forming units P1 may be arranged in juxtaposition in the first film formation region F1 as illustrated in FIG. 6, and a plurality of second film forming units P2, (P′2 or P″2) may be arranged in juxtaposition in the second film formation region F2, as illustrated in FIGS. 6 to 8. In this way, as a multiple number of film forming units are arranged in juxtaposition in the first film formation region F1 or the second film formation region F2, thin films are formed on the substrates B by the multiple number of film forming units. Therefore, without increasing the damages on the substrate B caused by the influence of the plasma or the charged particles, the film forming rate can be increased. In this case, the substrate holder 3 is moved between the targets (pair of targets) facing the film formation target surface B′ held on the substrate holder 3, or moved along a path which is always oriented toward a direction of the target surfaces facing parallel to the film formation target surface B′. Furthermore, the multiple number of film forming units are arranged spaced apart from each other at a predetermined distance on the line or curve connecting the other processing chambers 9 and 9′.

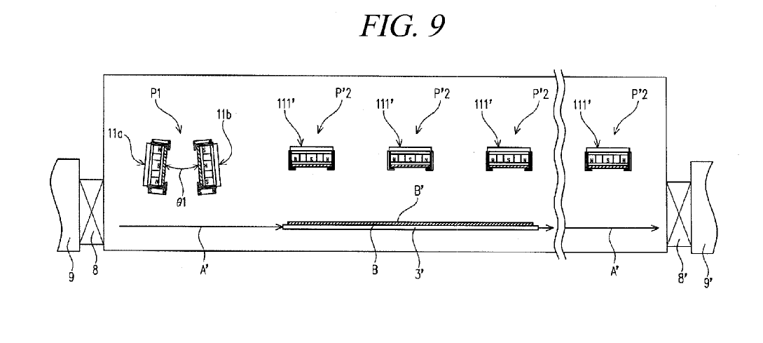

Moreover, when forming the film on the substrate B in the first film formation region F1 or the second film formation region F2 in which the multiple number of film forming units are arranged, the sputtering (film formation) may be performed while moving the substrate holder 3 on which an elongated substrate B is mounted such that its lengthwise direction is perpendicular to a movement direction A′ (arrangement direction of the film forming units), or such that its lengthwise direction is coincident with the movement direction (arrangement direction of the film forming units) as illustrated in FIG. 9. In this case, the sputtering may be performed while the substrate holder 3 is being moved as stated above or when the substrate holder is stopped. In this way, since the sputtering is performed by the multiple number of film forming units at the same time, it is possible to increase a film forming rate without increasing damage on the substrate B due to the plasma or the charged particles, thus improving productivity.

Further, in the first embodiment, the complex V-type cathodes 111a and 111b are used in the second film formation region F2 (second film forming unit P2), but the first embodiment is not limited thereto. As long as the film formation is carried out at a film forming rate higher than that in the first film formation region F1, it may be possible to use simple magnetron cathodes not having the cylindrical auxiliary magnetic field generating unit 130a (130b) and arranged to face each other in a V-shape. In other words, since the initial layer is formed on the substrate B by the low-temperature·low-damage film formation in the first film formation region F1, the initial layer serves as a protective layer even if the influence of the plasma or the amount of the charged particles increases during the film formation in the second film formation region F2, so that the damage onto the substrate B is suppressed. For this reason, even if the substrate B tends to be vulnerable to the plasma or the charged particles, the productivity can be improved during the film formation in the second film formation region F2, so that the film forming rate can be increased regardless of the influence of the plasma or the charged particles on the substrate B.

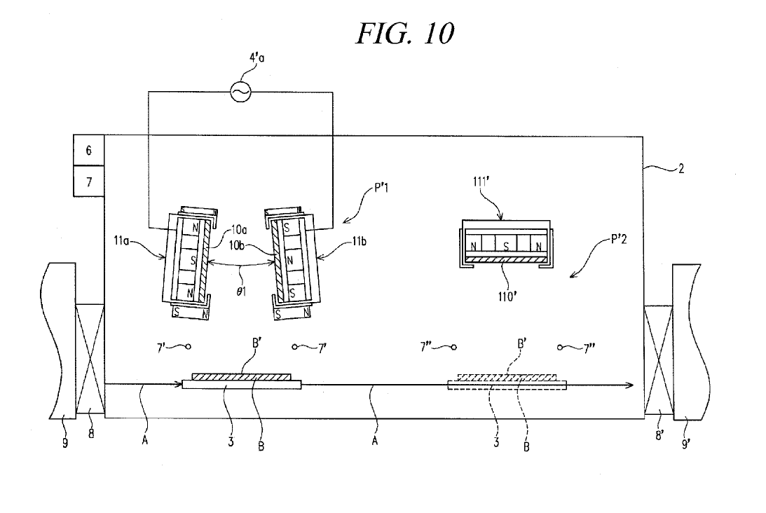

Further, as for the application power to the cathodes 10a and 10b of the first film forming unit P1 in the first film formation region F1 in the aforementioned embodiments, it may be possible to use an AC power supply, in particular, an AC power supply 4′a, as shown in FIG. 10, capable of applying AC electric fields having a phase difference of about 180° to the pair of targets (cathodes) used in the second film forming unit P″2 in the third embodiment.

In case that the thin film is made of a dielectric material such as oxide or nitride (for use as, e.g., a sealing film or a protective film for an organic EL device), there is used a method in which the reactive gases (O₂, N₂, and the like) are introduced toward the substrate B from reactive gas introduction pipes 7′ provided in the vicinity of the substrate B (or between the targets 10a and 10b), and the sputtered particles flying from the targets 10a and 10b and the reactive gases react with each other, and thus the thin film made of a compound such as oxide·nitride is formed on the substrate B. In this reactive sputtering, the surface 10a′ (10b′) of the target 10a (10b) is oxidized and reaction products such as the oxide and the nitride are adhered to uneroded regions of the protection plate, an earth shield and the target 10a (10b), whereby an abnormal arc discharge occurs frequently and a stable electric discharge can not be obtained. Further, a quality of the film deposited on the substrate B is deteriorated. Furthermore, even in case of forming an ITO film serving as a transparent conductive film by using an ITO target, sputtering is carried out by introducing a small amount of an O₂ gas to form a high quality of ITO film. Even in this case, if the film formation is performed for a long time, the phenomenon as stated above occurs.

It can be deemed that as a cause of such an abnormal arc discharge, the target surface 10a′ (10b′) is charged up due to the oxide or the nitride, and a chamber wall, the protection plate and the earth shield serving as an anode with respect to the target 10a (10b) are covered with the oxide or the nitride, whereby the size of the anodes becomes small or non-uniform.

By employing the above-described configuration in order to solve such problems, if the negative potential is applied to one target 10′a, the positive potential or the earth potential is applied to the other target 10b. Therefore, the other target 10b serves as an anode, so that the one target 10a to which the negative potential is applied is sputtered. Further, if the negative potential is applied to the other target 10b, the positive potential or the earth potential is applied to the one target 10a. Therefore, the one target 10a serves as an anode, so that the other target 10b is sputtered. In this way, by alternately switching the potentials to be applied to the targets (cathodes), charge-up of oxide and nitride does not occur on the target surface, and a stable electric discharge can be carried out for a long time.

For example, in case that the transparent conductive film is formed by using the ITO target, in order to form a high quality film with a low resistance (resistivity of about 6×10⁻⁴ Ω·cm or less without heating the substrate) and a high transmittance (about 85% or more at a wavelength of about 550 nm), an O₂ gas ranging from about 2 sccm to about 5 sccm is introduced with respect to an Ar gas of about 50 sccm. In this case, despite a long time electric discharge, by alternatively switching the potentials to be applied to the pair of targets 10a and 10b by the AC power supply, the charge-up caused by oxidization does not occur on the target surfaces 10a′ and 10b′. Further, by allowing the targets 210a and 210b to serve as the cathode and the anode reciprocally, the stable electric discharge can be carried out.

Further, as an another example, a reactive sputtering is performed by using a Si target and introducing an O₂ gas serving as an reactive gas to form a SiOx film as a sealing film or protective film for the organic EL device. In this case, the abnormal arc discharge occurs more frequently in a DC reactive sputtering using a conventional DC power supply than in a case of forming the ITO film. However, by connecting with the AC power supply, the charge-up caused by oxidization does not occur on the target surfaces 10a′ and 10b′ in the same manner as in a case where the ITO film is formed, and the stable electric discharge can be carried out for a long time.

Furthermore, in the first embodiment, the power may be applied to the cathodes 110a and 110b of the second film forming unit P2 in the second film formation region from the AC power supply 4′a capable of applying the AC electric fields having the phase difference of about 180° to the pair of targets 110a and 110b respectively, in the same manner as stated above. In such a way, the same effects as stated above can be obtained in the second film formation region F2.

Moreover, in the first embodiment, the pair of targets 10a and 10b (110a and 110b) of the first or second film forming unit P1 (P2) in the first or second film formation region F1 (F2) do not have to be made of the same material. Therefore, for example, one target 10a (110a) may be made of Al and the other target 10b (110b) may be made of Li. By using different materials for them, a composite film (in this case, a Li—Al film) is formed on the substrate B. In addition, by connecting each of the targets 10a and 10b (110a and 110b) to each power supply so as to separately control an input power thereto, a film composition ratio of the composite film can be varied.

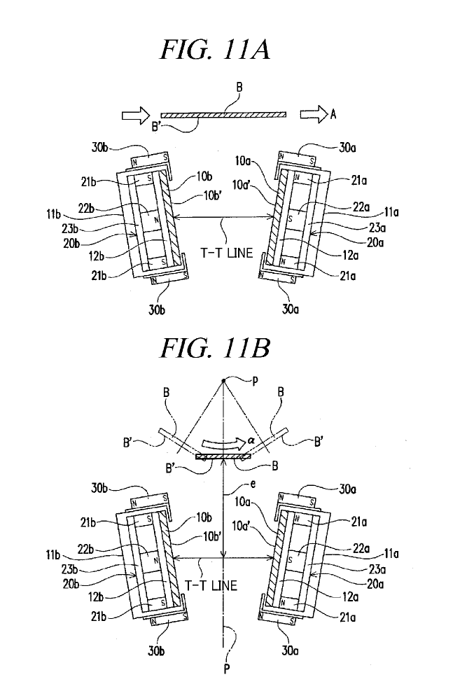

Further, in the present embodiment, the substrate B is fixed at the first film formation position L1 or at the second film formation position L2 when the film formation is carried out, but the present invention is not limited thereto. That is, in case that a film formation area on the film formation target surface B′ of the substrate B is larger than a film formable area by the sputtering apparatus, or in order to form a film having a uniform thickness distribution, it may be possible to perform the film formation while moving the film formation target surface B′ along a line T-T (in an arrow A direction), as illustrate in FIG. 11A. With this configuration, a uniform film can be formed on the elongated substrate B. Furthermore, when the film formation target surface B′ has a revolution center p at a predetermined position on a central line P perpendicular to the center of the line T-T and faces parallel to the line T-T as illustrated in FIG. 11B, the film formation target surface B′ may be configured to move along a revolution orbit (in an arrow a direction) which has a shortest distance e between the center of the film formation target surface B′ and the center of the line T-T. Even with this configuration, a uniform film can be formed on the elongated substrate B. Besides, the film formation target surface B′ may be moved in a one-way direction or a reciprocating direction (or a shaking direction) (in arrow A and a directions).

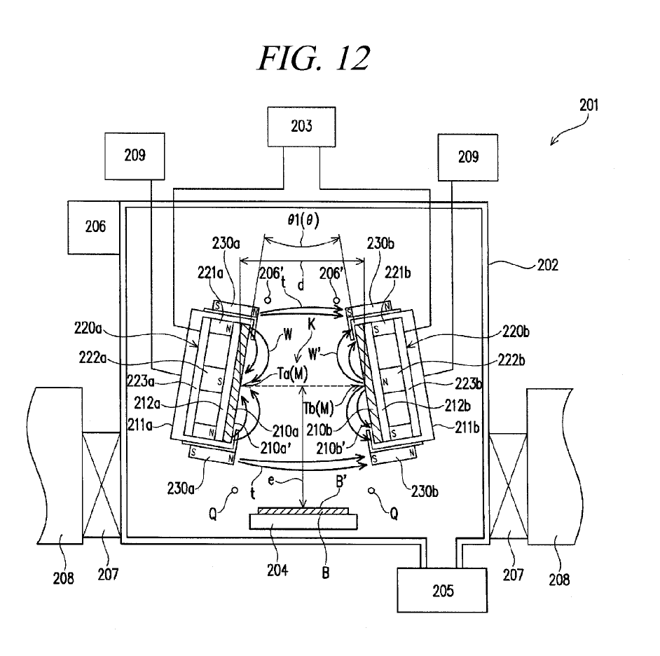

Subsequently, a fourth embodiment of the present invention will be explained with reference to FIGS. 12 to 22.

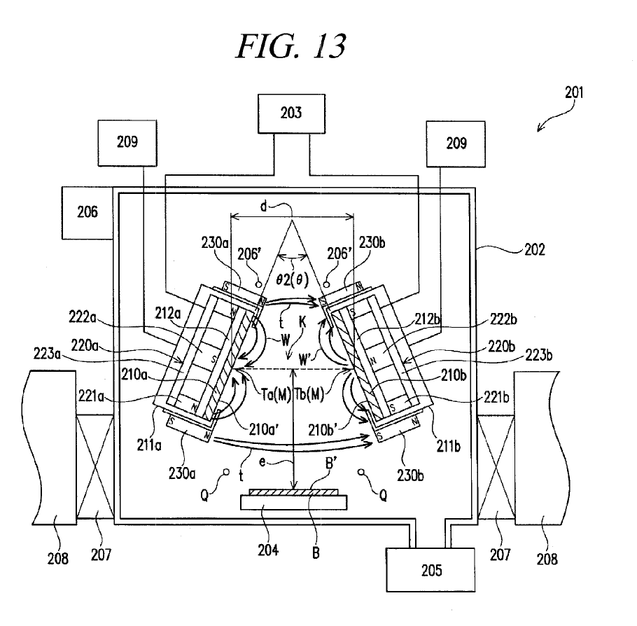

As illustrated in FIGS. 12 and 13, a sputtering apparatus 1 is provided with target holders 211a and 211b for fixing and holding a pair of targets 210a and 210b while allowing their directional changes, a vacuum chamber 202, a sputtering power supply 203, a substrate holder 204, an evacuation unit 205 and a gas supply unit 206. Further, the vacuum chamber 202 is connected to load lock chambers or other processing chambers 208 via communication passages (substrate transfer line valves) 207 at both ends on the side of the substrate holder 204 (lower end side of FIG. 12).

In the present embodiment, each of the pair of targets 210a and 210b is made of ITO (Indium Tin Oxide). Each of the targets 210a and 210b is formed of a rectangular plate-shaped member having a size of about 125 mm (width)×300 mm (length)×5 mm (thickness). In addition, the targets 210a and 210b are disposed to face each other within the vacuum chamber 202 and the facing surfaces (surfaces to be sputtered) 210a′and 210b′ are spaced away from each other at a predetermined distance (here, a distance d between the centers Ta and Tb of the facing surfaces 210a′ and 210b′ is set to be about 160 mm).

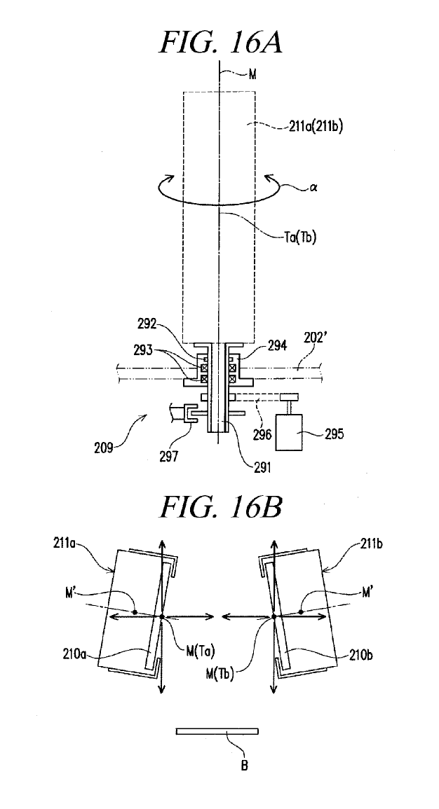

The target holder 211a (211b) is used for fixing and holding the target 210a (210b) via a backing plate 212a (212b) therebetween and is disposed with a target holder rotation unit 209 within the vacuum chamber 202 (see FIG. 16A) so that the facing surface 210a′ (210b′) of the target 210a (210b) can be changed in direction toward the substrate holder 4.

In particular, the target holder 211a (211b) is disposed within the vacuum chamber 202 such that a direction of the facing surface 210a′ (210b′) of one target 210a (210b), which is fixed to and held by the target holder 211a (211b) in parallel with the facing surface 210b′ (210a′) of the other target 210b (210a), can be changed (rotated) with respect to the center Ta (Tb) of the facing surface 210a′ (210b′) or the vicinity of the center Ta (Tb) as a rotation center so as to be oriented toward the film formation target surface B′ of the substrate B fixed to the substrate holder 204 by the target holder rotation unit 209 connected thereto (see FIG. 16A). Further, in the present embodiment, the target holder 211a (211b) can be rotated in a reverse direction (from the substrate B toward the facing surface 210b′).

In other words, the pair of targets 210a and 210b are installed within the vacuum chamber 202 to be changed in direction while being linked with each other such that an angle θ formed between both facing surfaces 210a′ and 210b′, more particularly, an angle θ formed between surfaces extended from the both facing surfaces 210a′ and 210b′ becomes equal to or larger than about 0° but smaller than about 180°. Further, in the present embodiment, when the angle θ formed between the facing surfaces 210a′ and 210b′ is 0°, the facing surfaces 210a′ and 210b′ are parallel to each other; when the angle θ increases, the directions of the facing surfaces 210a′ and 210b′ are changed so that they are more oriented toward the substrate B; and when the angle decreases, the directions of the facing surfaces 210a′ and 210b′ are changed such that they become more parallel to each other.

Provided on an outer surface (a surface opposite to the surface to which the target 210a (210b) is fixed) of the backing plate 212a (212b) for fixing the target 210a (210b) is a curved magnetic field generating unit 220a (220b). The curved magnetic field generating unit generates (forms) a magnetic field space having arc-shaped magnetic force lines (curved magnetic field spaces: see arrows W and W′ of FIGS. 12 and 13) in the vicinity of the facing surface of the target 210a (210b). In the present embodiment, they are made of permanent magnets.

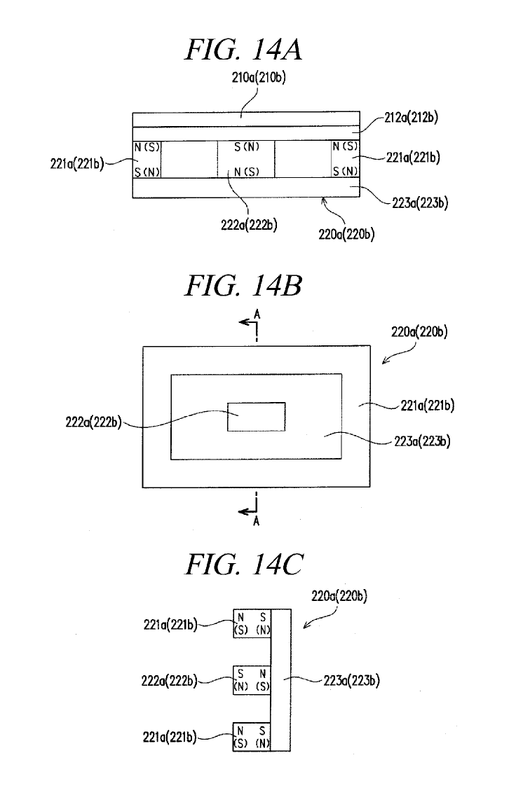

The curved magnetic field generating unit (permanent magnet) 220a (220b) is made of a ferromagnetic substance such as a ferrite-based or neodymium-based (e.g., neodymium, iron, boron, or the like) magnet or a samarium·cobalt-based magnet. In the present embodiment, they are made of ferrite-based magnets. Further, as illustrated in FIG. 14, the curved magnetic field generating unit 220a (220b) has a configuration in which a frame-shaped magnet 221a (221b) and a central magnet 222a (222b) having a magnetic pole opposite to that of the frame-shaped magnet 221a (221b) is disposed at a yoke 223a (223b). To be more specific, the first curved magnetic field generating unit 220a (220b) is configured such that the framed-shaped magnet 221a (221b) and the central magnet 222a (222b) are fixed to the yoke 223a (223b). The framed-shaped magnet 221a (221b) has a rectangular frame shape when viewed from the front; the central magnet 222a (222b) has a rectangular shape when viewed from the front and are located at the center of an opening of the frame-shaped magnet 221a (221b); and the yoke 223a (223b) has the same outer circumference shape as the frame-shaped magnet 221a (221b) and has a plate shape of a certain thickness when viewed from the front (see FIGS. 14B and 14C).

One curved magnetic field generating unit 220a is disposed on an outer surface of the backing plate 212a such that the frame-shaped magnet 221a has an N (S) pole at lateral end portions of the backing plate 212a (i.e., at the lateral end portions of the yoke 223a) while the central magnet 222a has an S (N) pole. The other curved magnetic field generating unit 220b is disposed on an outer surface of the baking plate 212b such that the frame-shaped magnet 221b has an S (N) pole at lateral end portions of the backing plate 212b (i.e., at the lateral end portions of the yoke 223b) and the central magnet 222b has an N (S) pole. In such a configuration, a curved magnetic field space W having magnetic force lines oriented from an outer peripheral portion of the one target 210a's surface (facing surface 210a′) toward a central portion thereof in an arc shape is formed at one target 210a, whereas a curved magnetic field space W′ having magnetic force lines oriented from a central portion of the other target 210b's surface (facing surface 210b′) toward an outer peripheral portion thereof in an arc shape is formed at the other target 210b.

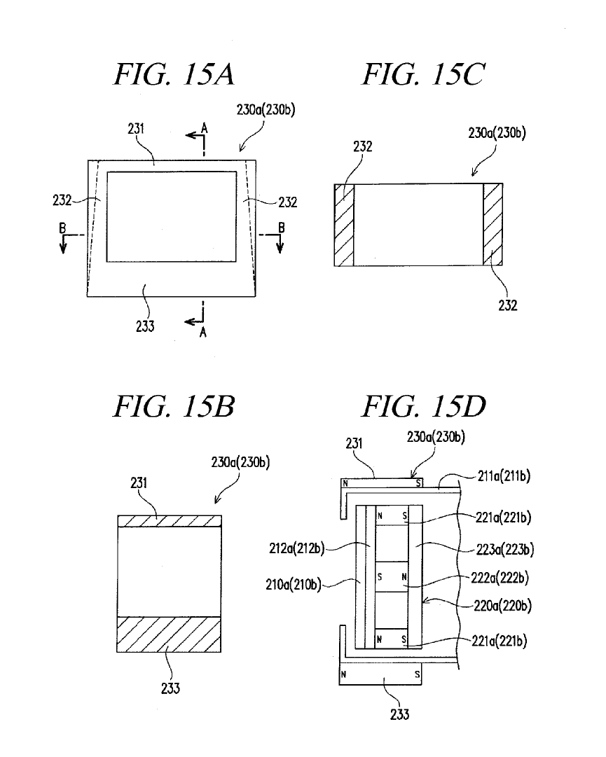

A cylindrical auxiliary magnetic field generating unit 230a (230b) is disposed at a front end portion of the target holder 211a (211b) conforming to its outer periphery. Like the curved magnetic field generating units 220a and 220b, each of the cylindrical auxiliary magnetic field generating units 230a and 230b is made of a permanent magnet and formed in a square (rectangular) tube shape conforming to (capable of being fitted onto) the outer periphery of the target holders 211a and 211b, as depicted in FIG. 15D. In the present embodiment, each of the cylindrical auxiliary magnetic field generating units 230a and 230b made of a neodymium-based substance such as a neodymium·iron·boron magnet is formed in a rectangular frame shape when viewed from the front and formed in a square (rectangular) tube shape having a peripheral wall whose forward-backward directional thickness is uniform (see FIGS. 15B and 15C). The peripheral wall forming the cylindrical auxiliary magnetic field generating unit 230a (230b) is configured such that the thickness thereof is the thinnest at a ceiling wall 231; thicker at sidewalls 232; and the thickest at a bottom wall 233, which is positioned on the side of the substrate B when fitted onto the target holder 211a (211b) as described below, is the largest. Further, in the present embodiment, though the cylindrical auxiliary magnetic field generating unit 230a (230b) is formed in the square (rectangular) tube shape, it may formed in a cylindrical shape or the like as long as it is configured to surround the targets 210a and 210b.

The thickness of the peripheral wall is set so as to allow the strength of the magnetic field at the center points of the respective targets 210a and 210b to be constant when forming an initial layer of a thin film on the film formation target surface B′ of the substrate B, which will be described below. Therefore, a difference in the thickness varies depending on an angle θ1 formed between the two facing surfaces 210a′ and 210b′ when forming the initial layer on the film formation target surface B′ of the substrate B. For this reason, if the angle θ1 during the formation of the initial layer increases, the thickness of the sidewalls 232 may gradually increase from the ceiling wall 231 toward the bottom wall 233 (see dotted lines in FIG. 15A).

Furthermore, the cylindrical auxiliary magnetic field generating unit 230a (230b) is fitted onto the outer periphery of the end portions of the target holder 211a (211b) such that the polarity of the front end thereof is the same as that of the frame-shaped magnet 221a (221b) of the curved magnetic field generating unit 220a (220b) (see FIG. 15D). With this arrangement, a cylindrical auxiliary magnetic field space which surrounds an inter-target space K formed between the targets 210a and 210b and has magnetic force lines oriented from the one target 210a toward the other target 210b is formed so as to (see arrows t of FIGS. 12 and 13).

The target holder rotation unit 209 is configured to rotate the target holder 211a (11b) by being engaged with a shaft unit 291 connected with an end portion of the target holder 211a (211b), as illustrated in FIG. 16A. The shaft unit 291 is provided to penetrate a vacuum chamber wall 202′ airtightly via a bearing member 294 including therein a sealing member 292 and bearings 293 so that it can be rotated (in an arrow a direction in FIG. 16A) with respect to an axis M passing through the center Ta (Tb) of the target 210a (210b) mounted on the target holder 211a (211b) or a center M′ of the target holder 211a (211b) positioned in the vicinity of the center Ta (Tb) as a rotation center. Connected with an outer end portion of the vacuum chamber 202 in the shaft unit 291 via a timing belt 296 is a motor 295 included in the target holder rotation unit 209 and rotating the target holder 211a (211b) around the axis M. Further, provided at an outer end portion of the shaft unit 291 is an angle sensor 297 for detecting a rotation angle of the shaft unit 291.

Moreover, in the present embodiment, each target holder rotation unit 209 is connected with the respective target holders 211a and 211b. That is, each target holder 211a (211b) is rotationally driven by each target holder rotation unit 209 (motor 295), but a configuration thereof is not limited thereto, so a pair of target holders 211a and 211b may be rotationally driven by one target holder rotation unit 209 (motor 295). Besides, in the present embodiment, some components of the target holder rotation unit 209 such as the motor 295, the timing belt 296, the angle sensor 297, and the like are disposed at the outside of the vacuum chamber 202, but all the components of the target holder rotation unit 209 may be disposed within the vacuum chamber 202. Further, with the configuration that the axes M of the target holders 211a and 211b can be moved while being in parallel with each other (see an arrow in FIG. 16B), it is possible to appropriately change the distance d between the target centers and a distance e between a line connecting the centers Ta and Tb of the respective targets 210a and 210b (hereinafter, referred to, simply, as [symbol] line T-T [symbol] and the substrate according to film formation condition.

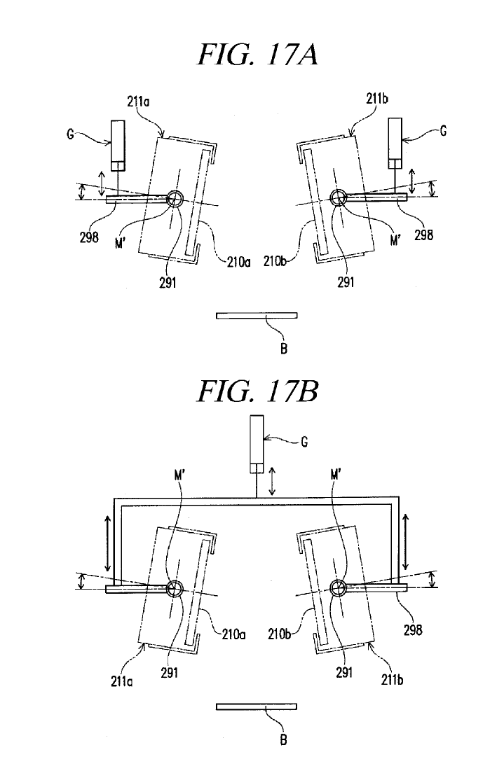

Furthermore, as illustrated in FIGS. 17A and 17B, by connecting a lower portion of the shaft unit 291 of the target holders 11a and 11b with one end side of an arm 298 in a direction perpendicular to the center of the shaft unit 291 and by reciprocating a cylinder or the like (in the present embodiment, an air cylinder G) in connection with the other end side of the arm 298, the angle θ formed between the facing surfaces 210a′ and 210b′ of the targets 210a and 210b may be changed. In this case, it may be possible to connect the target holders 211a and 211b with the air cylinders G respectively as illustrated in FIG. 17A, or it may be possible to link the pair of target holders 211a and 211b so as to be driven in connection with only one air cylinder G as illustrated in FIG. 17B. By using the air cylinder G in this way, cost can be more reduced as compared to a case of using the motor 295.

The sputtering power supply 203 is capable of applying a DC constant power or current, and it supplies a sputtering power while the vacuum chamber 202 at a ground potential (earth potential) serves as an anode and the target 210a (210b) serves as a cathode. Moreover, in the present embodiment, though the sputtering power supply 203 is capable of applying DC constant powers or current, it is not limited thereto. That is, the sputtering power supply 3 can be appropriately changed depending on the material of the target 210a (210b) and the kind of a thin film to be formed (e.g., a metal film, an alloy film, a compound film, and the like). It may be possible to use an AC power supply, an RF power supply, an MF power supply, a pulse-type DC power supply, or it may be also possible to a combination of the DC power supply with the RF power supply. Furthermore, one DC power supply or one RF power supply may be also connected to each target holder 211a (211b).

The substrate holder 204 holds thereon the substrate B and is disposed such that the film formation target surface B′ of the substrate B faces the space (inter-target space) K formed between the two facing surfaces 210a′ and 210b′ of the targets 210a and 210b. In addition, the shortest distance e between the center of the film formation target surface B′ and the straight line (line T-T) connecting the centers Ta and Tb of the two facing surfaces 210a′ and 210b′ of the targets 210a and 210b is set to be equal to about 175 mm in the present embodiment.

The vacuum chamber 202 is connected with the evacuation unit 205 and the gas supply unit 206 for supplying an electric discharge gas. The gas supply unit 206 includes nonreactive gas introduction pipes 206′ for supplying a nonreactive gas (an argon gas (Ar) in the present embodiment) in vicinity of the target 210a (210b).

Furthermore, in the vicinity of the substrate B, it may be possible to provide reactive gas introduction pipes Q for introducing a reactive gas such as O₂, N₂ or the like from a reactive gas supply unit (not illustrated) toward the film formation target surface B′ of the substrate B, in order to manufacture a thin film of dielectric such as oxide or nitride.

The substrate B is a film formation target object having the film formation target surface B′ on which a thin film is to be formed. In the present embodiment, a relationship between the size of the substrate B and the size of targets 210a and 210b for use in the sputtering is generally related with the required degree of film thickness distribution uniformity within the substrate surface (film formation target surface) B′. When the film thickness distribution uniformity is within about ±10%, a relationship between a substrate width S_{W} (mm) of the substrate B, which corresponds to a length of the targets 210a and 210b in a lengthwise direction thereof, and a lengthwise size T_{L} (mm) of the targets 210a and 210b, which corresponds to a length of the substrate B in a widthwise direction thereof, is represented as S_{W}≦T_{L}×0.6˜0.7. Accordingly, in the sputtering apparatus 1 in accordance with the present embodiment, since the rectangular targets each having a size of 125 mm (width)×300 mm (length)×5 mm (thickness) are used, the film formation can be carried out on the substrate B having a substrate width S_{W} of about 200 mm derived from the above-mentioned relationship. In addition, the sputtering apparatus 1 has a configuration in which the film formation is carried out while the substrate is transferred within the apparatus (i.e., the sputtering is performed while the substrate B is transferred in left-right direction of FIG. 12), so that the apparatus can perform the film formation on a substrate having a length equal to or larger than the width thereof even though the length of the substrate B is limited by the size of the apparatus. For example, in the present embodiment, it is be possible to perform the film formation on the substrate B having a size of about 200 mm (width)×200 mm (length), 200 mm (width)×250 mm (length) or 200 mm (width)×300 mm (length) within the range of film thickness distribution of about ±10%. At this time, the substrate B such as an organic EL device or an organic thin film semiconductor, which requires a low-temperature·low-damage film formation, may be used as the substrate B having the film formation target surface B′ on which the thin film is to be formed by the sputtering.

In addition, in the present embodiment, the width of the substrate B corresponds to a length along the lengthwise direction of the targets 210a and 210b, while the length of the substrate B corresponds to a length along a direction perpendicular to the lengthwise direction of the targets 210a and 210b (left-right direction of FIG. 12).

Furthermore, in the present embodiment, a substrate such as an organic EL device or an organic semiconductor, which requires a low-temperature·low-damage film formation, may be used as the substrate B having the film formation target surface B′ on which the thin film is to be formed by the sputtering.

The sputtering apparatus 201 in accordance with the present embodiment is configured as stated above, and there will be explained an operation of a thin film formation in the sputtering apparatus 201 hereinafter.

When carrying out a thin film formation on the film formation target surface B′ of the substrate B in the present embodiment, a second layer is formed by the sputtering enabling a high film forming rate after forming an initial layer (first layer) by the sputtering capable of enabling a low-temperature·low-damage film formation (i.e., a low film forming rate), so that a thin film is formed on the film formation target surface B′. Here, it should be noted that the first layer (initial layer) and the second layer are only distinguished by an imaginary surface where film forming rates is changed in a film thickness direction of a thin film, and the thin film are not actually divided as separate layers in the film thickness direction, but formed as a continuous single thin film layer.

When forming the initial film, the target holder 211a (211b) for mounting thereon the target 210a (210b) is rotationally driven by the target holder rotation unit 209 so that the angle θ formed between the facing surfaces 210a′ and 210b′ of the targets 210a and 201b is set to be a predetermined angle θ1 (smaller than the angle θ2 to be described below) (see FIG. 12). At this time, the angle θ1 formed between the facing surfaces 210a′ and 210b′ is set to be a small angle at which plasma and charged particles such as secondary electrons generated during the sputtering do not cause damage over a certain tolerance to the film formation target surface B′ of the substrate B. In the present embodiment, the angle θ1 is in a range from about 0° to about 30° and desirably, in a range from about 0° to about 10°.

Then, the inside of the vacuum chamber 202 is evacuated by the evacuation unit 205. Thereafter, an argon gas (Ar) is introduced from the nonreactive gas introduction pipes 206′ by the gas supply unit 206 so that a predetermined sputtering pressure (here, about 0.4 Pa) is set.

Subsequently, a sputtering power is supplied to the targets 210a and 210b by the sputtering power supply 3. At this time, since the curved magnetic field generating units 220a and 220b and the cylindrical auxiliary magnetic field generating units 230a and 230b are made of permanent magnets, the curved magnetic field spaces W and W′ are formed on the facing surfaces 210a′ and 210b′ of the targets 210a and 210b, respectively, by the magnetic field generating units 220a and 220b. A cylindrical auxiliary magnetic field space t is formed so as to surround the column-shaped space K formed between the facing surfaces 210a′ and 210b′ of the targets 210a and 210b by the cylindrical auxiliary magnetic field generating units 230a and 230b.

Then, plasma is generated within the curved magnetic field spaces W and W′, whereby the facing surfaces 210a′ and 210b′ of the targets 210a and 210b are sputtered, and the sputtering particles are emitted. Thereafter, plasma escaped from the curved magnetic field spaces W and W′ or charged particles such as secondary electrons released therefrom are trapped within the space (inter-target space) K surrounded by the auxiliary magnetic field space t.

Accordingly, the sputtered particles emitted (ejected due to collisions) from the sputtering surface (facing surface) 210a′ (210b′) of the target 210a (210b) are adhered to the substrate B of which the film formation target surface B′ is disposed to face the inter-target space K at a lateral position of the inter-target space K, whereby the thin film (initial layer of the thin film) is formed.

Generally, in the sputtering performed by disposing the pair of targets 210a and 210b to face each other, the strength of the magnetic field in the inter-target space K increases as the angle θ between the facing surfaces 210a′ and 210b′ of the pair of targets 210a and 210b decreases (i.e., as the facing surfaces become more parallel to each other). Therefore, the amount of the charged particles such as the secondary electrons flying to the substrate B decreases and the effect of confining the plasma within the inter-target space K is improved. However, since the facing surfaces 210a′ and 210b′ become more parallel to each other, the amount of the sputtered particles flying to the substrate B decreases. Thus, though it is possible to perform a low-temperature·low-damage film formation on the substrate, a film forming rate of the thin film formed on the substrate B decreases.

Meanwhile, as the angle θ formed between the facing surfaces 210a′ and 210b′ of the pair of targets 210a and 210b increases (i.e., as the facing surfaces 210a′ and 210b′ are further oriented toward the direction of the substrate B), the distance between end portions of the facing surfaces 210a′ and 210b′ on the side of the substrate may increase, and the strength of the magnetic field strength of the magnetic field in the inter-target space K in that portions may be reduced. Therefore, the amount of the charged particles such as the secondary electrons reaching the substrate B may increase while the effect of confining the plasma within the inter-target space K becomes deteriorated. However, since the facing surfaces 210a′ and 210b′ are further oriented toward the direction of the substrate B, an amount of the sputtered particles reaching the substrate B may increase, so a film forming rate may increase, though a temperature rise of the substrate B and damage on the substrate caused by the charged particles may be also increased as compared to the case where the angle θ is set smaller.

In this regard, the angle θ1 between the facing surfaces 210a′ and 210b′ is set to be almost parallel to each other (i.e., small) such that the plasma and the charged particles such as secondary electrons may not damage the substrate B during the sputtering beyond a tolerance limit. In this manner, the effect of confining the plasma and the charged particles such as secondary electrons in the inter-target space K may be ameliorated.

Furthermore, since the cylindrical auxiliary magnetic field generating units 230a and 230b are separately provided, a cylindrical auxiliary magnetic field space t is formed outside the inter-target space K. For this reason, the cylindrical auxiliary magnetic field space t is formed between the curved magnetic field space W (W′) formed on the target surface (facing surface) 210a′ (210b′) and the substrate B, and the plasma escaped from the curved magnetic field space W (W′) is trapped by the cylindrical auxiliary magnetic field space t (i.e., its escape toward the substrate B is suppressed), so that the influence of the plasma upon the substrate B can be more reduced.

Furthermore, as for the charged particles such as the secondary electrons released from the curved magnetic field space W (W′) toward the substrate B, since the cylindrical auxiliary magnetic field space t is formed between the curved magnetic field space W (W′) and the substrate B so as to surround the inter-target space K, the effect of confining the charged particles in the inter-target space K is enhanced. That is, the release of the charged particles from the inter-target space K toward the substrate B may be further reduced.

Moreover, since the cylindrical auxiliary magnetic field generating unit 230a (230b) is arranged such that its the bottom wall 233 having the greatest thickness is placed on the side (substrate B side) where the distance between the facing surfaces of the pair of targets 210a and 210b increases, the strength of the magnetic field in the vicinity of the cylindrical auxiliary magnetic field generating unit 230a (230b) may be enhanced as the distance between the facing surfaces of the pair of targets 210a and 210b increases.

If the strengths of the magnetic field were set to be the same in the vicinities of the respective cylindrical auxiliary magnetic field generating units 230a and 230b which are arranged along the peripheries of the targets 210a and 210b, the strength of the magnetic field at a midway point between one target 210a and the other target 210b would be weakened as the distance between the facing surfaces is increased when the facing surfaces (sputtering surfaces) 210a′ and 210b′ of the targets 210a and 210b are inclined so as to face toward the film formation surface B′ of the substrate B (when the angle θ>0°. As a result, the plasma would escape from that region (substrate B side) where the strength of the magnetic field is reduced and the charged particles such as the secondary electrons would be released therefrom, so that the substrate B may be damaged.

However, if the cylindrical auxiliary magnetic field generating units 230a and 230b have the above-described configuration, the strength of the magnetic field at the midway point can be constant because the strength of the magnetic field in the vicinities of the cylindrical auxiliary magnetic field generating units 230a and 230b is set to increase as the distance between the facing surfaces increases.

Accordingly, even in the arrangement (so-called V-shaped facing-target arrangement) where the targets 210a and 210b are inclined toward the substrate B, it is possible to effectively suppress the escape of the plasma or the release of the charged particles such as the secondary electrons from where the distance between the facing surfaces 210a′ and 210b′ is increased, so that the effect of confining the plasma and the charged particles such as the secondary electrons can be improved and the low-temperature·low-damage film formation can be performed.

Further, the cylindrical auxiliary magnetic field generating unit 230a (230b) may be set as one of an earth potential, a minus potential, a plus potential or a floating (electrically insulated state), or may be set such that the earth potential and the minus potential or the earth potential and the plus potential are alternately switched in time. By setting the potential of the cylindrical auxiliary magnetic field generating unit 230a (230b) to be one of the above-mentioned potentials, a electric discharge voltage can be reduced as compared to a magnetron sputtering apparatus of a V-type facing-target arrangement (a conventional magnetron sputtering apparatus), which does not have the cylindrical auxiliary magnetic field generating units 230a and 230b and has a pair of magnetron cathodes including facing surfaces of targets inclined toward the substrate.

As stated above, the sputtering can be performed with a high effect of confining the charged particles such as the secondary electrons and the plasma generated by the sputtering performed in the inter-target space K. For this reason, the influence of the plasma and the secondary electrons flown from the sputtering surface 201a (210b) on the film formation target surface B′ of the substrate B can be reduced greatly, so that the initial layer of the thin film can be formed by the low-temperature·low-damage film formation. In the present embodiment, the initial layer is formed in a film thickness of about 10 to 20 nm.

Thereafter, in order to form the second layer, the sputtering performed under the film formation condition (the angle θ1 formed between the facing surfaces 210a′ and 210b′) in the initial layer formation is stopped. Then, the target holder 211a (211b) is rotationally driven (changed in direction (changed in posture)) by the target holder rotation unit 209 so that the angle θ formed between the facing surfaces 210a′ and 210b′ of the targets 210a and 210b is increased from θ1 to θ2 and is then changed in direction such that the facing surfaces 210a′ and 210b′ of the targets 210a and 210b held by the target holders 211a and 211b face toward the substrate B (see FIG. 13). In this state (after the direction change), the sputtering is started so as to form the second layer. In the present embodiment, the angle θ2 is in a range from about 45° to about 180° and desirably, in a range from about 30° to about 45°. Further, since the initial layer (first layer) is formed so as to function as a protective film for preventing damage caused by a formation of the second film, the damage on the substrate B caused by a formation of the second film layer can be suppressed. For this reason, it is desirable to perform the film formation with the increased angle θ2 in consideration of productivity.

By performing the film formation at the angle θ2 larger than the angle θ1 at which the initial layer was formed, the distance between end portions of the facing surfaces 210a′ and 210b′ on the substrate's side increases. Therefore, the strength of the magnetic field in the cylindrical auxiliary magnetic field space t on the substrate's side is decreased, whereby the effect of confining the plasma and the charged particles within the inter-target space K becomes decreased and the influence of the plasma on the substrate B and the amount of the charged particles reaching the substrate B increase. However, since the facing surfaces 210a′ and 210b′ are further oriented toward the substrate B, the amount of the emitted (second) sputtered particles, which are generated by sputtering the sputtering surfaces (facing surfaces) 210a′ and 210b′ and then reach the substrate B (the film formation target surface B′), may be increased. Therefore, a film forming rate would be increased. In this way, at a film forming rate higher than that in the initial layer formation, the second layer is formed on the initial layer. In the present embodiment, the second layer is formed in a film thickness ranging from about 100 nm to about 150 nm.

As stated above, when the initial layer (first layer) and the second layer are formed on the film formation target surface B′ after the film forming rate is changed by varying the angle θ formed between the facing surfaces 210a′ and 210b′ of the targets 210a and 210b, the angles θ1 and θ2 meets a condition of θ1<θ2. When the input powers to the targets 210a and 210b are the same, the film forming rate of the second layer can be increased to about 20 to 50% of the film forming rate of the first layer. In addition, by increasing the input power at the angle θ2, the film forming rate can be raised two times or more.

From the above explanation, the sputtering is performed by setting the angle θ formed between the facing surfaces 210a′ and 210b′ to be a predetermined angle (small angle) θ1. Therefore, though the film forming rate is small, the effect of confining the plasma and the charged particles generated by sputtering within the inter-target space K becomes improved. Accordingly, the low-temperature·low-damage film formation can be performed on the substrate B up to a predetermined thickness and the initial layer (first layer) is deposited (formed) by such a low-temperature·low-damage film formation.

Thereafter, the target holder 211a (211b) is rotationally driven by the target holder rotation unit 209 without changing the sputtering condition such as a pressure within the vacuum chamber 2 and the facing surface 210a′ (210b′) is changed in direction toward the substrate B, so that sputtering is performed by increasing the angle θ1 to the angle θ2. Therefore, the influence of the charged particles such as the secondary electrons and the plasma reaching the substrate is increased but the second layer can be formed by increasing the film forming rate.

In this way, since the initial layer is formed on the substrate B by the low-temperature·low-damage film formation so as to function as a protective film, i.e., by covering the substrate with the initial layer, the film formation can be performed while suppressing the damage on the substrate B caused by the charged particles such as the secondary electrons in the second film formation and the plasma on the substrate B. Further, when forming the second layer (after the time of forming the first layer with the low-temperature and low-damage before the time of forming the second layer with the increased film forming rate), the angle θ formed between the pair of targets 210a and 210b is changed from the angle θ1 to the angle θ2 without changing the sputtering condition such as the pressure within the vacuum chamber 202, so that a film formation time (entire film formation processing time) can be reduced. To be specific, in the present embodiment, the entire film formation processing time, during which the sputtering is performed by changing the angle θ between the facing surfaces 210a′ and 210b′ of the pair of targets 210a and 210b twice or more with the same input power, is shorter than the sputtering time performed without changing the angle θ by about 30% or more.

Further, by providing the cylindrical auxiliary magnetic field generating units 230a (230b) fitted onto the outer periphery of the end portions of the target holder 211a (211b), formed is the cylindrical auxiliary magnetic field space t which is extended from the vicinity of one target 210a to the vicinity of the other target 210b in a cylinder shape and has magnetic force lines oriented from the vicinity of one target 210a toward the vicinity of the other target 210b. Thus, the plasma escaped from the inside of the curved magnetic field spaces W and W′ on the target facing surfaces 210a′ and 210b′ and the charged particles released therefrom during the sputtering are trapped in the cylindrical auxiliary magnetic field space t.

That is, since both ends of the cylindrical auxiliary magnetic field space t are enclosed by the facing surfaces 210a′ and 210b′ of the targets 210a and 210b, the plasma escaped from the curved magnetic field spaces W and W′ formed on the target surfaces (facing surfaces) 210a′ and 210b′ is trapped by the cylindrical auxiliary magnetic field space t (i.e., the plasma ejection toward the substrate is suppressed), so that the influence of the plasma upon the substrate B can be reduced.

Furthermore, since both ends of the cylindrical auxiliary magnetic field space t are enclosed by the facing surfaces 210a′ and 210b′ of the targets 210a and 210b, the charged particles such as the secondary electrons released from the curved magnetic field spaces W and W′ toward the substrate can also be trapped in the cylindrical auxiliary magnetic field space t, so that the amount of the charged particles reaching the substrate B can be reduced

Moreover, since the magnetron sputtering cathode is used, even when the current value inputted to the magnetron cathode (target) 210a (210b) during the sputtering is increased, an unstable discharge due to plasma concentration at a central portion, which may occur in case of the facing target type sputtering, does not occur. Therefore, the plasma generated in the vicinities of the target surfaces can be electrically discharged stably for a long time.

In addition, since the magnetic field strength of the cylindrical auxiliary magnetic field space t is greater than the magnetic field strengths of the curved magnetic field spaces W and W′, there can be obtained a magnetic field distribution in which the magnetic field strength in the vicinities of the facing surfaces is the weakest at the center sides of the targets 210a and 210b and the strongest at the peripheral portions of the targets 210a and 210b. Further, the effect of confining the plasma escaped from the curved magnetic field spaces W and W′ and the charged particles such as the secondary electrons released therefrom within the cylindrical auxiliary magnetic field space t can be further improved.

Therefore, the influence of the plasma and the influence of the charged particles such as the secondary electrons flying from the sputtering surfaces (facing surfaces) 210a′ and 120b′ upon the substrate B used as the film formation target object can be minimized without having to shorten the distance between the centers of the pair of first targets 210a and 210b. As a result, the low-temperature·low-damage film formation can be performed, thereby improving a film quality. Furthermore, if a required film property is approximately the same with that of a thin film formed by the sputtering which does not generate the first cylindrical auxiliary magnetic field space t1, the angle θ formed between the facing surfaces 210a′ and 210b′ of the pair of targets 210a and 210b can be further increased.

Accordingly, with the cylindrical auxiliary magnetic field generating units 230a and 230b, the angle θ1 formed between the facing surfaces 210a′ and 210b′ can be increased while maintaining the low-temperature·low-damage film formation on the substrate B, and as a result, the time of forming the initial layer can be reduced. Furthermore, since the film forming rate of the second layer can be further increased, the entire film formation processing time can be further reduced.

Moreover, the sputtering method and the sputtering apparatus in accordance with the present invention are not limited to the aforementioned fourth embodiment but can be modified in various ways within a scope of the present invention.

In the present embodiment, as cathodes, there are used the magnetron cathodes which generate the curved magnetic field space W (W′) on the target facing surface 210a′ (210b′) and perform the sputtering with the plasma trapped within the magnetic field space W (W′) and there are employed the complex type cathodes in which the cylindrical auxiliary magnetic field generating units 230a and 230b are disposed in the outer peripheral portions of the magnetron cathodes to face each other. However, the present invention is not limited thereto.

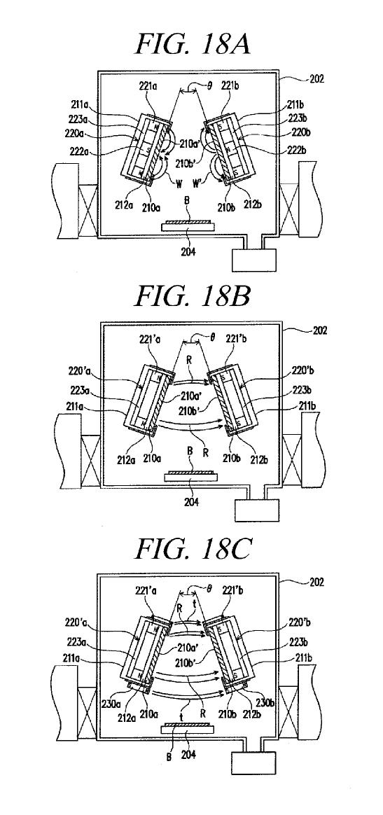

For example, as illustrated in FIGS. 18A and 18B, only the curved magnetic field generating unit 220a (220b) may be disposed on the rear surface side of the target 210a (210b) and a pair of magnetron cathodes which do not include the cylindrical auxiliary magnetic field generating units 230a and 230b may be arranged to face each other. Further, it may be possible to use facing target-type cathodes in which the targets 210a and 210b are arranged to face each other and an inter-target magnetic field generating unit 220′a (220′b) for generating an inter-target magnetic field space R between the targets 210a and 210b is arranged on the rear surface thereof so that magnetic force lines are oriented from one target 210a toward the other target 210b.

Such a cathode may be used as long as when forming the thin film on the substrate B, the angle θ1 formed between the facing surfaces 210a′ and 210b′ of the targets 210a and 210b in the initial layer formation is smaller than the angle θ2 formed between the facing surfaces 210a′ and 210b′ in the second layer formation; and the angle θ1 may be also set to be an angle at which the charged particles such as secondary electrons or the plasma generated during the sputtering may not damage the film formation target surface B′ of the substrate B, i.e., a film formation target object beyond a certain tolerance limit. In this way, the initial layer formed at the angle θ1 functions as the protective layer. Accordingly, even if the amount of the charged particles reaching the substrate B or the influence of the plasma generated by the sputtering increases when the second layer is formed at an increased film forming rate, it is possible to prevent the film formation target surface B′ of the substrate B from being damaged, due to the presence of the initial layer serving as the protective layer.

As a result, it is possible to form a thin film (an electrode film, a protective film, a sealing film or the like) on a substrate (e.g., an EL device) in need of the low-temperature·low-damage film formation. Moreover, since the film forming rate can be increased after the initial layer formation, it is possible to reduce the entire film formation processing time.

Further, as illustrated in FIG. 18C, there may be further provided the cylindrical auxiliary magnetic field generating units 230a and 230b, which surround the outside of the inter-target magnetic field space R so that magnetic force lines in outer peripheries of the facing target-type cathodes are oriented in the same direction, and generates the cylindrical auxiliary magnetic field space t having the strength of the magnetic field stronger than that of the inter-target magnetic field space R, in order to surround the targets 210a and 210b.

In this way, since the cylindrical auxiliary magnetic field space t is further formed so as to surround the outside of the inter-target magnetic field space R, a distance from a central line of the inter-target magnetic field space R to the end of a space having a high magnetic flux density is increased, and plasma is not escaped from a magnetic field space (trapping magnetic field space) R+t including the inter-target magnetic field space R and the cylindrical auxiliary magnetic field space t formed in the outside thereof, thereby trapping the plasma within the trapping magnetic field space R+t. In this way, by trapping the plasma within the trapping magnetic field space R+t, the influence of the plasma on the substrate can be reduced.

Further, conventionally, an inter-target magnetic field generating unit 221′a (221′b) is disposed only on the rear surface side (opposite to the facing surface) of the target 210a (210b) in the facing target-type cathode. If an input power applied to the cathode is increased, plasma between the targets is concentrated in a central portion, and erosion is increased at the central portion of the target 210a (210b). This phenomenon becomes more conspicuous when the target 210a (210b) is made of a magnetic body as compared to when the target 210a (210b) is made of a non-magnetic body, since the target 210a (210b) becomes a yoke. However, with the configuration stated above, since the trapping magnetic field space R+t has the magnetic field distribution in which the strength of the magnetic field increases outwardly, even if the target 210a (210b) is made of the magnetic body, it is possible to reduce the concentration of the plasma in the central portion of the trapping magnetic field space (inter-target magnetic field space) R+t, which is caused by the increase of the input power to the cathode and there occurs no particular increase in the erosion at the central portion. For this reason, even if the target 210a (210b) is made of the magnetic body, a decrease in utilization efficiency of the target can be suppressed and a distribution of a film thickness of the thin film formed on the substrate B becomes even (uniform).

Accordingly, the lower-temperature·lower-damage film formation can be more facilitated and the film quality can be further improved. Further, if the film quality is approximately the same as a film quality of a thin film formed by the sputtering which does not generate the cylindrical auxiliary magnetic field space t, the angle θ formed between the facing surfaces 210a′ and 210b′ of the pair of targets 210a and 210b can be further increased and the productivity can be improved by the increased film forming rate.

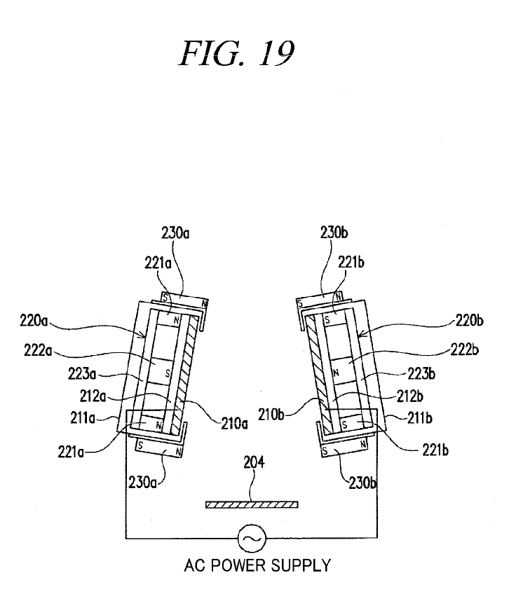

Furthermore, in the present embodiment, the power applied to the target (cathode) 210a and 210b may be an AC power supply as illustrated in FIG. 19, in particular, an AC power supply capable of applying an AC electric field having a phase difference of about 180° to each of the pair of targets.

In case of forming a thin film made of a dielectric material such as oxide or nitride (for use as, e.g., an protective film or a sealing film for an organic EL device), there is used a method in which reactive gases (O₂, N₂, and the like) are introduced toward the substrate B from reactive gas introduction pipes Q (see FIGS. 12 and 13) provided between the targets 210a and 210b or in the vicinity of the substrate B and the sputtered particles flying from the target 210a (210b) and the reactive gases react with each other, and thus the thin film made of a compound such as oxide·nitride is formed on the substrate B. In this case of the reactive sputtering, the surface 210a′ (210b′) of the target 210a (210b) is oxidized and reaction products such as the oxide and the nitride are adhered to uneroded regions of a protection plate, an earth shield and the target 210a (210b), whereby an abnormal arc discharge occurs frequently and a stable discharge can not be carried out. Further, a quality of the film deposited on the substrate B is deteriorated. Furthermore, even in case of forming an ITO film serving as a transparent conductive film by using an ITO target, sputtering is carried out by introducing a small amount of an O₂ gas to form a high quality of ITO film. Even in this case, if film formation is performed for a long time, the phenomenon as described above occurs.

It can be deemed that as a cause of such an abnormal arc discharge, the target surface 210a′ (210b′) is charged up due to the oxide or the nitride, and a chamber wall, the protection plate and the earth shield serving as an anode with respect to the target (cathode) 210a (210b) are covered with the oxide or the nitride, whereby the size of the anodes becomes small or non-uniform.

By employing the above-described configuration in order to solve such problems, if the negative potential is applied to one target (cathode) 210a, the positive potential or the earth potential is applied to the other target (cathode) 210b. Therefore, the other target (cathode) 210b serves as an anode, so that the one target (cathode) 210a to which the negative potential is applied is sputtered. Further, if the negative potential is applied to the other target 210b, the positive potential or the earth potential is applied to the one target 210a. Therefore, the one target 210a serves as an anode, so that the other target 210b is sputtered. In this way, by alternately switching the potentials to be applied to the targets (cathodes), charge-up (damage) caused by oxide and nitride does not occur on the target surface and a stable electric discharge can be carried out for a long time.

For example, in case that the transparent conductive film is formed by using the ITO target, in order to form a high quality film with a low resistance (resistivity of about 6×10⁻⁴ Ω·cm or less without heating the substrate) and a high transmittance (about 85% or more at a wavelength of about 550 nm), an O₂ gas in a range from about 2 sccm to about 5 sccm is introduced with respect to an Ar gas of 50 sccm. In this case, despite a long time electric discharge, by alternatively switching the potentials to be applied to the pair of targets 10a and 10b by the AC power supply, the charge-up caused by oxidization does not occur on the target surface 210a′ (210b′), and by the targets 210a and 210b serving as the cathode and the anode respectively, a stable electric discharge can be performed.

Further, as an another example, a reactive sputtering is performed by using a Si target and introducing an O₂ gas serving as an reactive gas to form a SiOx film as a protective film and sealing film for the organic EL device. In this case, the abnormal arc discharge is more frequently generated in a DC reactive sputtering using a conventional DC power supply than in a case of forming the ITO film. However, by connecting with the AC power supply, the charge-up caused by oxidization does not occur on the target surfaces 210a′ and 210b′ in the same manner as in a case where the ITO film is formed, and the stable electric discharge can be performed for a long time.

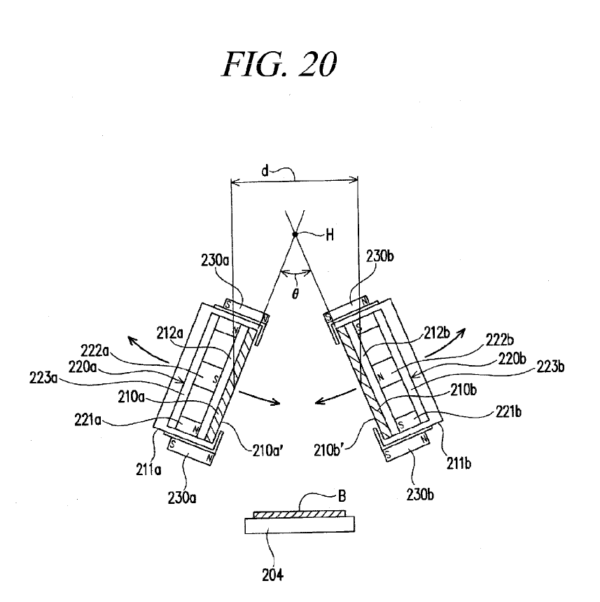

Furthermore, in the present embodiment, the target holder 211a (211b) is configured so as to be changed in direction by the target holder rotation unit 209 with respect to the axis M passing through the center Ta (Tb) of the facing surface 210a′ (210b′) of the target 210a (210b) fixed to and held by the target holder 211a (211b) or the central axis M′ of the target holder 211a (211b) as a rotation center (see FIGS. 16A and 16B), but the configuration thereof is not limited thereto. As illustrated in FIG. 20, it may be configured that the targets 210a and 210b are in contact with each other or are separate from each other with a predetermined imaginary point H as a rotation center. That is, when the angle θ is changed, the distance d between the centers of the targets 210a and 210b may or may not be changed.

Moreover, in the first embodiment, the pair of targets 210a and 210b do not have to be made of the same material. Therefore, for example, one target 210a may be made of Al and the other target 210b may be made of Li. By using different materials for them, a composite film (in this case, a Li—Al film) is formed on the substrate B. In addition, by connecting each of the targets 210a and 210b to each power supply so as to separately control an input power, a film composition ratio of the composite film can be varied.

Besides, in the present embodiment, after the initial layer formation, the sputtering is stopped and the angle between the target facing surfaces 210a′ and 210b′ is changed from the angle θ1 to the angle θ2 by changing the direction of the target holder 211a (211b), and then the sputtering is started again so as to form the second layer. However, the present embodiment is not limited thereto. For example, the direction of the target holder 211a (211b) may be changed so that the angle is gradually changed from the angle θ1 to the angle θ2 while the sputtering is continued after the initial layer formation.

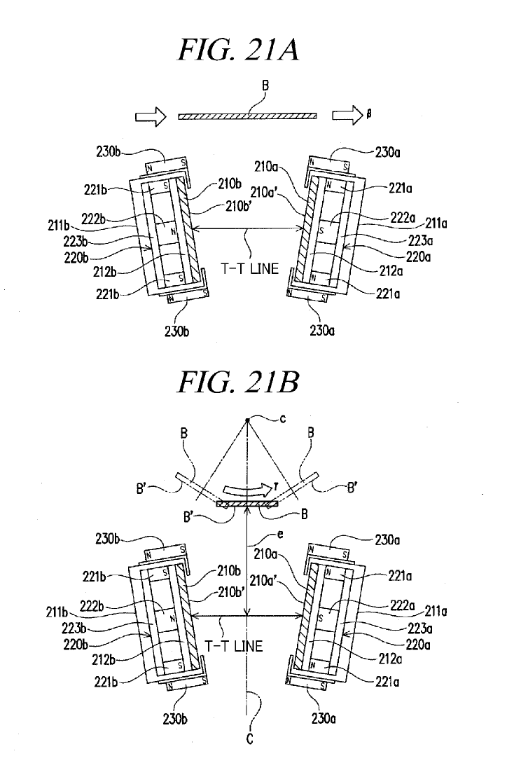

Further, in the present embodiment, in case that a film formation area on the film formation target surface B′ of the substrate B is larger than a film formable area by the sputtering apparatus, or in order to form a film having a uniform thickness distribution, the film formation target surface B′ of the substrate B is configured to move along a line T-T (in an arrow β direction) as illustrated in FIG. 21A. As long as a uniform film formation can be performed on an elongated substrate B, the present embodiment is not limited thereto. In other words, when the film formation target surface B′ has a revolution center p set at a predetermined position on a central line C perpendicular to the center of the line T-T and faces parallel to the line T-T as illustrated in FIG. 21B, the film formation target surface B′ may be arranged to move along a revolution orbit (in arrow γ direction) having the shortest distance e between the center of the film formation target surface B′ and the center of the line T-T. Even with this configuration, a film formation can be performed on the elongated substrate B. Besides, the film formation target surface B′ may move in a one-way direction or a reciprocating direction (or a shaking direction) (arrows β and γ).

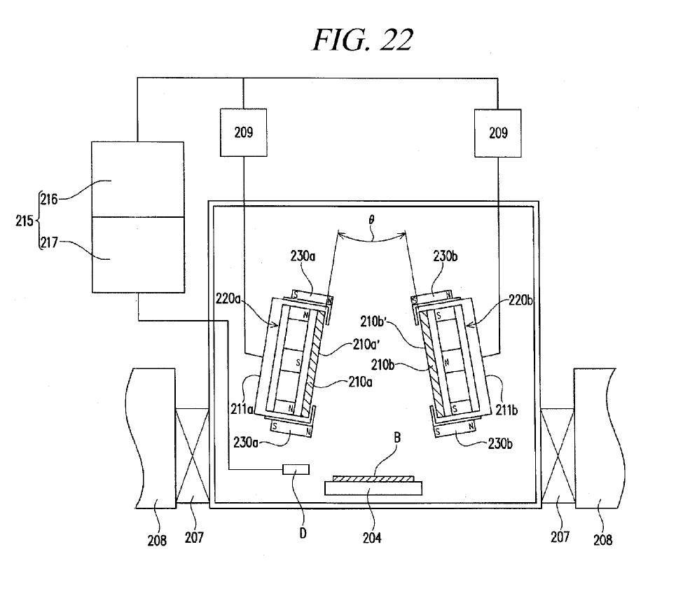

Furthermore, as illustrated in FIG. 22, when the substrate B is held on the substrate holder 204, the sputtering apparatus 201 may include a detection unit (detecting sensor) D for detecting at least one of the film thickness and the temperature. The detection unit D is provided at a position facing a flow path of the sputtered particles flying from each target 210a (210b) of the pair of targets 210a and 210b toward the substrate B (film formation target surface B′ of the substrate B) in the vicinity of the substrate B. The sputtering apparatus 201 may further include a control unit 250 for controlling a rotational driving of the target holder rotation unit 209 (motor 295) so as to change the direction of each target 210a (210b) based on detected values (detection values) detected by the detection unit D.

With this configuration, for example, if the detection unit D is a film thickness detecting sensor D using a quartz oscillator, the film thickness detecting sensor D can obtain detection values including an amount of the sputtered particles (film thickness) and a variation in the film thickness per unit time (film forming rate) based on a variation in a frequency caused by the sputtered particles adhered to the quartz oscillator. Besides, based on these detection values, the control unit 215 obtains the film thickness of the thin film formed on the film formation target surface B′ of the substrate B and the film forming rate.

Moreover, the control unit 215 compares the detection values detected by the film thickness detecting sensor D with a first film formation condition (a film forming rate at which an film interface B′ of the substrate B in need of the low-temperature·low-damage film formation is not damaged and a film thickness with which the initial layer serves as a protective film) of the initial layer formed on the substrate B, and if it is determined that the detection values are different from the first film formation condition of the initial layer, the direction (angle) of each target 210a (210b) ((motor 295 within) the target holder rotation unit 209) is controlled so that the angle θ between the facing surfaces 210a′ and 210b′ of the pair of targets 210a and 210b satisfies the first film formation condition of the initial layer. Then, if it is determined that the formation of the initial layer is completed, each target 210a (210b) is changed in direction (in posture) again so as to satisfy a first film formation condition of the second layer.

Further, for example, if the detection unit D is a temperature detecting sensor D using a thermometer, the temperature detecting sensor D can obtain detection values including temperatures in the vicinity of the substrate B and a variation in the temperature per unit time (increase in the temperature). Besides, based on these detection values, the control unit 215 obtains the temperature on the film formation target surface B′ of the substrate B and the variation in the temperature.

Furthermore, the control unit 215 compares the detection values detected by the temperature detecting sensor D with a second film formation condition (temperature at which the interface B′ of the substrate B in need of the low-temperature-low-damage film formation is not damaged and an increase in the temperature during the film formation time) of the initial layer formed on the substrate B, and if it is determined that the detection values are different from the second film formation condition of the initial layer, the direction (angle) of each target 210a (210b) ((motor 295 within) the target holder rotation unit 209) is controlled so that the angle θ between the facing surfaces 210a′ and 210b′ of the pair of targets 210a and 210b satisfies the second film formation condition of the initial layer. Then, if it is determined that the formation of the initial layer is completed, each target is changed in direction (in posture) so as to satisfy a second film formation condition of the second layer.

As stated above, the detection values detected by the detection unit D are fed back to the angle formed between the facing surfaces 210a′ and 210b′ of the pair of targets 210a and 210b by the control unit 215, so that the initial layer on the film formation target surface B′ of the substrate B is formed according to the first or second film formation condition of the initial layer, the film formation can be performed on the substrate B in need of the low-temperature·low-damage film formation in a shortest film formation time without causing damage thereto or without forming the initial layer thicker than needs.

Moreover, if the detection unit D is a combined detecting sensor D combining the film thickness detecting sensor with the temperature detecting sensor, the combined detecting sensor D can obtain detection values including the amount of the sputtered particles adhered to the quartz oscillator (film thickness), the variation in the film thickness per unit time (film forming rate), the temperatures in the vicinity of the substrate B and the variation in the temperature per unit time (increase in the temperature). Besides, based on these detection values, the control unit 215 obtains the thickness of the thin film formed on the film formation target surface B′ of the substrate B, the film forming rate, the temperature on the film formation target surface B′ of the substrate B and the variation in the temperature.

The control unit 215 compares the detection value of the variation in the film thickness detected by the combined detecting sensor D with the first film formation condition of the initial layer, and compares the detection value of the variation in the temperature detected by the combined detecting sensor D with the second film formation condition of the initial layer, and if it is determined that the detection value of the variation in the film thickness is different from the first film formation condition of the initial layer or if it is determined that the detection value of the variation in the temperature is different from the second film formation condition of the initial layer, the direction (angle) of each target 210a (210b) ((motor 295 within) the target holder rotation unit 209) is controlled so that the angle θ formed between the facing surfaces 210a′ and 210b′ of the pair of targets 210a and 210b satisfies at least one of the first and second film formation condition of the initial layer. Then, if it is determined that the formation of the initial layer is completed, each target is changed in direction (in posture) so as to satisfy the first and second film formation conditions of the second layer.

As a result, since the initial layer formed on the film formation target surface B′ of the substrate B is formed according to the first and second film formation conditions of the initial layer, the film formation can be performed on the substrate B in need of the low-temperature·low-damage film formation in a shortest film formation time without causing damage thereto or without forming the initial layer thicker than needs, as compared to a case where the detection unit D is made of either one of the film thickness detecting sensor and the temperature detecting sensor.

As stated above, the status of the film formation on the substrate B can be detected by using the detection unit D and the control unit 215, and thus the angle θ formed between the facing surfaces of the pair of targets can be controlled by feedback of the detection values.

Further, it is desirable that the detection unit D may detect at least one of the film thickness and the temperature and may be made up of either one of the film thickness detecting sensor and the temperature detecting sensor, or a combination thereof. Furthermore, the number of the detecting sensor D is not limited to one but may be plural. In this way, it is possible to more accurately detect the status of the film formation (film forming rate, temperature, increase in temperature, and the like) and to control the angle θ formed between the facing surfaces 210a′ and 210b′ of the pair of targets 210a and 210b to an optimal value.

Furthermore, the control unit 215 may include a detection unit controller 216 for controlling the detection unit D and a target holder rotation unit controller 217 for controlling a rotation driving of the target holder rotation unit 209 based on the detection values. In this case, the detection unit controller 216 and the target holder rotation unit controller 217 may be integrated in one body or may be installed in different bodies.

1. A sputtering method for forming, in a vacuum chamber, an initial layer on a film formation target object and then further forming a second layer on the initial layer therein, the method comprising:
in the vacuum chamber, arranging surfaces of a pair of targets to face each other while distanced apart from each other at a preset distance and to be inclined toward the film formation target object placed at a lateral position between the targets, and then sputtering the targets by generating a magnetic field space on the facing surfaces of the pair of targets, and thus forming the initial layer on the film formation target object by using particles sputtered by the sputtering; and
further forming the second layer on the film formation target object at a higher film forming rate than a film forming rate of the initial layer.

2. The sputtering method of claim 1, wherein in the vacuum chamber whose inner space is divided into a first film formation region having a first film forming unit for forming the initial layer and a second film formation region having a second film forming unit for forming the second layer, the first film forming unit and the second film forming unit are arranged in juxtaposition,
the initial layer is formed on the film formation target object in the first film forming unit,
then, the film formation target object is transferred from a first film formation position where the film formation is performed on the film formation target object in the first film forming unit to a second film formation position where the film formation is performed on the film formation target object in the second film forming unit, the second layer is further formed on the film formation target object in the second film forming unit, and
the method includes:
disposing the pair of targets in the first film forming unit as first targets;
generating, on a surface side of one of the first targets, an arc-shaped inwardly curved magnetic field space having magnetic force lines oriented from an outer peripheral portion toward a central portion of the one first target and generating, on a surface side of the other first target, an arc-shaped outwardly curved magnetic field space having magnetic force lines oriented from a central portion toward an outer periphery of the other first target;
performing sputtering by generating a cylindrical auxiliary magnetic field space, which has magnetic force lines oriented from a vicinity of the one first target toward a vicinity of the other first target while surrounding a first inter-target space formed between the first targets and has a magnetic field strength greater than that of the curved magnetic field space, and thus forming the initial layer on the film formation target object by using first particles sputtered by the sputtering; and
performing sputtering by generating an inwardly curved magnetic field space or an outwardly curved magnetic field space on surface sides of second targets in the second film forming unit, and forming the second layer on the film formation target object by second particles sputtered by the sputtering.

3. The sputtering method of claim 2, wherein a plurality of first film forming units is arranged in juxtaposition in the first film formation region, and film formation is carried out on the film formation target object by the plurality of first film forming units in sequence or at the same time.

4. The sputtering method of claim 2, wherein a multiple number of second film forming units is arranged in juxtaposition in the second film formation region, and film formation is carried out on the film formation target object by the multiple number of second film forming units in sequence or at the same time.

5. The sputtering method of claim 1, wherein the initial layer is formed on the film formation target object in a preset thickness by performing the sputtering after an angle between the facing surfaces of the pair of targets is set to a preset angle, and
then, the second layer is formed by performing the sputtering after the angle between the facing surfaces is set to be larger than the preset angle by way of changing the directions of the facing surfaces toward the film formation target object.

6. The sputtering method of claim 5, wherein a magnetic field space generated on the facing surfaces of the pair of targets is an inter-target magnetic field space having magnetic force lines oriented from one of the targets toward the other.

7. The sputtering method of claim 6, wherein a cylindrical auxiliary magnetic field space having a magnetic field strength greater than that of the inter-target magnetic filed space is further formed to surround the outside of the inter-target magnetic field space such that magnetic force lines of the cylindrical auxiliary magnetic field space are oriented in the same direction as that of magnetic force lines of the inter-target magnetic field space.

8. The sputtering method of claim 5, wherein a magnetic field space generated on the facing surface of the pair of targets is a curved magnetic field space having magnetic force lines connecting an outer peripheral portion of the facing surface of the target with a central portion thereof in an arc shape.

9. The sputtering method of claim 8, wherein the curved magnetic field space has magnetic force lines oriented from a peripheral portion toward a central portion on the facing surface of one of the pair of targets and magnetic force lines oriented from a central portion toward a peripheral portion on the facing surface of the other target, and
there is further generated a cylindrical auxiliary magnetic field space having magnetic force lines oriented from a vicinity of one of the targets toward a vicinity of the other target to surround the outside of an inter-target space formed between the pair of targets and having a magnetic field strength greater than that of the curved magnetic field space.

10. A sputtering apparatus for forming, in a vacuum chamber, an initial layer on a film formation target object and then further forming a second layer on the initial layer therein, the apparatus comprising:
in the vacuum chamber,
a pair of targets for forming the initial layer, arranged to face each other while distanced apart at a preset distance and having surfaces inclined toward the film formation target object placed at a lateral position between the targets;
a magnetic field generating unit for generating a magnetic field space on the facing surfaces of the pair of targets; and
a holder for holding the film formation target object,
wherein the second layer is formed on the film formation target object at a film forming rate higher than that of the initial layer.

11. The sputtering apparatus of claim 10, wherein in the vacuum chamber whose inner space is divided into a first film formation region having a first film forming unit for forming the initial layer and a second film formation region having a second film forming unit for forming the second layer, the first film forming unit and the second film forming unit are arranged in juxtaposition,
the holder is configured to be movable, while holding the film formation target object in the vacuum chamber, from a first film formation position where the film formation is performed on the film formation target object in the first film forming unit to a second film formation position where the film formation is performed on the film formation target object in the second film forming unit,
the first film forming unit includes a pair of first complex type cathodes each having a first target of the pair of targets; a curved magnetic field generating unit for generating a curved magnetic field space having arc-shaped magnetic force lines on the facing surface of the first target; and a cylindrical auxiliary magnetic field generating unit installed to surround the first target,
the pair of first complex type cathodes are installed such that surfaces of the first targets face each other while distanced apart from each other at a preset distance and the surfaces are inclined toward the first film formation position located at a lateral position between the first targets,
the curved magnetic field generating unit of one of the pair of first cathodes generates an inwardly curved magnetic field whose polarity is set such that magnetic force lines are oriented from an outer peripheral portion of one of the first targets toward a central portion thereof while the curved magnetic field generating unit of the other first cathode generates an outwardly curved magnetic field whose polarity is set such that magnetic force lines are oriented from a central portion of the other first target to an outer peripheral portion thereof,
the cylindrical auxiliary magnetic field generating unit generates a cylindrical auxiliary magnetic field space having magnetic force lines oriented from a vicinity of the one first target toward a vicinity of the other first target so as to surround a first inter-target space formed between the first targets and having a magnetic field strength greater than that of the curved magnetic field space, and
the second film forming unit includes a sputtering cathode having a second target and an inwardly or outwardly curved magnetic field generating unit for generating an inwardly or outwardly curved magnetic field space on a surface of the second target, and being capable of emitting sputtered particles toward the second film formation position, and having a film forming rate higher than that of the first film forming unit.

12. The sputtering apparatus of claim 11, wherein a plurality of first film forming units is arranged in juxtaposition in the first film formation region.

13. The sputtering apparatus of claim 11, wherein a multiple number of second film forming units is arranged in juxtaposition in the second film formation region.

14. The sputtering apparatus of claim 11, wherein the second film forming unit includes a parallel plate type magnetron cathode made up of the sputtering cathode in which a surface of the second target is oriented toward the second film formation position.

15. The sputtering apparatus of claim 11, wherein the second film forming unit includes dual magnetron cathodes in which a pair of the sputtering cathodes are arranged in juxtaposition and surfaces of second targets are oriented toward the second film formation position, and the dual magnetron cathodes are connected with an AC power supply capable of applying AC electric fields having a phase difference of about 180° to the pair of sputtering cathodes respectively.

16. The sputtering method of claim 11, wherein the second film forming unit includes a pair of second complex type cathodes each having a second target; a curved magnetic field generating unit for generating a curved magnetic field space having arc-shaped magnetic force lines on the surface of the second target; and a cylindrical auxiliary magnetic field generating unit installed to surround the second target,
the pair of second complex type cathodes are installed such that surfaces of the second targets face each other while distanced apart from each other at a preset distance and the surfaces are inclined toward the second film formation position located at a lateral position between the second targets,
the curved magnetic field generating unit of one of the pair of second cathodes generates an inwardly curved magnetic field whose polarity is set such that magnetic force lines are oriented from an outer peripheral portion of one of the second targets toward a central portion thereof while the curved magnetic field generating unit of the other second cathode generates an outwardly curved magnetic field whose polarity is set such that magnetic force lines are oriented from a central portion of the other second target to an outer peripheral portion thereof,
the cylindrical auxiliary magnetic field generating unit generates a cylindrical auxiliary magnetic field space having magnetic force lines oriented from a vicinity of the one second target toward a vicinity of the other second target so as to surround a second inter-target space formed between the second targets and having a magnetic field strength greater than that of the curved magnetic field space, and
an angle formed between facing surfaces of the second targets in the pair of second complex type cathodes is larger than an angle formed between the facing surfaces of the first targets in the pair of first complex type cathodes of the first film forming unit.

17. The sputtering apparatus of claim 11, wherein the pair of first complex type cathodes are connected with an AC power supply capable of applying AC electric fields having a phase difference of about 180° to the pair of first combination cathodes respectively.

18. The sputtering apparatus of claim 10, wherein the pair of targets are disposed such that their directions can be changed toward the holder so as to increase an angle formed between their facing surfaces.

19. The sputtering apparatus of claim 18, wherein the magnetic field generating unit is an inter-target magnetic field generating unit for generating an inter-target magnetic field space having magnetic force lines oriented from one of the targets toward the other.

20. The sputtering apparatus of claim 19, wherein a cylindrical auxiliary magnetic filed generating unit is further disposed to surround each of the pair of targets so as to generate a cylindrical auxiliary magnetic field space having a magnetic field strength greater than that of the inter-target magnetic field space and surrounding the outside of the inter-target magnetic field space such that magnetic force lines of the cylindrical auxiliary magnetic field space are oriented in the same direction as that of magnetic force lines of the inter-target magnetic field space.

21. The sputtering apparatus of claim 18, wherein the magnetic field generating unit is a curved magnetic field generating unit for generating a magnetic field space having magnetic force lines connecting an outer peripheral portion of the facing surface of the target with a central portion thereof in an arc shape.

22. The sputtering apparatus of claim 21, wherein the curved magnetic field generating unit generates a curved magnetic field having magnetic force lines oriented from a peripheral portion toward a central portion on the facing surface of one of the targets and magnetic force lines oriented from a central portion toward a peripheral portion on the facing surface of the other target, and
disposed to surround the each of the pair of targets is a cylindrical auxiliary magnetic field generating unit for generating a cylindrical auxiliary magnetic field space having magnetic force lines oriented from a vicinity of one of the targets toward a vicinity of the other target to surround the outside of an inter-target space formed between the pair of targets and having a magnetic field strength greater than that of the curved magnetic field space.

23. The sputtering apparatus of claim 18, wherein the pair of targets are disposed such that their directions can be changed so as to increase or decrease the angle formed between their facing surfaces, and
the apparatus further comprises:
a detection unit for detecting at least one of a film thickness and a temperature at a vicinity of the film formation target object held by the holder, the detection unit being provided at a position facing a flow path of sputtered particles flying toward the film formation target object from each of the pair of targets; and a controller for controlling a change of direction of each target based on a detection value obtained by the detection unit.
